(19) United States
(12) Patent Application Publication
(10) Pub. No.: US 2026/0323973 A1
(43) Pub. Date: Oct. 15, 2026

(54) SEMICONDUCTOR STRUCTURES AND MEMORY DEVICES AND METHODS FOR MANUFACTURING THE SAME

(71) Applicant: Peiching LING, Taipei (TW)

(72) Inventors: Peiching LING, San Jose, CA (US); Nanray WU, Miaoli (TW); Liang-Gi YAO, Hsinchu City (TW)

(21) Appl. No.: 19/104,230

(22) PCT Filed: Dec. 19, 2023
(86) PCT No.: PCT/US2023/084974

§ 371 Date: Feb. 17, 2025

Related U.S. Application Data
(60) Provisional application No. 63/387,972, filed on Dec. 19, 2022.

(51) Int. Cl. H10D 8/00; H10B 61/00; H10B 63/00; H10B 63/10; H10D 8/01; H10D 62/10; H10D 84/00; H10D 84/01; H10N 50/10

(52) U.S. Cl. CPC H10D 8/411; H10B 61/10; H10D 8/045; H10D 62/124; H10D 84/0112; H10D 84/221; H10B 63/10; H10B 63/20; H10B 63/84; H10N 50/10

(57) ABSTRACT

The present disclosure relates to semiconductor structures, memory devices, and methods for making the same. The semiconductor structure comprises a first doped region, a second doped region, a first ohmic contact, a second ohmic contact, and a first dielectric structure. The second doped region is in contact with the first doped region. The first ohmic contact is in contact with a bottom surface of the first doped region. The second ohmic contact is in contact with a top surface of the second doped region. The first dielectric structure surrounds each of the first doped region, the second doped region, the first ohmic contact, and the second ohmic contact. The first doped region is doped with a first conductivity-type of dopant, and the second doped region is doped with a second conductivity-type of dopant opposite to the first conductivity-type, such that a p-n junction is formed between the first doped region and the second doped region. An ohmic junction is formed between the first doped region and the first ohmic contact. An ohmic junction is formed between the second doped region and the second ohmic contact.

### RELATED APPLICATION

This application claims priority to U.S. Provisional Patent Application Ser. No. 63/387,972, filed on Dec. 19, 2022, entitled “Structures of Vertical Diodes and Memory Cells and Manufacturing Processes thereof,” which is incorporated herein by reference in its entirety.

### FIELD OF THE INVENTION

### Background of the Invention

The present invention is related to semiconductor structures and memory devices and methods for manufacturing the same. In particular, some embodiments of the present disclosure relate to semiconductor structures including a vertical PN diode, memory devices including a vertical PN diode, and methods for making the same.

### Description of Related Art

The demand for non-volatile memory is increasing due to the continuous development of portable devices. As the dimension of the devices is reduced, non-volatile memory with greater efficiency, faster memory access, and low-power consumption become hot topics for fulfilling the market. However, there are several technical issues that need to be overcome to provide the desired properties. First, in a conventional non-volatile memory device, a transistor is used as a selector. When the size of the transistor is reduced and the integration density is increased, the space between these devices is also decreased. The inter-device space becomes critical to the performance of the devices, and when the space is too small, these devices may interfere with each other. Second, the transistor has a saturation region, the current it can provide is limited by its inherent characteristics. When a non-volatile memory device has a high current density requirement, such as a magnetoresistive random access memory (MRAM) device, the size of a transistor capable of providing fulfilling current density would be significantly large. Third, the channel region of the transistor forming in a semiconductor substrate may suffer from current leakage, which may decrease the efficiency and result in high power consumption.

When using a transistor as the selector of the non-volatile memory device, compromise has to be made to balance the feature size and the inter-device space, and each device's performance may need to be optimized. When more devices are put into one chip, parasitic capacitance and power consumption may increase due to the small inter-device space and current leakage. There is still a need to improve the structure and process for greater efficiency, faster memory access, and low-power consumption of memory devices.

### SUMMARY

According to the present disclosure, a semiconductor structure is provided. The semiconductor structure comprises a first doped region, a second doped region, a first ohmic contact, a second ohmic contact, and a first dielectric structure. The second doped region is in contact with the first doped region. The first ohmic contact is in contact with a bottom surface of the first doped region. The second ohmic contact is in contact with a top surface of the second doped region. The first dielectric structure surrounds each of the first doped region, the second doped region, the first ohmic contact, and the second ohmic contact. The first doped region is doped with a first conductivity-type of dopant, and the second doped region is doped with a second conductivity-type of dopant opposite to the first conductivity-type, such that a p-n junction is formed between the first doped region and the second doped region. An ohmic junction is formed between the first doped region and the first ohmic contact. An ohmic junction is formed between the second doped region and the second ohmic contact.

According to the present disclosure, a method for manufacturing a semiconductor structure is provided. The method comprises providing a semiconductor substrate comprising a first substrate and a second substrate on the first substrate (step (a)), forming a first ohmic contact on the first surface of the second substrate or in the second substrate (step (b)), patterning the second substrate to define a first doped region (step (c)), adding a third substrate to the first surface of the second substrate, wherein the second substrate is between the third substrate and the first substrate (step (d)), removing the first substrate and exposing a second surface of the second substrate opposite to the first surface (step (e)), either exposing or forming a second doped region in the second substrate or on the second surface of the second substrate (step (f)), and forming a second ohmic contact on the second surface of the second substrate or in the second substrate (step (g)).

According to the present disclosure, a semiconductor structure is provided. The semiconductor structure comprises a first diode and a second diode. The first diode comprises a first doped region and a second doped region over and in contact with the first doped region. The second diode comprises a third doped region and a fourth doped region over and in contact with the third doped region. Each of the first doped region and the fourth doped region is doped with a first conductivity-type of dopant. Each of the second doped region and the third doped region is doped with a second conductivity-type of dopant opposite to the first conductivity-type. A top surface of the second doped region is higher than a bottom surface of the third doped region. A top surface of the fourth doped region is higher than a bottom surface of the first doped region.

According to the present disclosure, a method for manufacturing a semiconductor structure. The method comprises providing a semiconductor substrate comprising a first substrate and a second substrate on the first substrate (step (a)), forming a third doped region of a second diode in the second substrate or on a first surface of the second substrate (step (b)), patterning the second substrate to define a first doped region of the first diode and a fourth doped region of a second diode (step (c)), adding a third substrate to the first surface of the second substrate, wherein the second substrate is between the third substrate and the first substrate (step (d)), removing the first substrate and exposing a second surface of the second substrate opposite to the first surface (step (e)), either exposing or forming a second doped region of the first diode in the second substrate or on the second surface of the second substrate (step (f)).

According to the present disclosure, a memory device is provided. The memory device comprises a memory unit, an electrode, a first diode pair, and a second diode pair. The memory unit has a first end and a second end. The electrode extends laterally in a first direction from a first side of the memory unit to a second side of the memory unit. The memory unit is electrically coupled to the electrode from the second end of the memory unit. The first diode pair is disposed on the first side of the memory unit. The second diode pair is disposed on the second side of the memory unit. Each of the first diode pair and the second diode pair comprises a first diode and a second diode. Each of the first diode of the first diode pair and the second diode pair comprises a first doped region and a second doped region over and in contact with the first doped region. Each of the second diode of the first diode pair and the second diode pair comprises a third doped region and a fourth doped region over and in contact with the third doped region. Each of the first doped region of the first diode pair and the second diode pair is doped with a first conductivity-type of dopant. Each of the second doped region of the first diode pair and the second diode pair is doped with a second conductivity-type of dopant opposite to the first conductivity-type. Each of the third doped region of the first diode pair and the second diode pair is doped with a second conductivity-type of dopant. Each of the fourth doped region is doped with a first conductivity-type of dopant. In each of the first diode pair and the second diode pair, a top surface of the second doped region is higher than a bottom surface of the third doped region, and a top surface of the fourth doped region is higher than a bottom surface of the first doped region. Each of the first diode and the second diode of the first diode pair is electrically coupled to the electrode at the first side of the memory unit. Each of the first diode and the second diode of the second diode pair is electrically coupled to the electrode at the second side of the memory unit.

### BRIEF DESCRIPTION OF THE DRAWINGS

FIGS. 1A to 1J are schematic diagrams illustrating intermediate stages in the manufacture of a semiconductor structure according to one embodiment of the present disclosure.

FIGS. 2A to 2E are schematic diagrams illustrating intermediate stages in the manufacture of a semiconductor structure according to one embodiment of the present disclosure.

FIGS. 3A to 3I are schematic diagrams illustrating intermediate stages in the manufacture of a semiconductor structure according to one embodiment of the present disclosure.

FIGS. 4A to 4F are schematic diagrams illustrating intermediate stages in the manufacture of a semiconductor structure according to one embodiment of the present disclosure.

FIGS. 5A to 5G are schematic diagrams illustrating intermediate stages in the manufacture of a semiconductor structure according to one embodiment of the present disclosure.

FIGS. 6A to 6H are schematic diagrams illustrating intermediate stages in the manufacture of a semiconductor structure according to one embodiment of the present disclosure.

FIGS. 7A to 7D are schematic diagrams illustrating intermediate stages in the manufacture of a semiconductor structure according to one embodiment of the present disclosure.

FIGS. 8A to 8B are schematic views to illustrate an embodiment of a memory device according to the present disclosure.

FIG. 9 is a schematic view to illustrate an embodiment of a memory device according to the present disclosure.

FIGS. 10A to 10B are schematic views to illustrate an embodiment of a memory device according to the present disclosure.

FIGS. 11A to 11B are schematic views to illustrate an embodiment of a memory device according to the present disclosure.

FIG. 12 is a schematic view to illustrate an embodiment of a memory device according to the present disclosure.

FIGS. 13A to 13B are schematic views to illustrate an embodiment of a memory device according to the present disclosure.

FIGS. 14A to 14B are schematic views to illustrate an embodiment of a memory device according to the present disclosure.

FIG. 14C is an electronic schematic diagram to illustrate a memory array including the memory device as shown in FIGS. 14A and 14B according to an embodiment of the present disclosure.

FIG. 14D is a table of operation voltage of a memory cell in the memory array as shown in FIG. 14C according to an embodiment of the present disclosure.

FIG. 15 is a schematic view to illustrate an embodiment of a memory device according to the present disclosure.

FIGS. 16A to 16D are schematic diagrams illustrating intermediate stages in the manufacture of a semiconductor structure according to one embodiment of the present disclosure.

FIGS. 17A to 17C are schematic diagrams illustrating intermediate stages in the manufacture of a semiconductor structure according to one embodiment of the present disclosure.

FIG. 18 is a schematic view to illustrate an embodiment of a semiconductor substrate according to the present disclosure.

FIG. 19 is a schematic view to illustrate an embodiment of a semiconductor structure according to the present disclosure.

FIG. 20 is a schematic view to illustrate an embodiment of a semiconductor structure according to the present disclosure.

### DETAILED DESCRIPTION OF PREFERRED EMBODIMENTS

The terminology used in the description presented below is intended to be interpreted in its broadest reasonable manner, even though it is used in conjunction with a detailed description of certain specific embodiments of the technology. Certain terms may even be emphasized below; however, any terminology intended to be interpreted in any restricted manner will be specifically defined as such in this Detailed Description section. Components and achievement of a semiconductor structure or a memory device, according to the present disclosure may be illustrated in the following drawings and embodiments. However, the size and shape shown on drawings for the semiconductor structure or the memory device do not limit the features of the present disclosure.

The phrase “on” used in this application can mean directly on or indirectly on with intervening elements or layers. The spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

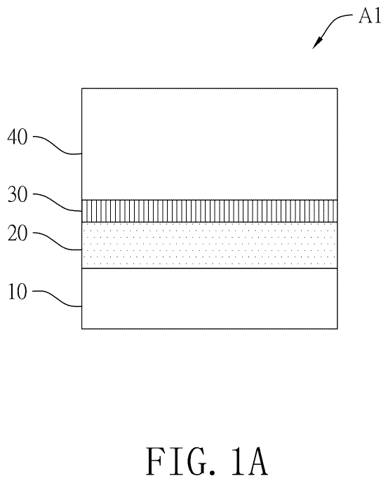

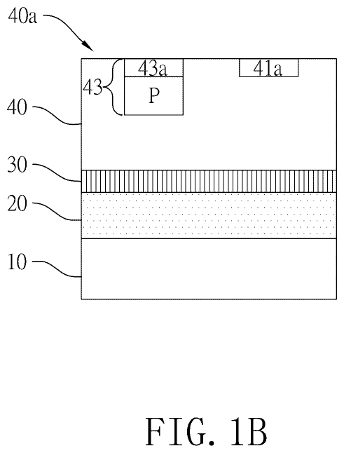

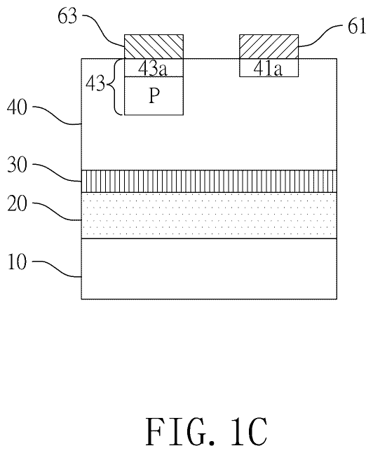

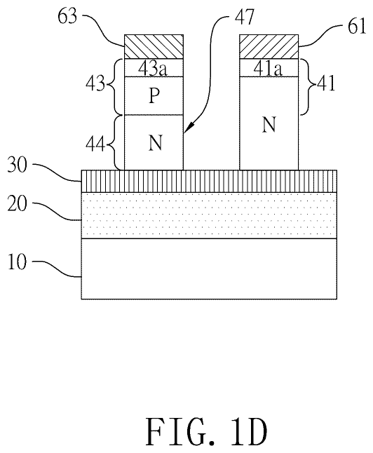

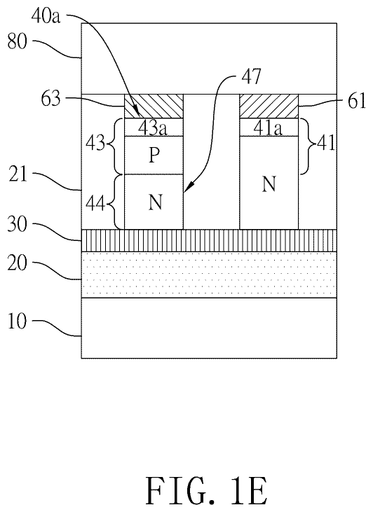

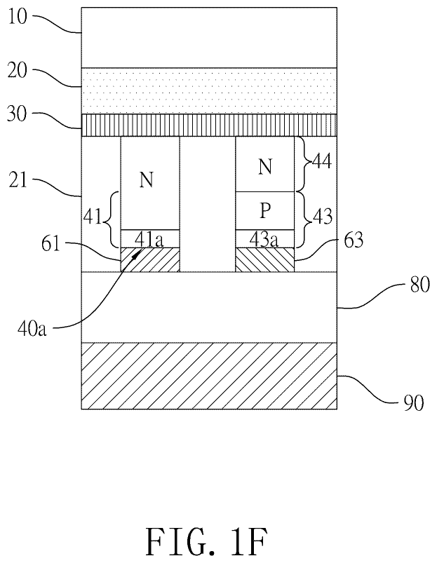

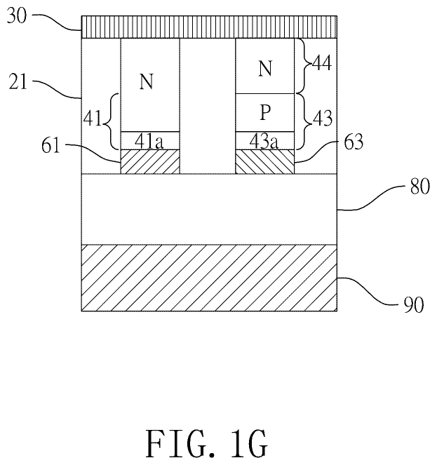

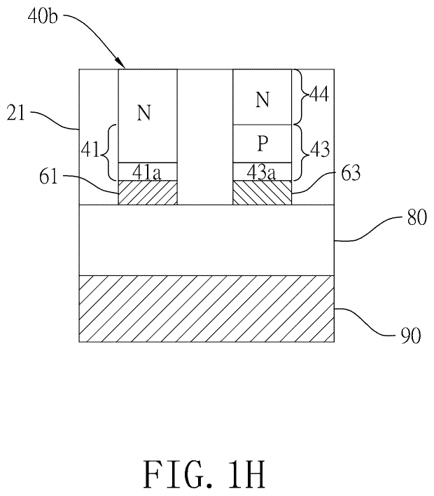

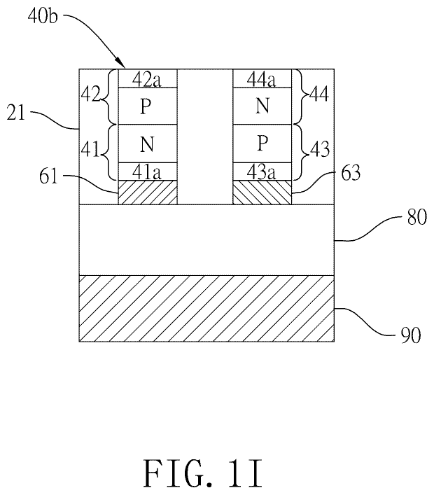

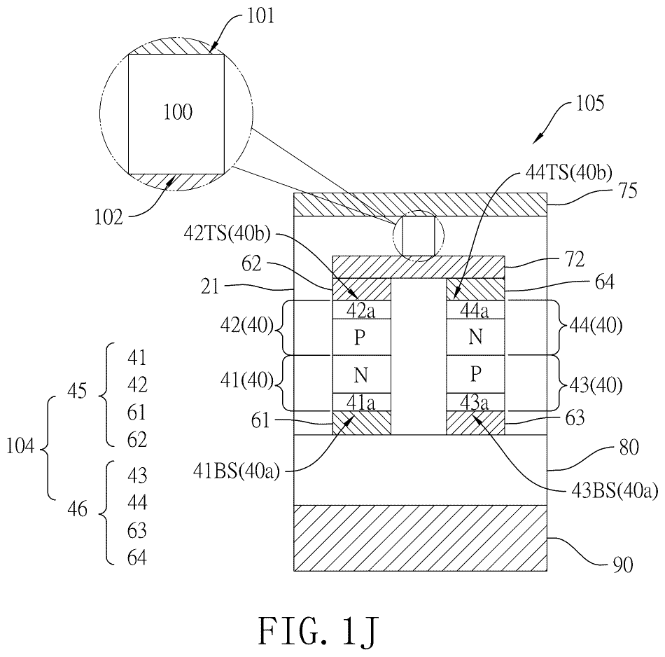

FIGS. 1A to 1I are schematic diagrams illustrating intermediate stages in the manufacture of a semiconductor structure according to one embodiment of the present disclosure. As shown in FIG. 1A, a semiconductor substrate A1 is provided (step (a)). The semiconductor substrate comprises a first substrate 10, a second substrate 40, and a bonding layer 20. The second substrate 40 is on the first substrate 10. The bonding layer 20 is located between the first substrate 10 and the second substrate 40. In the embodiment as shown in FIG. 1A, the semiconductor substrate A1 further comprises an etch stop layer 30 located between the bonding layer 20 and the second substrate 40.

In one embodiment, each of the first substrate 10 and the second substrate 40 is a wafer with a diameter of 6, 8, 12, or 18 inches. In this situation, the first substrate 10 may be referred to as a handle wafer and the second substrate 40 may be referred to as a device wafer. In some embodiments, the first substrate 10 comprise glass, polysilicon, or ceramic. In some other embodiments, the first substrate 10 may comprise semiconductor material, for example, a single crystalline semiconductor material made of silicon, germanium, silicon germanium, gallium arsenide (GaAs), indium phosphide (InP), silicon carbide (SiC), or gallium nitride (GaN). The second substrate 40 may comprise a layer of a semiconductor material. In some embodiments, the second substrate 40 may comprise a single crystalline semiconductor material, for example, made of silicon, germanium, silicon germanium, gallium arsenide (GaAs), indium phosphide (InP), silicon carbide (SiC), or gallium nitride (GaN). In some embodiments, the second substrate 40 may be doped with a first conductivity-type of dopant, for example, a p-type dopant, such as boron, aluminum, gallium, indium, the like, or combinations thereof, or a n-type dopant, such as phosphorus, arsenic, antimony, bismuth, the like, or combinations thereof. In some embodiments, the doping concentration of the second substrate 40 may be from about 1.0×10¹⁴ atoms/cm³ to about 5.0×10¹⁷ atoms/cm³. In one embodiment, the thickness of the second substrate 40 may be in a range between 5 nm and 3 μm. These values are merely examples and are not intended to be limiting.

In some embodiments, the etch stop layer 30 may have a high etch selectivity against the bonding layer 20. An etch selectivity of the etch stop layer 30 against the bonding layer 20 may refer to the ratio of the etch rate of the bonding layer 20 to the etch rate of the etch stop layer 30 under the same etching condition, and the etch stop layer 30 may have a high etch selectivity against the bonding layer 20 when the etch rate of the bonding layer 20 is substantially faster than the etch rate of the etch stop layer 30 under the same etching condition. In some embodiments, the etch selectivity of the etch stop layer 30 against the bonding layer 20 may be higher than 5:1. In some embodiments, the etch selectivity of the etch stop layer 30 against the bonding layer 20 may be higher than 10:1, 20:1, 30:1, 50:1, 80:1, 100:1, 200:1, or 300:1.

For example, in one embodiment, the etch stop layer 30 comprises silicon nitride and the bonding layer 20 comprises silicon oxide. Under appropriate etching conditions, for example, dilute HF (e.g., a weight ratio of H₂O to HF at about 100:1) may be used as an etchant, the etch stop layer 30 (e.g., silicon nitride) may have an etch rate of about 1 Å/min, and the bonding layer 20 (e.g., silicon oxide) may have an etch rate of about 30 Å/min, which renders an etch selectivity of about 30:1 (oxide/nitride). The present disclosure is not limited thereto. In some embodiments, other materials for the etch stop layer 30 and the bonding layer 20 may be used to achieve a high etch selectivity under dry etching processes or wet etching processes with proper etching conditions. Proper materials of the etch stop layer 30 and the bonding layer 20 and proper etching conditions can be selected based on actual needs and properties of the materials.

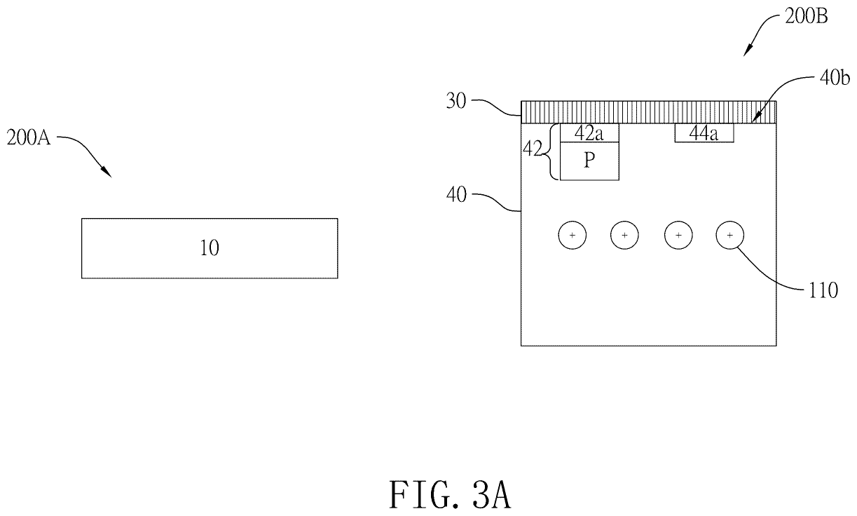

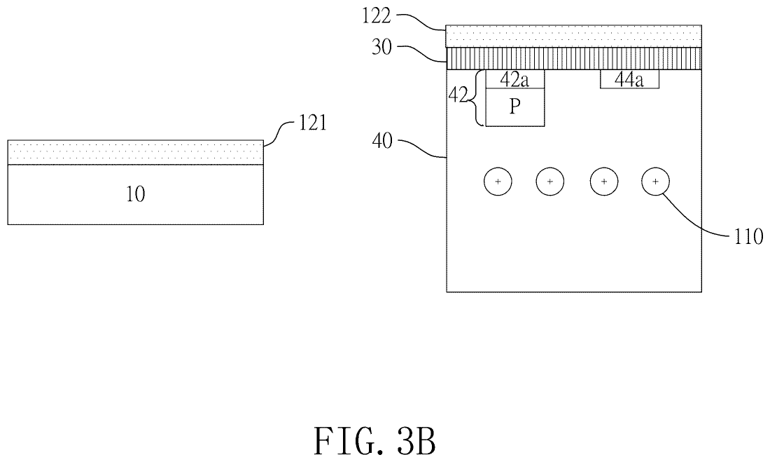

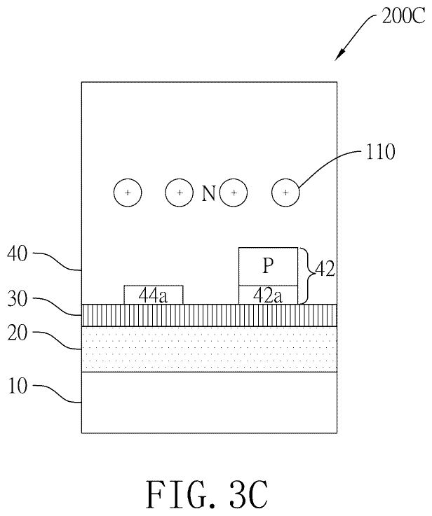

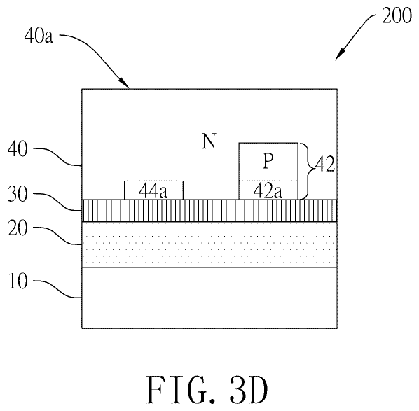

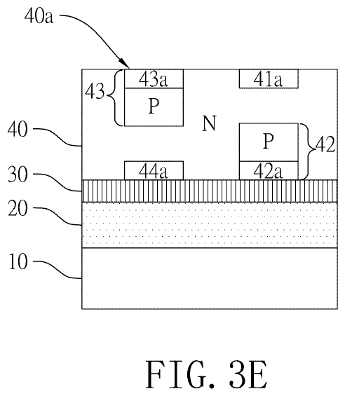

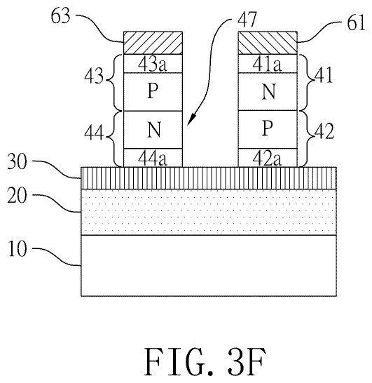

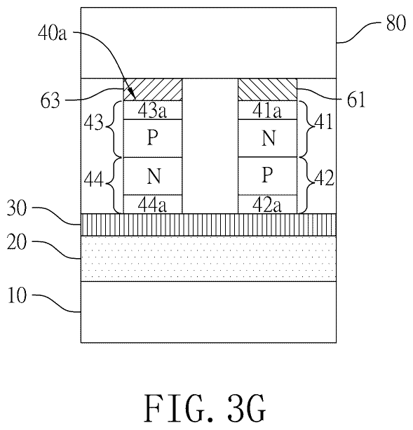

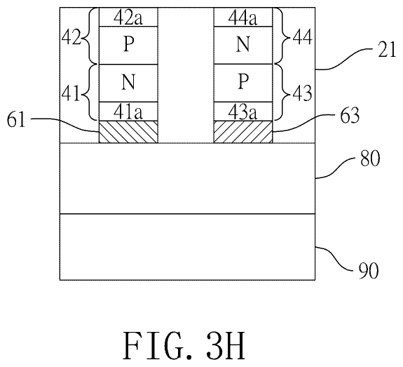

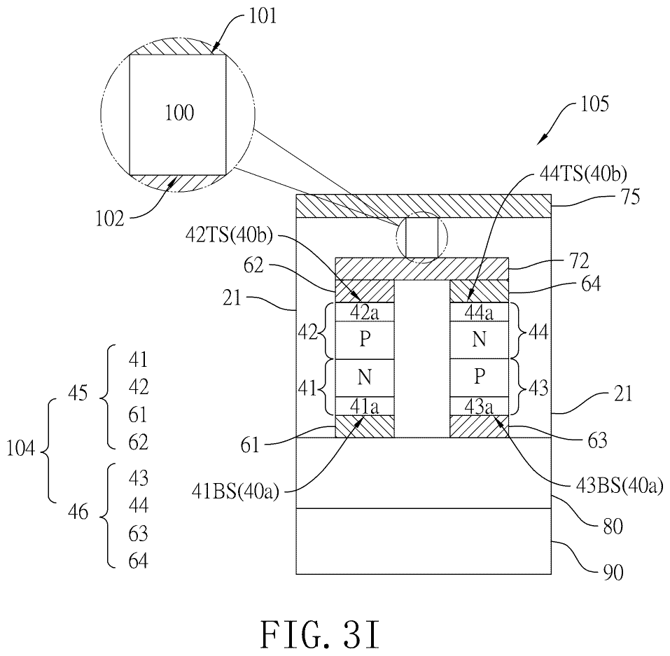

In some embodiments, the bonding layer 20 comprises oxide such as silicon oxide, and the etch stop layer 30 may comprise silicon nitride, silicon oxynitride, doped semiconductor material, undoped semiconductor material, metal, conductive metal compound, or combinations thereof. The doped semiconductor material may be semiconductor material with p-type dopants, such as boron, aluminum, gallium, indium, the like, or combinations thereof, or semiconductor material with n-type dopants, such as phosphorus, arsenic, antimony, bismuth, the like, or combinations thereof. The undoped semiconductor material may be amorphous silicon, polysilicon, or silicon germanium, the like, or combinations thereof. The metal may be aluminum, gold, copper, tungsten, the like, or an alloy thereof. The conductive metal compound may be metal silicide, metal carbide, metal nitride, the like, or combinations thereof, e.g., WN, TaN, TaSi, TiN, TiSi, TiSiN, TiAlN, MoN, IrOx, RuOx, or RuTiN. In one embodiment, the thickness of the bonding layer 20 may be in a range between 0.2 nm and 1000 nm. In one embodiment, the thickness of the etch stop layer 30 may be in a range between 0.2 nm and 5 nm. These values are merely examples and are not intended to be limiting. The semiconductor substrate A1 may be fabricated by processes similar to that described below with regard to FIGS. 3A to 3D.

As shown in FIG. 1B, a third doped region 43 (of a second diode to be formed) is formed in the second substrate 40 (step (b)). The third doped region 43 may be formed extending from a first surface 40a of the second substrate 40. The third doped region 43 is doped with a second conductivity-type of dopant opposite to the first conductivity-type. In some embodiments, the doping concentration of the third doped region 43 may be from about 1.0×10¹⁸ atoms/cm³ to about 3.0×10²⁰ atoms/cm³. In one embodiment, the thickness of the third doped region 43 may be in a range between 2 nm and 100 nm. These values are merely examples and are not intended to be limiting. The third doped region 43 may be formed by ion implantation or epitaxial growth. In some other embodiments, at least a portion of the third doped region 43 may be formed on the first surface 40a of the second substrate 40, e.g., through epitaxial growth.

The third doped region 43 may comprise a third heavily-doped region 43a. The third heavily-doped region 43a may extend from the first surface 40a of the second substrate 40. The third heavily-doped region 43a is doped with the second conductivity-type of dopant. In some embodiments, the third heavily-doped region 43a may have a higher doping concentration than the third doped region 43. In some embodiments, the doping concentration of the third heavily-doped region 43a may be from about 1.0×10¹⁹ atoms/cm³ to about 5.0×10²⁰ atoms/cm³. In one embodiment, the thickness of the third heavily-doped region 43a may be in a range between 1 nm and 50 nm. These values are merely examples and are not intended to be limiting. The third heavily-doped region 43a may be formed by ion implantation in the third doped region 43 or by epitaxial growth on the surface the third doped region 43.

In the embodiment shown in FIG. 1B, a first heavily-doped region 41a is formed. The first heavily-doped region 41a may be formed extending from the first surface 40a of the second substrate 40. In one embodiment, the first heavily-doped region 41a may be formed by ion implantation or epitaxial growth. The first heavily-doped region 41a may be doped with the first conductivity-type of dopant as the second substrate 40 as described above. In some embodiments, the first heavily-doped region 41a may have a higher doping concentration than the second substrate 40. In some embodiments, the doping concentration of the first heavily-doped region 41a may be from about 1.0×10¹⁸ atoms/cm³ to about 3.0×10²⁰ atoms/cm³. In one embodiment, the thickness of the first heavily-doped region 41a may be in a range between 1 nm and 50 nm. These values are merely examples and are not intended to be limiting. In some other embodiments, each of the first heavily-doped region 41a and the third heavily-doped region 43a may be formed on the first surface 40a of the second substrate 40, e.g., by epitaxial growth.

As shown in FIG. 1C, a first ohmic contact 61 of the first diode and a third ohmic contact 63 of the second diode may be formed. The first ohmic contact 61 and the third ohmic contact 63 may be formed on the first surface 40a of the second substrate 40. The first ohmic contact 61 and the third ohmic contact 63 may be formed in contact with the first heavily-doped region 41a and the third heavily-doped region 43, respectively. The third ohmic contact 63 may be formed over and in contact with the third doped region 43, and an ohmic junction may be formed between the third ohmic contact 63 and the third heavily-doped region 43a. The first ohmic contact 61 may be formed over and in contact with a region in the second substrate 40 designated to form a first doped region, and an ohmic junction may be formed between the first ohmic contact 61 and the first heavily-doped region 41. Each of the first ohmic contact 61 and the third ohmic contact 63 may comprise suitable metal, alloy, or conductive metal compound, e.g., Mo, Ag, TiN, or combinations thereof. In one embodiment, the thickness of the first ohmic contact 61 may be in a range between 2 nm and 100 nm. In one embodiment, the thickness of the third ohmic contact 63 may be in a range between 2 nm and 100 nm. These values are merely examples and are not intended to be limiting. In some other embodiments, the first doped region 41 and/or the third doped region 43 may be etched to form trench(es), and the first ohmic contact 61 and/or the third ohmic contact 63 may be formed in the trenches in the second substrate 40. The compositions of the first ohmic contact 61 and the third ohmic contact 63 and the doping concentrations of the first heavily-doped region 41a, the third heavily-doped region 43a, and the third doped region 43 may be adjusted according to desired diode properties.

In some embodiments, each of the first ohmic contact 61 and the third ohmic contact 63 may be formed by deposition such as chemical vapor deposition (CVD), physical vapor deposition (PVD), or atomic layer deposition (ALD). In the embodiment shown in FIG. 1C, each of the first ohmic contact 61 and the third ohmic contact 63 may be patterned. In some embodiments, an un-patterned ohmic contact material layer (not shown) may be formed on the first surface 40a of the second substrate 40 and then be patterned through any suitable process (e.g., photolithography and etch process) to form the first ohmic contact 61 and the third ohmic contact 63. In some embodiments, trench(es) can be etched through a mask layer (not shown, e.g., a masking element formed of a photoresist) on the second substrate 40 to expose the first heavily-doped region 41a and the third heavily-doped region 43a, and the first ohmic contact 61 and the third ohmic contact 63 may be formed in the trench(es). Then the mask layer may be removed after the formation of the first ohmic contact 61 and the third ohmic contact 63.

As shown in FIG. 1D, the second substrate is patterned to define a first doped region 41 of the first diode and a fourth doped region 44 of a second diode (step (c)). The second substrate 40 may be patterned through any suitable process (e.g., photolithography and etch process). In some embodiments, one or more etch process(es) may be performed to form a trench 47 through the second substrate 40, such that the third doped region 43 and the fourth doped region 44 are separated from the s first doped region 41. In the embodiment shown in FIG. 1C, a portion of the first ohmic contact 61 and/or the third ohmic contact 63 may also be removed before and/or during the patterning of the second substrate 40. In some embodiments, the etch stop layer 30 may function as an etch stop layer in the etch process for patterning the second substrate 40.

As shown in FIG. 1E, a first dielectric structure 21 may be formed before the third substrate is added. The first dielectric structure 21 may surround each of the first doped region 41, the third doped region 43, the fourth doped region 44, the first ohmic contact 61, and the third ohmic contact 63. The first dielectric structure 21 may include one or more stacked dielectric layers. The first dielectric structure 21 may comprise dielectric material such as silicon oxide, silicon oxynitride, low dielectric constant (low k) materials, a combination thereof, and/or other applicable material and may be formed by deposition such as CVD, PVD, or ALD, spinning, or any suitable method. The first dielectric structure 21 may fill the trench 47, such that each of the first diode 45 and the second diode 46 that will be formed subsequently is surrounded by the first dielectric structure 21.

Alternatively, in some other embodiments, the first doped region 41 and the fourth doped region 44 may be defined before the formation of the first ohmic contact 61 and/or the third ohmic contact 63. For example, the first dielectric structure 21 may be formed in the trench 47 separating the third doped region 43 and the fourth doped region 44 from the first doped region 41, and the first ohmic contact 61 and/or the third ohmic contact 63 may be formed in the first dielectric structure 21 using a damascene or dual damascene process or any suitable method to form the structure shown in FIG. 1E.

As shown in FIG. 1E, an interconnect structure 80 is formed over the first dielectric structure 21. The interconnect structure 80 may include conductive features (e.g., conductive lines and vias). In the embodiment shown in FIG. 1E, the interconnect structure 80 may be electrically coupled to the first ohmic contact 61 and/or the third ohmic contact 63. In some embodiments, the interconnect structure 80 may be electrically connected to other devices, such as a control circuit, a memory unit, etc. As shown in FIG. 1E, the interconnect structure 80 is formed over the first surface 40a of the second substrate 40. Conductive features of the interconnect structure 80 may comprise titanium nitride, tantalum nitride, tungsten, ruthenium, aluminum, copper, some other suitable material(s), or a combination of the foregoing and may be formed by using a damascene or dual damascene process or any suitable method.

In some other embodiments, instead of forming the interconnect structure 80 over the first ohmic contact 61 and the third ohmic contact 63, at least a portion of an interconnect structure 80 may be formed in the same layer as the first ohmic contact 61 and the third ohmic contact 63. In some other embodiments, the interconnect structure 80 may be omitted. For example, instead of forming extra wiring layers, the first ohmic contact 61 and/or the third ohmic contact 63 may extend laterally and provide electrical connection therebetween and/or among the devices formed in the second substrate 40.

As shown in FIG. 1F, a third substrate 90 is added to the first surface 40a of the second substrate 40, wherein the second substrate 40 is located between the third substrate 90 and the first substrate 10 (step (e)). As shown in FIG. 1F, the interconnect structure 80 may be located between the second substrate 40 and the third substrate 90.

In one embodiment, the third substrate 90 is a wafer with a diameter of 6, 8, 12, or 18 inches. The third substrate 90 may be a handle wafer or a device wafer. In some embodiments, the third substrate 90 may comprise glass, polysilicon, or ceramic. In some embodiments, the third substrate 90 may comprise semiconductor material, for example, made of silicon, germanium, silicon germanium, gallium arsenide (GaAs), indium phosphide (InP), silicon carbide (SiC), or gallium nitride (GaN). In some embodiments, the third substrate 90 may comprise single crystalline semiconductor material. In one embodiment, the thickness of the third substrate 90 may be in a range between 20 μm and 700 μm. These values are merely examples and are not intended to be limiting. The third substrate 90 may comprise a semiconductor device including but not limited to a transistor, a diode, a capacitor, and a resistor. In some embodiments, the interconnect structure and/or the semiconductor devices in the third substrate 90 (not shown) may be electrically coupled to the first ohmic contact 61 and/or the third ohmic contact 63. In one embodiment, the interconnect structure 80 may be omitted, and the interconnect structure(s) in the third substrate 90 (not shown) may be electrically coupled to the first ohmic contact 61 and/or the third ohmic contact 63. In some embodiments, the third substrate 90 may be bonded onto the second substrate 40 by performing suitable process(es) such as adhesive bonding or direct bonding. In some embodiments, the third substrate 90 may be formed on the second substrate 40 by epitaxial growth, CVD, PVD, and/or ALD. The third substrate 90 may provide mechanical support to the semiconductor structure to avoid fractures and cracks generated during the subsequent manufacturing process.

As shown in FIG. 1G, the first substrate 10 and the bonding layer 20 are removed to expose the etch stop layer 30. The first substrate 10 and the bonding layer 20 can be removed by performing suitable process(es) such as grinding, chemical mechanical polishing (CMP), and etching process. In one embodiment, the first substrate 10 is removed by grinding and/or CMP process, and the bonding layer 20 can be removed by applying a first etchant, e.g., dilute HF (e.g., a weight ratio of H₂O to HF at about 100:1). In one embodiment, when using dilute HF as an etchant, the etch stop layer 30 (e.g., silicon nitride) may be exposed after removing the bonding layer 20 (e.g., silicon oxide) due to etch selectivity. In the embodiment shown in FIG. 1G, the etch stop layer 30 can protect the first dielectric structure 21 and the structures in the second substrate 40 from the etching process.

As shown in FIG. 1H, at least a portion of the etch stop layer 30 is removed. The etch stop layer 30 may be removed by oxide etching, plasma etching, hydrogen peroxide etching, the like, and/or any suitable method. In one embodiment, the etch stop layer 30 comprising silicon nitride can be removed by applying a second etchant, e.g., hot phosphoric acid. The disclosure is not limited thereto. At least a portion of a second surface 40b of the second substrate 40 is exposed after the removal of the etch stop layer 30. By methods disclosed herein, the exposed second surface 40b of the second substrate 40 may have better planarity, thus the heights of the diodes formed may be more uniform and more controllable. Also, endpoint of etching process that removes the bonding layer 20 may be easier to control. In the embodiment shown in FIG. 1H, the etch stop layer 30 is completely removed. However, in other embodiments, only a portion of the etch stop layer 30 may be removed (e.g., the portion of the etch stop layer 30 overlapped with the first diode 45 and the second diode 46 is removed) by suitable methods such as photolithography and etching process. For example, when the etch stop layer 30 comprises silicon nitride, dry etching can be performed by remote plasma using NF₃ as an etching gas to remove only a portion of the etch stop layer 30.

As shown in FIG. 1I, a second doped region 42 of the first diode 45 is formed in the second substrate 40 (step (f)) after removing the bonding layer 20 and exposing the second surface 40b of the second substrate 40. The second doped region 42 may be formed extending from a second surface 40b of the second substrate 40. The second doped region 42 may be formed in the region over the first doped region 41, such that the second doped region 42 is formed in contact with the first doped region 41. In some embodiments, the second doped region 42 may be doped with the second conductivity-type of dopant. In some embodiments, the doping concentration of the second doped region 42 may be from about 1.0×10¹⁸ atoms/cm³ to about 3.0×10²⁰ atoms/cm³. In one embodiment, the thickness of the second doped region 42 may be in a range between 2 nm and 100 nm. These values are merely examples and are not intended to be limiting. The second doped region 42 may be formed by ion implantation or epitaxial growth. In some other embodiments, at least a portion of the second doped region 42 may be formed on the second surface 40b of the second substrate 40, e.g., through epitaxial growth. Details and formation methods of the second doped region 42 may be substantially similar to that of the third doped region 43 described above with respect to FIG. 1B.

The second doped region 42 may comprise a second heavily-doped region 42a. In the embodiment shown in FIG. 1I, the second heavily-doped region 42a may be formed extending from a second surface 40b of the second substrate 40. In some embodiment, the second heavily-doped region 42a may be doped with the second conductivity-type of dopant. In some embodiments, the second heavily-doped region 42a may have a higher doping concentration than the second doped region 42. In some embodiments, the doping concentration of the second heavily-doped region 42a may be from about 1.0×10¹⁹ atoms/cm³ to about 5.0×10²⁰ atoms/cm³. In one embodiment, the thickness of the second heavily-doped region 42a may be in a range between 1 nm and 50 nm. These values are merely examples and are not intended to be limiting. Details and formation methods of the second heavily-doped region 42a may be substantially similar to that of the third heavily-doped region 43a described above with respect to FIG. 1B.

A fourth heavily-doped region 44a may be formed on the second surface 40b of the second substrate 40. The fourth heavily-doped region 44 may be formed after the second surface 40b of the second substrate 40 is exposed. In some embodiment, the fourth heavily-doped region 44a may be doped with a first conductivity-type of dopant, which is the same as the second substrate 40. In some embodiments, the fourth heavily-doped region 44a may have a higher doping concentration than the second substrate 40 (and the fourth doped region 44). In some embodiments, the doping concentration of the fourth heavily-doped region 44a may be from about 1.0×10¹⁹ atoms/cm³ to about 5.0×10²⁰ atoms/cm³. In one embodiment, the thickness of the fourth heavily-doped region 44a may be in a range between 1 nm and 50 nm. These values are merely examples and are not intended to be limiting. Details and formation methods of the fourth heavily-doped region 44a may be substantially similar to that of the first heavily-doped region 41a described above with respect to FIG. 1B.

In some embodiments, the second doped region 42 and the third doped region 43 may have similar doping concentrations, and the second heavily-doped region 42 and the third heavily-doped region 43 may have similar doping concentrations. In some embodiments, the fourth heavily-doped region 44a and the first heavily-doped region 41a may have similar doping concentrations.

As shown in FIG. 1J, a second ohmic contact 62 and a fourth ohmic contact 64 may be formed. The second ohmic contact 62 and the fourth ohmic contact 64 may be formed on the second surface 40b of the second substrate 40. Each of the second ohmic contact 62 and the fourth ohmic contact 64 may be patterned. In the embodiment shown in FIG. 1J, the second ohmic contact 62 may be formed over and overlapped with the first ohmic contact 61. The second ohmic contact 62 may be formed over and in contact with the second doped region 42, and an ohmic junction may be formed between the second ohmic contact 62 and the second heavily doped region 42a. In the embodiment shown in FIG. 1J, the fourth ohmic contact 64 may be formed over and overlapped with the third ohmic contact 63. The fourth ohmic contact 64 may be formed over and in contact with the fourth doped region 44, and an ohmic junction may be formed between the fourth ohmic contact 64 and the fourth heavily-doped region 44a. In one embodiment, the thickness of the second ohmic contact 62 may be in a range between 2 nm and 100 nm. In one embodiment, the thickness of the fourth ohmic contact 64 may be in a range between 2 nm and 100 nm. These values are merely examples and are not intended to be limiting. In some embodiments, the second ohmic contact 62 and the fourth ohmic contact 64 may have similar thickness.

Each of the second ohmic contact 62 and the fourth ohmic contact 64 may be formed using similar materials and similar methods as that of the first ohmic contact 61 and the third ohmic contact 63 described above with reference to FIG. 1C. In some embodiments, one or more stacked dielectric layers of first dielectric structure 21 may be formed on the second surface 40b of the second substrate 40, and the second ohmic contact 62 and/or the fourth ohmic contact 64 may be formed in the first dielectric structure 21 using a damascene or dual damascene process or any suitable method. In some other embodiments, the second doped region 42 and/or the fourth doped region 44 may be etched to form trench(es), and the fourth ohmic contact 64 and/or the second ohmic contact 62 may be formed in the trench(es) in the second substrate 40. In some embodiments, the second ohmic contact 62 and the fourth ohmic contact 64 may have the same composition; however, in some other embodiments, the second ohmic contact 62 and the fourth ohmic contact 64 may have different compositions according to actual needs. The compositions of the second ohmic contact 62 and the fourth ohmic contact 64 and the doping concentrations of the second heavily-doped region 42a and the fourth heavily-doped region 44a may be adjusted according to desired diode properties.

As shown in FIG. 1J, a memory unit 100 is formed (step (h)). The memory unit 100 may have a first end 101 and a second end 102. In the embodiment shown in FIG. 1J, the memory unit 100 is formed over a wiring layer 72. The wiring layer 72 may comprise conductive features (e.g., conductive lines or vias) connected with both the first diode 45 and the second diode 46, and the memory unit 100 may be electrically coupled to the conductive features from the second end 102 of the memory unit 100, such that the memory unit 100 is electrically coupled to both the first diode 45 and the second diode 46 through the wiring layer 72. The wiring layer 72 may comprise Pt, Pd, Ir, Ru, Cu, W, some other suitable material(s), or a combination of the foregoing and may be formed in the first dielectric structure 21 using a damascene or dual damascene process or any suitable method. In some embodiments, the second ohmic contact 62 of the first diode 45 may be connected with the fourth ohmic contact 64 of the second diode 46, such that an additional wiring layer (e.g., the wiring layer 72 in FIG. 1J) may not be required, and the memory unit 100 is in contact with the second ohmic contact 62 and/or the fourth ohmic contact 64 at the second end 102 of the memory unit 100.

The memory unit 100 may comprise a magnetic tunnel junction (MTJ) structure, a phase-change material, or a variable resistance material. The MTJ structure may comprise a free magnetic layer, a fixed magnetic layer, and a tunnel barrier layer between the free magnetic layer and the fixed magnetic layer. The fixed magnetic layer may have a fixed magnetization and the free magnetic layer may have a magnetization switchable by a program current. The orientation of magnetization in the free magnetic layer relative to that of the fixed magnetic layer may determine whether the MTJ structure is in a high resistance state or a low resistance state (e.g., whether the memory unit is storing a “1” or a “0”). For example, if the magnetization of the free magnetic layer and the fixed magnetic layer are in a parallel orientation, the MTJ structure may be in a low resistance state (e.g., “0” state); and if the magnetization of the free magnetic layer and the fixed magnetic layer are in an oppositional (anti-parallel) orientation, the MTJ structure may be in a high resistance state (e.g., “1” state). Data writing can be performed by switching the orientation of the magnetization of the free magnetic layer. In some embodiments, to enhance the performance of the MTJ structure, the free magnetic layer and/or the fixed magnetic layer may include a multilayer structure. In some embodiments, an anti-ferromagnetic (AFM) layer may be added between an electrode and the fixed magnetic layer, which allows for canceling the dipole fields around the free magnetic layer. The MTJ structure may be formed by any suitable method and any material suitable for each layer thereof. In the embodiment shown in FIG. 1J, the memory unit 100 is formed after the formation of the second ohmic contact 62 and the fourth ohmic contact 64. However, the present disclosure is not limited thereto.

As shown in FIG. 1J, a bit line 75 is formed over the memory unit 100. The memory unit 100 may be electrically coupled to the bit line 75 from the first end 101 of the memory unit 100. The bit line 75 may comprise Pt, Pd, Ir, Ru, Cu, W, some other suitable material(s), or a combination of the foregoing. In some embodiments, the bit line 75 may be formed in the first dielectric structure 21 using a damascene or dual damascene process or any suitable method.

Referring to FIG. 1J, a semiconductor structure 104 comprising a first diode 45 and a second diode 46 is provided. The first diode 45 comprises a first doped region 41 and a second doped region 42. The second doped region 42 is disposed over and in contact with the first doped region 41, such that a top surface 42TS of the second doped region 42 is higher than a bottom surface 41BS of the first doped region 41. The second diode 46 comprises a third doped region 43 and a fourth doped region 44. The fourth doped region 44 is disposed over and in contact with the third doped region 43, such that a top surface 44TS of the fourth doped region 44 is higher than a bottom surface 43BS of the third doped region 43. Each of the first doped region 41 and the fourth doped region 44 may be doped with a first conductivity-type of dopant (as the second substrate 40 described above), and each of the second doped region 42 and the third doped region 43 is doped with a second conductivity-type of dopant opposite to the first conductivity-type.

For ease of description, the expression “top surface”, “bottom surface”, and “higher” herein describes one element or feature's relationship to another element(s) or feature(s) as illustrated in FIG. 1J. It will be understood that the spatially relative terms are intended to encompass different orientations of the device in use or operation in addition to the orientation depicted in the figures. For example, if the device in the figures is turned over, elements described as “higher” than other elements or features would then be oriented “lower” than the other elements or features. The structure may be otherwise oriented (rotated 90 degrees or at other orientations) and the spatially relative descriptors used herein are interpreted accordingly.

As shown in FIG. 1J, the top surface 42TS of the second doped region 42 is higher than the bottom surface 43BS of the third doped region 43; and the top surface 44TS of the fourth doped region 44 is higher than a bottom surface 41BS of the first doped region 41. In other words, the first diode 45 may be located at about the same level as the second diode 46, while the first diode 45 and the second diode 46 are arranged in opposite directions.

Generally speaking, adjacent PN diodes located in substantially the same layer are formed, e.g., through formation of semiconductor material layer(s) and/or metal layer(s) and subsequent patterning process, to be arranged in identical direction. However, by methods disclosed herein, adjacent PN diodes located in substantially the same layer can be formed as being arranged in opposite direction. In other words, diodes in a pair of the PN diodes arranged in opposite direction may be formed at about the same level, which may render a simplified routing and a reduced thickness of the semiconductor structure.

In the embodiment shown in FIG. 1J, the bottom surface 41BS of the first doped region 41 may be substantially level with the bottom surface 43BS of the third doped region 43. The top surface of the second doped region 42 may be substantially level with the top surface 44TS of the fourth doped region 44.

In the embodiment shown in FIG. 1J, each of the first doped region 41 and the fourth doped region 44 may comprise a single crystalline semiconductor material. Each of the second doped region 42 and the third doped region 43 may also comprise a single crystalline semiconductor material. The single crystalline semiconductor material can be, for example, made of silicon, germanium, silicon germanium, gallium arsenide (GaAs), indium phosphide (InP), silicon carbide (SiC), or gallium nitride (GaN).

In some embodiments, the doping concentration of the first doped region 41, and the fourth doped region 44 may each be from about 1.0×10¹⁸ atoms/cm³ to about 3.0×10²⁰ atoms/cm³. In some embodiments, the doping concentration of the second doped region 42 and the third doped region 43 may each be from about 1.0×10¹⁸ atoms/cm³ to about 3.0×10²⁰ atoms/cm³. In some embodiments, the thickness of the first doped region 41 may be in a range between 2 nm and 100 nm. In some embodiments, the thickness of the fourth doped region 44 may be in a range between 2 nm and 100 nm. In some embodiments, the thickness of the second doped region 42 may be in a range between 2 nm and 100 nm. In some embodiments, the thickness of the third doped region 43 may be in a range between 2 nm and 100 nm. These values are merely examples and are not intended to be limiting. In some embodiments, the first doped region 41 and the third doped region 43 may have substantially the same thickness. In some embodiments, the second doped region 42 and the fourth doped region 44 may have substantially the same thickness.

As shown in FIG. 1J, the first diode 45 may further comprise a first ohmic contact 61 in contact with the bottom surface 41BS of the first doped region 41, and the second diode 46 may further comprise a fourth ohmic contact 64 in contact with the top surface 44TS of the fourth doped region 44. In some embodiments, the first diode 45 may further comprise a second ohmic contact 62 in contact with the top surface 42TS of the second doped region 42, and the second diode 46 may further comprise a third ohmic contact 63 in contact with the bottom surface 43BS of the third doped region 43.

The first doped region 41 may further comprise a first heavily-doped region 41a extending from the bottom surface 41BS of the first doped region 41. The fourth doped region 44 may further comprise a fourth heavily-doped region 44a extending from the top surface 44TS of the fourth doped region 44. Each of the first heavily-doped region 41a and the fourth heavily-doped region 44a is doped with the first conductivity-type of dopant. An ohmic junction may be formed between the first ohmic contact 61 and the first heavily-doped region 41a, and an ohmic junction may be formed between the fourth ohmic contact 64 and the fourth heavily-doped region 44a.

The second doped region 42 may further comprise a second heavily-doped region 42a extending from the top surface 42TS of the second doped region 42. The third doped region 43 may further comprise a third heavily-doped region 43a extending from the bottom surface 43BS of the third doped region 43. Each of the second heavily-doped region 42a and the third heavily-doped region 43a is doped with the second conductivity-type of dopant. An ohmic junction may be formed between the second ohmic contact 62 and the second heavily-doped region 42a, and an ohmic junction may be formed between the third ohmic contact 63 and the third heavily-doped region 43a.

In the embodiment shown in FIG. 1J, the first doped region 41 and the second doped region 42 of the first diode 45 are vertically aligned, and the first doped region 41 is in contact with the second doped region 42, such that the first doped region 41 and the second doped region 42 may function together as a vertical PN diode. The third doped region 43 and the fourth doped region 44 of the second diode 46 are vertically aligned, and the third doped region 43 is in contact with the fourth doped region 44, such that the third doped region 43 and the fourth doped region 44 may function together as a vertical PN diode. As shown in FIG. 1J, the sidewalls of the first doped region 41 and the second doped region 42 may be substantially aligned, and the sidewalls of the third doped region 43 and the fourth doped region 44 may be substantially aligned. This may minimize the size of a unit cell. However, the present disclosure is not limited thereto.

Referring to FIG. 1J, a semiconductor structure 105 is provided. The semiconductor structure 105 comprises the first diode 45 and the second diode 46, as described above, and a memory unit 100. In some embodiments, the memory unit 100 may comprises a magnetic tunnel junction (MTJ) structure. The memory unit 100 may have a first end 101 and a second end 102. In the embodiment shown in FIG. 1J, the memory unit 100 is electrically coupled to both the first diode 45 and the second diode 46 from the second end 102 of the memory unit 100. The memory unit 100 may be electrically coupled to both the second doped region 42 of the first diode 45 and the fourth doped region 44 of the second diode 46. In some other embodiments, the memory unit 100 may comprises a phase-change material.

The semiconductor structure 105 shown in FIG. 1J may be a spin-transfer torque type MRAM (STT-MRAM) device. For example, to conduct a data writing process, a program current may flow along a first current flow path from the second diode 46 to the bit line 75 through the wiring layer 72 and the memory unit 100; or, a program current may flow along a second current flow path from the bit line 75 to the first diode 45 through the memory unit 100 and the wiring layer 72. Despite that only one memory cell is illustrated in FIGS. 1A-1J, a plurality of memory cells or an array of memory cells can be fabricated at the same time using the method disclosed herein.

In the embodiment shown in FIGS. 1A to 1J, a memory device including a pair of PN diodes as a selector can be fabricated using the method disclosed herein. By including the first diode 45 and the second diode 46 arranged in opposite directions while being located at about the same level as discussed above with regard to FIG. 1J, the memory device disclosed herein may have a simplified routing structure and a reduced cell size and may be easy to fabricate. The memory device disclosed herein may also provide higher current density compared to a memory device using a transistor as selector and may have desired properties such as a greater efficiency, a faster memory access, and a low-power consumption.

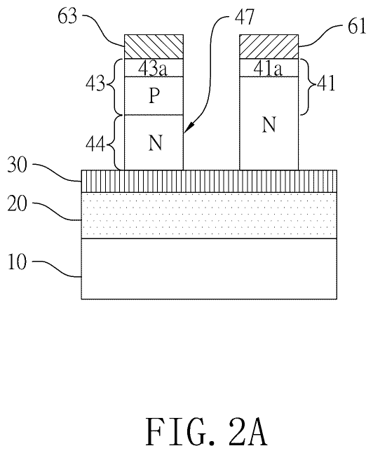

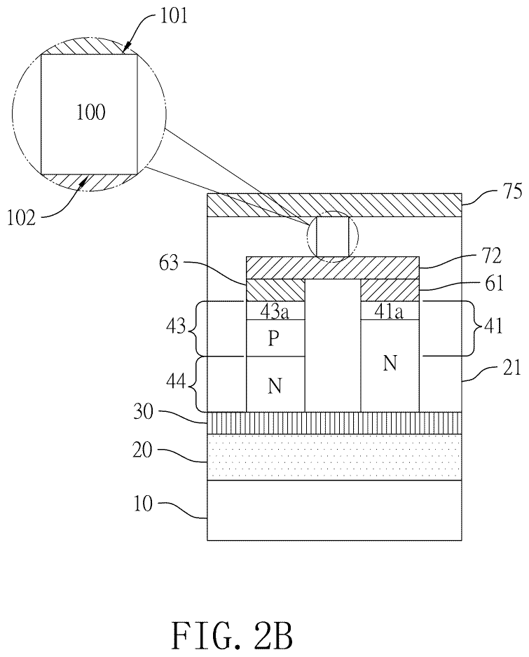

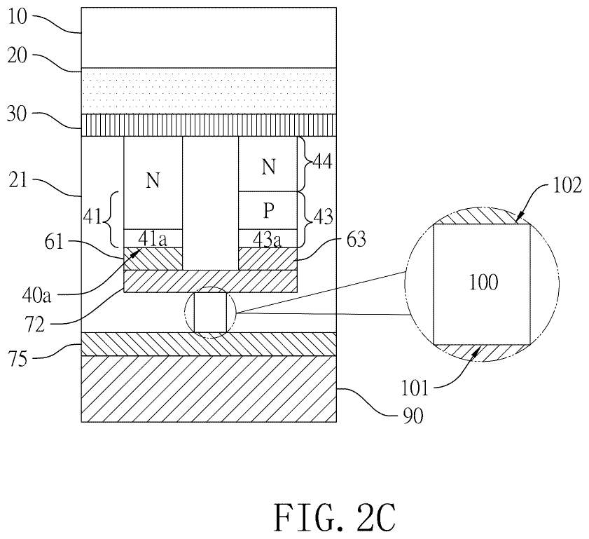

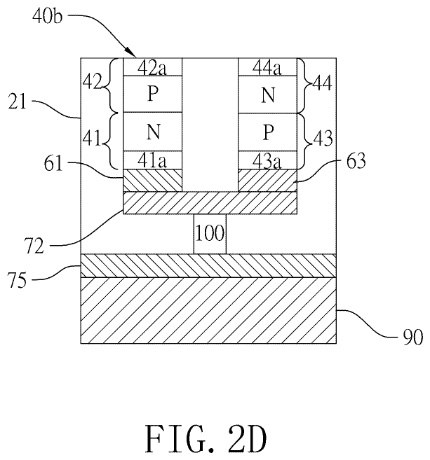

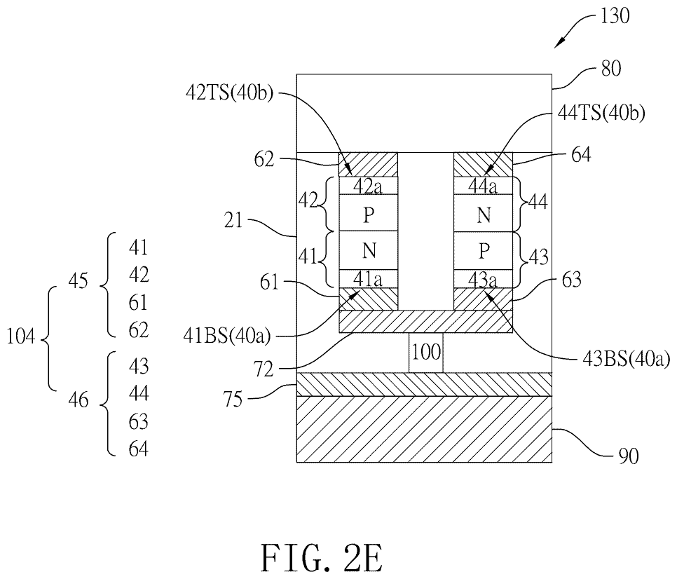

FIGS. 2A to 2E are schematic diagrams illustrating intermediate stages in the manufacture of a semiconductor structure according to one embodiment of the present disclosure. As shown in FIG. 2A, a third doped region 43, a third heavily-doped region 43a, a first heavily-doped region 41a, a first ohmic contact 61, and a third ohmic contact 63 are formed, and a first doped region 41 and a third doped region 43 are defined through patterning the second substrate 40. Details and formation methods of the semiconductor structure shown in FIG. 2A may be substantially similar to that described above with respect to FIGS. 1A-1D, where like reference numerals indicate like elements.

As shown in FIG. 2B, a first dielectric structure 21 is formed. The first dielectric structure 21 may be formed by similar material(s) and process(es) described above with respect to FIG. 1E, and the related description is omitted for brevity.

Alternatively, in some other embodiments, the first doped region 41 and the fourth doped region 44 may be defined before the formation of the first ohmic contact 61 and/or the third ohmic contact 63. For example, the first dielectric structure 21 may be formed in the trench 47 separating the third doped region 43 and the fourth doped region 44 from the first doped region 41, and the first ohmic contact 61 and/or the third ohmic contact 63 may be formed in the first dielectric structure 21 using a damascene or dual damascene process or any suitable method to form the structure shown in FIG. 2B.

As shown in FIG. 2B, a memory unit 100 is formed (step (h)). Details and formation methods of the memory unit 100 may be similar to that described above with respect to FIG. 1J, and the related description is omitted for brevity. In the embodiment shown in FIG. 2B, the memory unit 100 is electrically coupled to both the first diode 45 and the second diode 46 from the second end 102 of the memory unit 100. The memory unit 100 may be electrically coupled to the first ohmic contact 61. The memory unit 100 may also be electrically coupled to the third ohmic contact 63. In the embodiment shown in FIG. 2B, a wiring layer 72 coupled to the first ohmic contact 61 and the third ohmic contact 63 is formed, and the memory unit 100 is formed over the wiring layer 72. The materials and processes for forming the wiring layer 72 may be similar to that described above with respect to FIG. 1J, and the related description is omitted for brevity. In some embodiments, the first ohmic contact 61 may be connected with the third ohmic contact 63, such that an additional wiring layer (e.g., the wiring layer 72 in FIG. 2B) may not be required.

As shown in FIG. 2B, a bit line 75 is formed over the memory unit 100. The bit line 75 may be formed by similar material(s) and process(es) described above with respect to FIG. 1J, and the related description is omitted for brevity.

As shown in FIG. 2C, a third substrate 90 is added to a first surface 40a of the second substrate 40, wherein the second substrate 40 is located between the third substrate 90 and the first substrate 10 (step (d)). Methods of formation and/or attachment and details of the third substrate 90 may be similar to that described above with respect to FIG. 1F, and the related description is omitted for brevity. As shown in FIG. 2C, the memory unit 100 may be located between the second substrate 40 and the third substrate 90.

As shown in FIG. 2D, the first substrate 10 and the bonding layer 20 are removed to expose the etch stop layer 30. The removal of the first substrate 10 and the bonding layer 20 may be substantially similar to the processes described above with respect to FIG. 1G, and the related description is omitted for brevity. Also, as shown in FIG. 2D, at least a portion of the etch stop layer 30 is removed. The removal of the etch stop layer 30 may be substantially similar to the processes described above with respect to FIG. 1H, and the related description is omitted for brevity.

As shown in FIG. 2D, a second doped region 42 of the first diode is formed in the second substrate 40 (step (f)) after removing the bonding layer 20 and exposing a second surface 40b of the second substrate 40 (step (e)). The second doped region 42 may further comprise a second heavily-doped region 42a extending from a second surface 40b of the second substrate 40. A fourth heavily-doped region 44a may also be formed extending from a second surface 40b of the second substrate 40. Details and formation method of the second doped region 42, the second heavily-doped region 42a, and the fourth heavily-doped region 44a may be substantially similar to that described above with respect to FIG. 1I, and the related description is omitted for brevity.

As shown in FIG. 2E, a second ohmic contact 62 of the first diode 45 and a fourth ohmic contact 64 of the second diode 46 may be formed on the second surface 40b of the second substrate 40 (step (f)). Details and formation methods of the second ohmic contact 62 and the fourth ohmic contact 64 may be substantially similar to that described above with respect to FIG. 1J, and the related description is omitted for brevity.

As shown in FIG. 2E, interconnect structure 80 may be formed over the first dielectric structure 21. The interconnect structure 80 may include conductive features (e.g., conductive lines and vias). In the embodiment shown in FIG. 2E, the interconnect structure 80 may be electrically coupled to the second ohmic contact 62 and/or the fourth ohmic contact 64. In some embodiments, the interconnect structure 80 may include a plurality of word lines. In some embodiments, the interconnect structure 80 may be electrically connected to other devices, such as a control circuit, a memory unit, etc. As shown in FIG. 2E, the interconnect structure 80 is formed over the second surface 40b of the second substrate 40. The interconnect structure 80 may comprise titanium nitride, tantalum nitride, tungsten, ruthenium, aluminum, copper, some other suitable material(s), or a combination of the foregoing and may be formed by using of a damascene or dual damascene process or any suitable method.

In some other embodiments, instead of forming interconnect structure 80 over the second ohmic contact 62 and the fourth ohmic contact 64, interconnect structure may be formed in the same layer as the second ohmic contact 62 and the fourth ohmic contact 64. In some other embodiments, the interconnect structure 80 may be omitted. For example, instead of forming extra wiring layers, the second ohmic contact 62 and/or the fourth ohmic contact 64 may extend and provide electrical connection between devices.

Referring to FIG. 2E, a semiconductor structure 104 comprising a first diode 45 and a second diode 46 is provided. The semiconductor structure 104 shown in FIG. 2E may be substantially similar to the semiconductor structure 104 described above with respect to FIG. 1I, where like reference numerals indicate like elements. Related details of the semiconductor structure 104 described above may apply here if applicable.

Referring to FIG. 2E, a semiconductor structure 130 is provided. The semiconductor structure 130 comprises the first diode 45 and the second diode 46, as described above, and a memory unit 100. The memory unit 100 may have a first end 101 and a second end 102. In the embodiment shown in FIG. 2E, the memory unit 100 is electrically coupled to both the first diode 45 and the second diode 46 from the second end 102 of the memory unit 100. The semiconductor structure 130 shown in FIG. 2E may be a STT-MRAM device. For example, to conduct a data writing process, a program current may flow along a first current flow path from the first diode 45 to the bit line 75 through the wiring layer 72 and the memory unit 100; or, a program current may flow along a second current flow path from the bit line 75 to the second diode 46 through the memory unit 100 and the wiring layer 72. All other descriptions of the semiconductor structure 105 shown in FIG. 1J may apply here if applicable.

In the embodiment shown in FIGS. 2A to 2E, a memory device including a pair of PN diodes as a selector can be fabricated using the method disclosed herein, which may provide additional options for the manufacturing of the memory device including vertical PN diodes.

FIGS. 3A to 3I are schematic diagrams illustrating intermediate stages in the manufacture of a semiconductor structure according to one embodiment of the present disclosure. As shown in FIG. 3A, a first structure 200A and a second structure 200B are provided. The first structure 200A comprises a first substrate 10. The second structure 200B comprises a second substrate 40 and an etch stop layer 30 on the second substrate 40. The first substrate 10 and the second substrate 40 shown in FIG. 3A may be substantially similar to the first substrate 10 and the second substrate 40 described above with respect to FIG. 1A, and related details described above with respect to FIG. 1A may apply here if applicable.

The etch stop layer 30 may comprise silicon nitride, silicon oxynitride, doped semiconductor material, undoped semiconductor material, metal, conductive metal compound, or combinations thereof. The etch stop layer 30 may have a high etch selectivity against the bonding layer 20 shown in FIG. 3C, other related details of the etch stop layer 30 described above with respect to FIG. 1A may apply here if applicable. The etch stop layer 30 may be formed on a second surface 40b of the second substrate 40. In one embodiment, the etch stop layer 30 may be formed by epitaxial growth or by deposition such as chemical vapor deposition (CVD), physical vapor deposition (PVD), or atomic layer deposition (ALD). In one embodiment, the etch stop layer 30 may be formed by sputtering or evaporation.

In the embodiment shown in FIG. 3A, the second substrate 40 further comprises an implanted hydrogen layer 110 inside the second substrate 40. The implanted hydrogen layer 110 is implanted inside the second substrate 40 at a certain depth before the bonding of the first structure 200A and the second structure 200B. The implantation may be conducted before or after the formation of the etch stop layer 30 as long as the implanted hydrogen layer 110 will not be damaged by the succeeding processes. For example, if the formation of the etch stop layer 30 requires high temperature (e.g., annealing process), the hydrogen probably should be implanted after the formation of the etch stop layer 30. In one embodiment, hydrogen ions are implanted into the second substrate 40 using a dosage of 1×10¹⁶ ions/cm² to 2×10¹⁷ ions/cm² at an implantation energy of 50 KeV to 150 KeV. A larger dosage can be used with larger substrates. The implanted hydrogen layer 110 may be formed at a depth of about 4×10⁻⁵ inch to about 8×10⁻⁵ inch (1 to 2 μm) from the second surface 40b of the second substrate 40. These values are merely examples and are not intended to be limiting. In one embodiment, since the thicknesses of the etch stop layer 30 (and, in some embodiments, the second dielectric layer 122 shown in FIG. 3B) are known, the proper implantation voltage can be selected to have the peak of the implanted hydrogen occur at the desired depth below the etch stop layer 30. In one embodiment, when the etch stop layer 30 comprises a metal, the implantation may be conducted before the formation of the etch stop layer 30.

As shown in FIG. 3A, the second substrate 40 further comprises a second doped region 42 of a second diode 46 extending from the second surface 40b of the second substrate 40. The second doped region 42 may comprise a second heavily-doped region 42a extending from the second surface 40b of the second substrate 40. The second substrate 40 may further comprise a fourth heavily-doped region 44a extending from the second surface 40b of the second substrate 40. The materials and formation method of the second doped region 42, the second heavily-doped region 42a, and the fourth heavily-doped region 44a may be similar to that described above with respect to FIG. 1I, and the related description is omitted for brevity. In some embodiments, the formation of the second doped region 42, the second heavily-doped region 42a, and the fourth heavily-doped region 44a involves a high-temperature annealing process so that the second doped region 42, the second heavily-doped region 42a, and the fourth heavily-doped region 44a may be formed before the implantation of the hydrogen layer. In some embodiments, the second doped region 42, the second heavily-doped region 42a, and the fourth heavily-doped region 44a may be formed before the formation of the etch stop layer 30.

As shown in FIG. 3B, a first dielectric layer 121 is formed on the first substrate 10, and a second dielectric layer 122 is formed on the etch stop layer 30 before the bonding of the first structure 200A and the second structure 200B. In one embodiment, only one of the first dielectric layer 121 and the second dielectric layer 122 is formed before the bonding of the first structure 200A and the second structure 200B. In one embodiment, the first dielectric layer 121 and/or the second dielectric layer 122 may be formed by thermal oxidation or deposition such as CVD, PVD, or ALD. In some embodiments, the first dielectric layer 121 and/or the second dielectric layer 122 comprises silicon oxide. In some embodiments, the implantation process for the formation of the implanted hydrogen layer 70 may be conducted after the formation of the second dielectric layer 122.

As shown in FIG. 3C, the second structure 200B is flipped and bonded onto the first structure 200A by a bonding layer 20 to form a bonded structure 200C. In the embodiment shown in FIG. 3C, the first dielectric layer 121 and the second dielectric layer 122 are bonded to form the bonding layer 20. In the embodiments where only one of the first dielectric layer and the second dielectric layer is formed before bonding, the one of the first dielectric layer 121 and the second dielectric layer 122 forms the bonding layer 20. The bonding layer 20 shown in FIG. 3C may be substantially similar to the bonding layer 20 described above with respect to FIG. 1A, and the related description are omitted for brevity. For example, the second structure 200B may be bonded to the first structure 200A by a fusion bonding process, such as a hydrophilic fusion bonding process. In one embodiment, both the first dielectric layer 121 and the second dielectric layer 122 are cleaned by conventional cleaning techniques such as the RCA wafer cleaning procedure. The cleaning process removes surface impurities and particles from the surfaces of the dielectric layers 121 and 122. In one embodiment, hydroxyl groups (OH⁻) are formed on the surfaces to be bonded due to the presence of electric charges of atoms. Hydrogen bonds may be formed between the first dielectric layer 121 and the second dielectric layer 122 and an annealing process to form chemical bonds (e.g., Si—O bond) between the surfaces of the first dielectric layer 121 and the second dielectric layer 122 may be performed.

As shown in FIG. 3D, a portion of the second substrate 40 is removed from the bonded structure 200C approximately at the implanted hydrogen layer 110. The portion of the second substrate 40 may be removed by heating the bonded structure 200C at a first temperature. The first temperature is usually below 400° C. to avoid any damage to the semiconductor device or portions thereof fabricated in the second substrate 40 if there is any. In some embodiments, a portion of the second substrate 40 may be removed by other methods, as long as the portion of the second substrate 40 has been sufficiently weakened by previous hydrogen implantation and some subsequent annealing. For example, the bonded structure 200C can be cleaved by applying mechanical pressure to the second substrate 40 or by dipping and quenching the bonded structure 200C in liquid nitrogen.

The portion of the second substrate 40 remaining on the bonded structure 200C may be less than 3 μm based on the implanted depth of the implanted hydrogen layer 110. The thickness of the remaining portion of the second substrate 40 may also depend on the semiconductor manufacturing technology nodes applied for the fabrication of various semiconductor devices. After removal, a first surface 40a of the second substrate 40 is formed. The exposed surface of the second substrate 40 usually has a roughness on the order of a few hundred angstroms. The exposed surface of the second substrate 40 may be polished by chemical mechanical polishing (CMP) to planarize and minimize the non-uniformity to form the first surface 40a. Other approaches such as etching may be used for the same purpose. Another etch stop layer (not shown) may need to be deposited in advance when etching is used to planarize and minimize the non-uniformity to form the first surface 40a of the second substrate 40. Hence, a semiconductor substrate 200 is provided (step (a)). The semiconductor substrate 200 may be substantially similar to the semiconductor substrate A1 described above with respect to FIG. 1A, where like reference numerals indicate like elements. The semiconductor structure 200 may be used to fabricate various types of semiconductor devices as described following.

As shown in FIG. 3E, a third doped region 43 of a second diode 46 is formed in the second substrate 40 extending from the first surface 40a of the second substrate 40 (step (b)). The third doped region 43 may further comprise a third heavily-doped region 43a extending from the first surface 40a of the second substrate 40. The second substrate 40 may further comprise a first heavily-doped region 41a extending from the first surface 40a of the second substrate 40. Details and processes for forming the first heavily-doped region 41a, the third doped region 43, and the third heavily-doped region 43a may be substantially similar to that described above with respect to FIG. 1A, and the related description is omitted for brevity.

In the embodiment shown in FIG. 3F, a first ohmic contact 61 of the first diode and a third ohmic contact 63 of the second diode is formed on the first surface 40a of the second substrate 40. Details and processes for forming the first ohmic contact 61 and a third ohmic contact 63 may be substantially similar to that described above with respect to FIG. 1B, and the related description is omitted for brevity.

As shown in FIG. 3F, the second substrate 40 is patterned to define a first doped region 41 of the first diode 45 and a fourth doped region 44 of a second diode 46 (step (c)). The patterning processes may be substantially similar to the process described above with respect to FIG. 1D, and the related description is omitted for brevity.

As shown in FIG. 3G, a first dielectric structure 21 is formed. An interconnect structure 80 may be formed over the first dielectric structure 21. The materials and processes for forming the first dielectric structure 21 and the interconnect structure 80 may be substantially similar to that described above with respect to FIG. 1E, and the related description is omitted for brevity.

Alternatively, in some other embodiments, the first doped region 41 and the fourth doped region 44 may be defined before the formation of the first ohmic contact 61 and/or the third ohmic contact 63. For example, the first dielectric structure 21 may be formed in the trench 47 separating the third doped region 43 and the fourth doped region 44 from the first doped region 41, and the first ohmic contact 61 and/or the third ohmic contact 63 may be formed in the first dielectric structure 21 using a damascene or dual damascene process or any suitable method to form the structure shown in FIG. 3G.

As shown in FIG. 3H, a third substrate 90 is added to the first surface 40a of the second substrate 40, wherein the second substrate 40 is located between the third substrate 90 and the first substrate 10 (step (d)). Methods of formation and/or attachment and details of the third substrate 90 may be similar to that described above with respect to FIG. 1F, and the related description is omitted for brevity.

As shown in FIG. 3H, the first substrate 10 and the bonding layer 20 are removed to expose the etch stop layer 30. The removal of the first substrate 10 and the bonding layer 20 may be substantially similar to the processes described above with respect to FIG. 1G, and the related description is omitted for brevity. Then, at least a portion of the etch stop layer 30 is removed to expose the second surface 40b of the second substrate 40. As shown in FIG. 3H, the second doped region 42 of the first diode 45 in the second substrate 40 extending from a second surface 40b of the second substrate 40 may be exposed (step (f)) after removing the bonding layer 20. The fourth heavily-doped region 44a extending from a second surface 40b of the second substrate 40 may also be exposed. The removal of the etch stop layer 30 may be substantially similar to the processes described above with respect to FIG. 1H, and the related description is omitted for brevity.

In the embodiment shown in FIG. 3I, a second ohmic contact 62 and the fourth ohmic contact 64 is formed on the second surface 40b of the second substrate 40. Details and formation methods of the second ohmic contact 62 and the fourth ohmic contact 64 may be substantially similar to that described above with respect to FIG. 1J, and the related description is omitted for brevity.

As shown in FIG. 3I, a memory unit 100 is formed (step (h)). Details and formation methods of the memory unit 100 may be similar to that described above with respect to FIG. 1J, and the related description is omitted for brevity. In the embodiment shown in FIG. 3I, a wiring layer 72 coupled to the second ohmic contact 42 and the fourth ohmic contact 64 is formed, and the memory unit 100 is formed over the wiring layer 72. The materials and processes for forming the wiring layer 72 may be similar to that described above with respect to FIG. 1J, and the related description is omitted for brevity. A bit line 75 may be formed over the memory unit 100. The materials and processes for forming the bit line 75 may be similar to that described above with respect to FIG. 1J, and the related description is omitted for brevity. In some embodiments, instead of forming the first ohmic contact 61 and the third ohmic contact 63 before patterning the second substrate 40, the first ohmic contact 61 and the third ohmic contact 63 may be formed in the first dielectric structure 21 using a damascene or dual damascene process or any suitable method.

Referring to FIG. 3I, a semiconductor structure 104 comprising a first diode 45 and a second diode 46 is provided. The semiconductor structure 104 shown in FIG. 3I may be substantially similar to the semiconductor structure 104 described above with respect to FIG. 1J, where like reference numerals indicate like elements. Related details described above with respect to FIG. 1J may apply here if applicable.

Referring to FIG. 3I, a semiconductor structure 105 is provided. The semiconductor structure 105 comprises the first diode 45 and the second diode 46, as described above, and a memory unit 100. The semiconductor structure 105 shown in FIG. 3I may be substantially similar to the semiconductor structure 105 described above with respect to FIG. 1J, where like reference numerals indicate like elements. Related details of the semiconductor structure 105 described above may apply here if applicable.

In the embodiment shown in FIGS. 3A to 3I, a memory device including a pair of PN diodes as a selector can be fabricated using the method disclosed herein, which may provide additional options for the manufacturing of the memory device including vertical PN diodes. Specifically, subsequent high-temperature process(es) after the implant and/or epitaxial process(es) may damage the devices and/or metal layer fabricated earlier. However, by using the process described herein, the high-temperature annealing process is finished in the early stage (e.g., the second doped region 42, the second heavily-doped region 42a, and the fourth heavily-doped region 44a are formed in the stage shown in FIG. 3A), such that high-temperature process(es) at a later stage may be avoided.

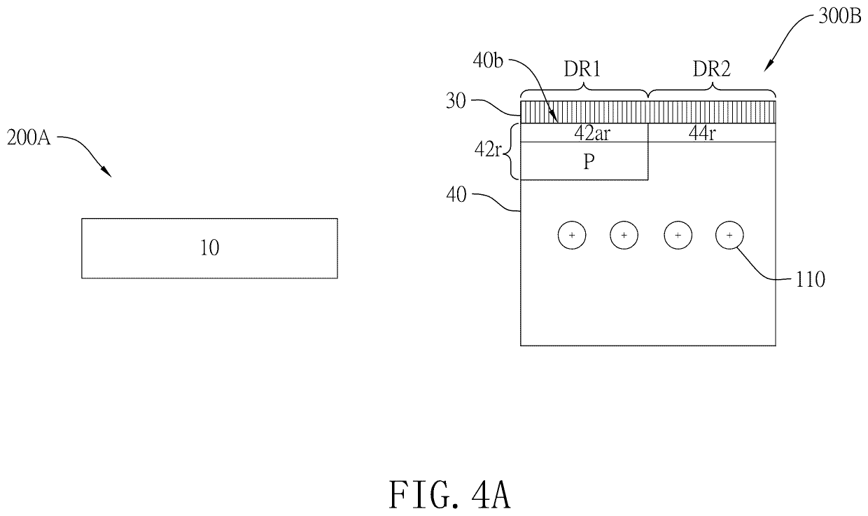

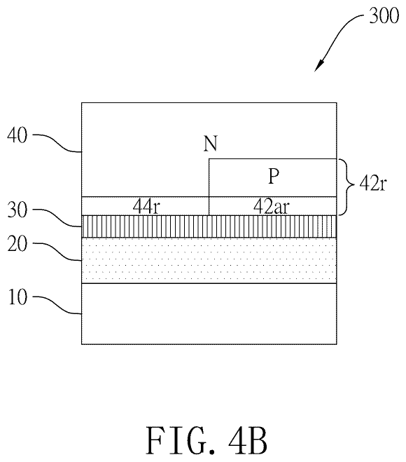

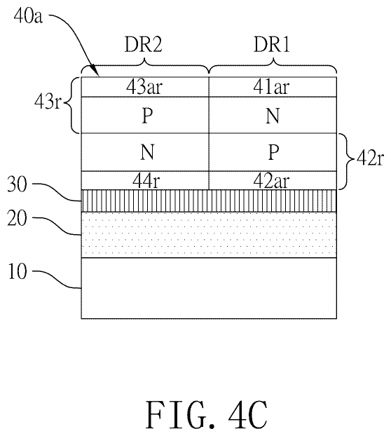

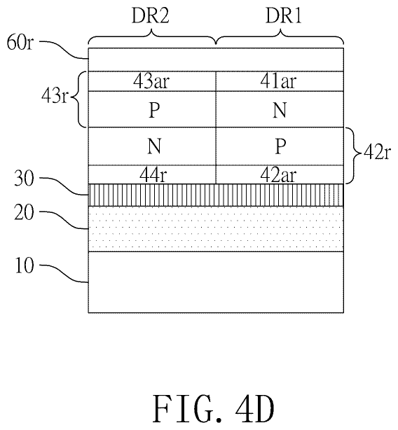

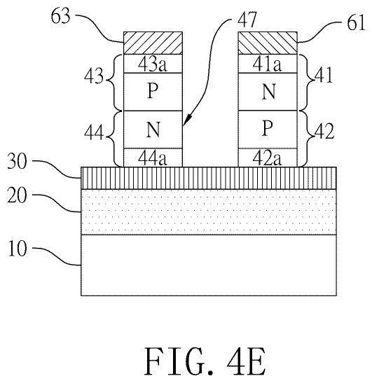

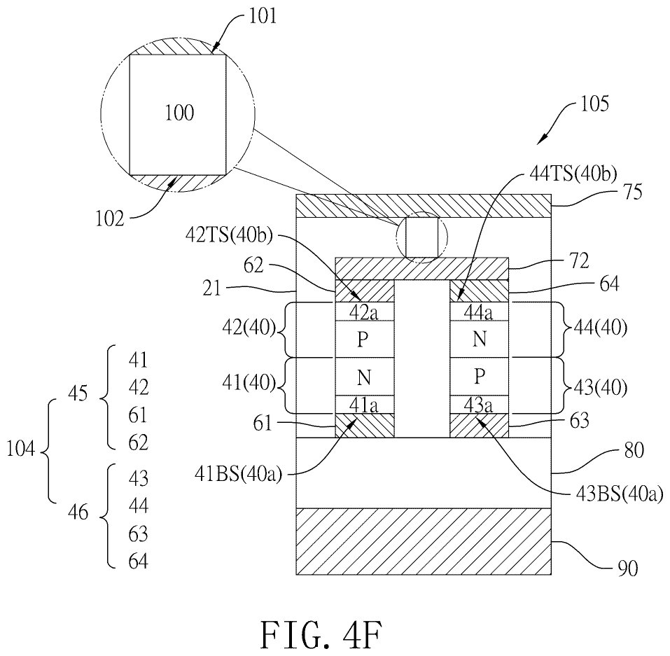

FIGS. 4A to 4F are schematic diagrams illustrating intermediate stages in the manufacture of a semiconductor structure according to one embodiment of the present disclosure. As shown in FIG. 4A, a first structure 200A and a second structure 300B are provided. The first structure 200A and the second structure 300B may be substantially similar to the first structure 200A and the second structure 200B described above with respect to FIG. 3A where like reference numerals indicate like elements, and related details described above with respect to FIG. 3A may apply here if applicable.

As shown in FIG. 4A, the second substrate 40 comprises a second doped region 42r extending from the second surface 40b of the second substrate 40. The second doped layer 42r may be a regionally un-patterned layer. For example, the second doped layer 42r may extend laterally across a predetermined device region DR1 in which a device unit is to be formed. The second doped layer 42r may further comprise a second heavily doped layer 42ar. In the embodiment shown in FIG. 4A, the second heavily doped layer 42a is vertically aligned to the second doped layer 42r. The second substrate 40 may further comprise a fourth heavily doped layer 44ar. As shown in FIG. 4A, each of the second heavily doped layer 42ar and the fourth heavily doped layer 44ar may also be a regionally un-patterned layer. For example, the second heavily doped layer 42ar may extend laterally across the device region DR1, and the fourth heavily doped layer 44ar may extend laterally across a consecutive device region DR2 in which another device unit is to be formed. As such, a heavily doped layer including a plurality of consecutive doped layers (e.g., the second heavily doped layer 42ar and the fourth heavily doped layer 44ar) which may be doped with different conductive-type of dopant is formed on the surface of the second substrate 40. The materials and formation method of the second doped layer 42r and the second heavily-doped layer 42ar may be substantially similar to the second doped region 42 and the second heavily-doped region 42 aheavily-doped region 44a described above with respect to FIG. 3A; and the materials and formation method of the fourth heavily-doped layer 44ar may be substantially similar to the fourth heavily-doped region 44a described above with respect to FIG. 3A.

As shown in FIG. 4B, the second structure 300B is flipped and bonded onto the first structure 200A by a bonding layer 20 to form a bonded structure. Details and processes for bonding process may be similar to that described above with respect to FIG. 3B to 3C, and the related description is omitted for brevity. Then, a portion of the second substrate 40 is removed from the bonded structure approximately at the implanted hydrogen layer 110. The removal process and the related details may be substantially similar to that described above with respect to FIG. 3D, and the related description is omitted for brevity. Hence, semiconductor substrate 300 is provided (step (a)). The semiconductor substrate 300 may be substantially similar to the semiconductor substrate 200 described above with respect to FIG. 3D where like reference numerals indicate like elements.

As shown in FIG. 4C, a third doped layer 43r is formed in the second substrate 40. The third doped layer 43r may be formed extending from a first surface 40a of the second substrate 40. The third doped layer 43r may be a regionally un-patterned layer. For example, the third doped layer 43r may extend laterally across the device region DR2. The third doped layer 43r may further comprise a third heavily-doped layer 43ar. The third heavily-doped layer 43ar may extend from the first surface 40a of the second substrate 40. In the embodiment shown in FIG. 4C, the third doped layer 43r and the third heavily-doped layer 43ar may be vertically aligned to the fourth heavily-doped layer 44ar. The second substrate 40 may further comprise the first heavily-doped layer 41ar. The first heavily-doped layer 41ar may extend from the first surface 40a of the second substrate 40. As shown in FIG. 4C, each of the first heavily doped layer 41ar and the third heavily doped layer 43ar may be a regionally un-patterned layer. For example, the first heavily doped layer 41ar may extend laterally across the device region DR1, and the third heavily doped layer 43ar may extend laterally across the consecutive device region DR2. As such, a heavily doped layer including a plurality of consecutive doped layers (e.g., the first heavily doped layer 41ar and the third heavily doped layer 43ar) which may be doped with different conductive-type of dopant is formed on the surface of the second substrate 40. In the embodiment shown in FIG. 4C, the first heavily-doped layer 41ar is vertically aligned with the second doped layer 42.

In some embodiments, each of the first heavily-doped layer 41ar, the third doped region 43, and the third heavily-doped layer 43ar may be formed in the second substrate 40 by suitable methods, e.g., implantation process and epitaxial growth. The materials and formation methods of the third doped layer 43r and the third heavily-doped layer 43ar may be substantially similar to that of the third doped region 43 and the third heavily-doped region 43a described above with respect to FIG. 3A; and the materials and formation methods of the first heavily-doped layer 41ar may be substantially similar to that of the first heavily-doped layer 41a described above with respect to FIG. 3A.

In the embodiment shown in FIG. 4D, an ohmic contact material layer 60r may be formed on the first surface of the second substrate 40. The ohmic contact material layer 60r may be an un-patterned layer (or at least extend across a plurality of device regions, e.g., the device region DR1 and the consecutive device region DR2). In the embodiment shown in FIG. 4D, the ohmic contact layer 60r extends across the third doped layer 43 and the first heavily-doped layer 43ar. The ohmic contact material layer 60r may comprise metal, alloy, or conductive metal compound suitable for the formation of ohmic contacts, such as Mo, Ag, TiN, or combinations thereof. The ohmic contact material layer 60r may be formed by deposition such as chemical vapor deposition (CVD), physical vapor deposition (PVD), or atomic layer deposition (ALD).

As shown in FIG. 4E, the ohmic contact layer 60r may be patterned to form a first ohmic contact 61 of a first diode and a third ohmic contact 63 of a second diode. The first ohmic contact 61 and the third ohmic contact 63 shown in FIG. 4E may be substantially similar to the first ohmic contact 61 and the third ohmic contact 63 described above with respect to FIGS. 1A to 1J, respectively. The patterning processes and related details may be substantially similar to that described above with respect to FIG. 1D, and the related description is omitted for brevity.

Alternatively, in some other embodiments, the ohmic contact layer 60r shown in FIG. 4D may not be formed, and the first doped region 41 and the fourth doped region 44 may be defined before the formation of the first ohmic contact 61 and/or the third ohmic contact 63. For example, the first dielectric structure 21 in FIG. 4F may be formed in the trench 47 separating the third doped region 43 and the fourth doped region 44 from the first doped region 41, and the first ohmic contact 61 and/or the third ohmic contact 63 may be formed in the first dielectric structure 21 using a damascene or dual damascene process or any suitable method to form the structure shown in FIG. 2B.

As shown in FIG. 4E, the second substrate 40 is patterned to define a first doped region 41 of a first diode and a fourth doped region 44 of a second diode (step(c)). In the embodiment shown in FIG. 4E, the first heavily-doped layer 41ar may be patterned to form a first heavily-doped region 41a of the first doped region 41, and the fourth heavily-doped layer 44ar may be patterned to form a fourth heavily-doped region 44a of the fourth doped region 44. The first doped region 41, the first heavily-doped region 41a, the fourth doped region 44, and the fourth heavily-doped region 44a shown in FIG. 4E may be substantially similar to that described above with respect to FIGS. 1A to 1J, respectively.

In the embodiment shown in FIG. 4E, the second doped layer 42r may be patterned to form a second doped region 42 of a first diode, and the third doped layer 43r may be patterned to form a third doped region 43 of a second diode. The second heavily-doped layer 42ar may be patterned to form a second heavily-doped region 42a of the second doped region 42, and the third heavily-doped layer 43ar may be patterned to form a third heavily-doped region 43a of the third doped region 43. The second doped region 42, the second heavily-doped region 42a, the third doped region 43, and the third heavily-doped region 43a shown in FIG. 4E may be substantially similar to that described above with respect to FIGS. 1A to 1J, respectively.

As shown in FIG. 4F, a semiconductor structure 105 is provided. The structure shown in FIG. 4F may be formed by processes similar to that described above with respect to FIGS. 1E to 1J and FIGS. 3F to 3I, and the related description is omitted for brevity.

Referring to FIG. 4F, a semiconductor structure 104 comprising a first diode 45 and a second diode 46 is provided. The semiconductor structure 104 shown in FIG. 4F may be substantially similar to the semiconductor structure 104 described above with respect to FIG. 1J, where like reference numerals indicate like elements. Related details of the semiconductor structure 104 described above with respect to FIG. 1J may apply here if applicable.

Referring to FIG. 4F, a semiconductor structure 105 is provided. The semiconductor structure 105 comprises the first diode 45 and the second diode 46, as described above, and a memory unit 100. The semiconductor structure 105 shown in FIG. 4F may be substantially similar to the semiconductor structure 105 described above with respect to FIG. 1J, where like reference numerals indicate like elements. Related details of the semiconductor structure 105 described above may apply here if applicable.

In the embodiment shown in FIGS. 4A to 4F, a memory device including a pair of PN diodes as a selector can be fabricated using the method disclosed herein, wherein the ion implantation process may be done during the manufacturing of the semiconductor substrate (e.g., semiconductor substrate 300), and the first doped region 41, the second doped region 42, the third doped region 43, and the fourth doped region 44 may be formed through pattering the second substrate 40, as shown in FIG. 4E without conducting further implantation process. Moreover, through the method disclosed herein, the first heavily-doped region 41a may be formed vertical-aligned with the first ohmic contact 61, and the third heavily-doped region 43a may be formed vertical-aligned with the third ohmic contact 63.

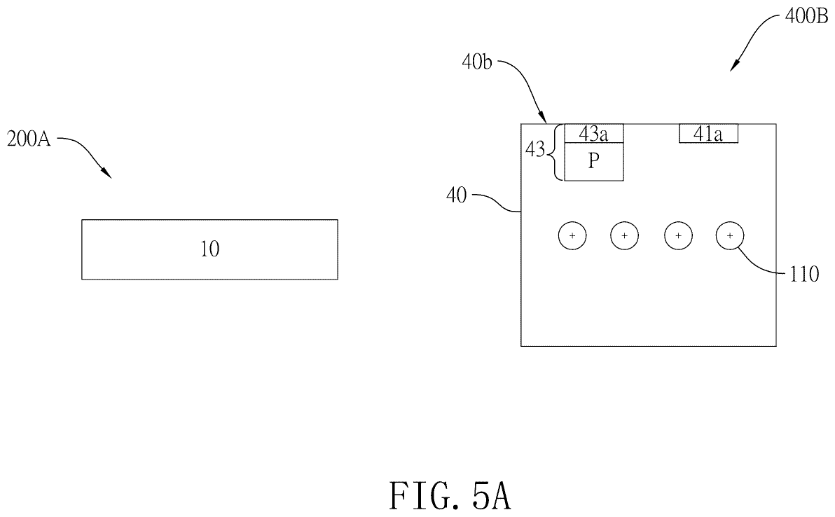

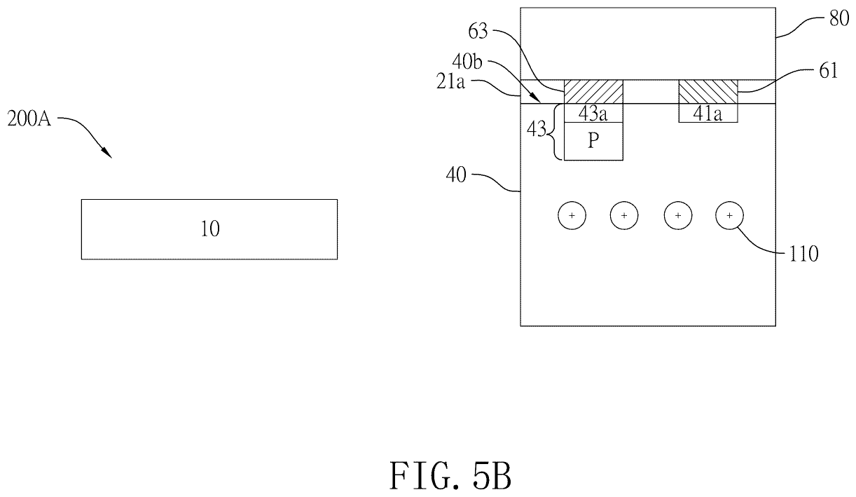

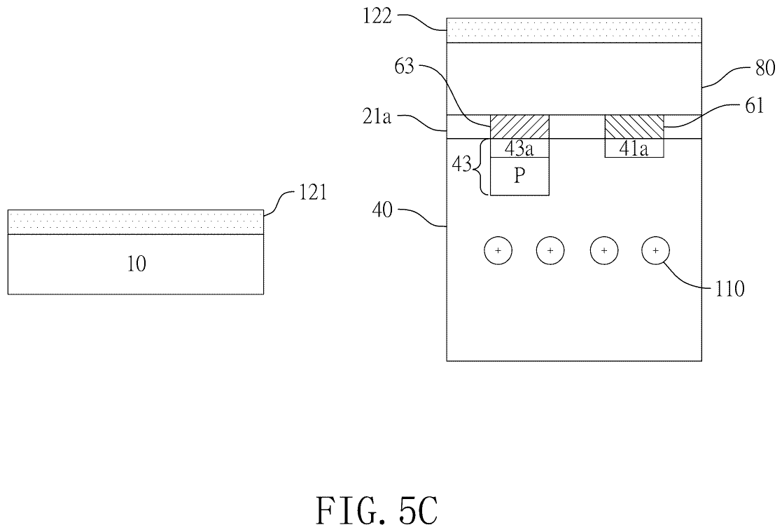

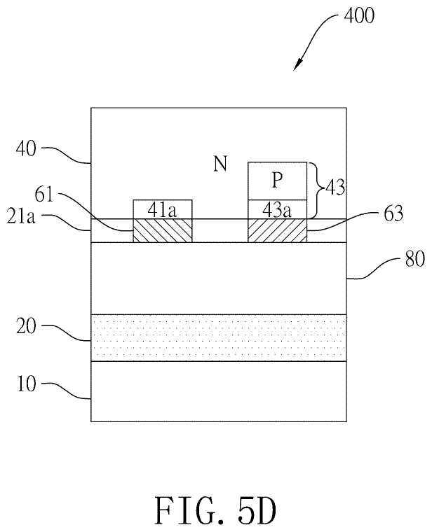

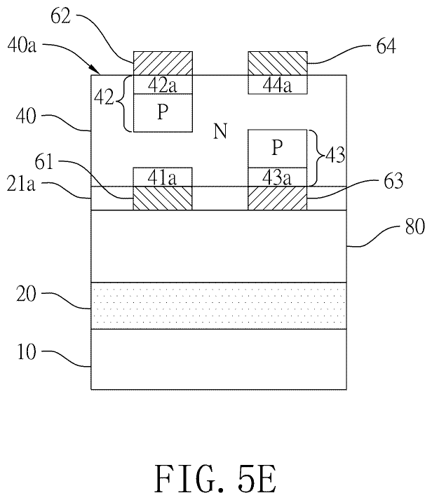

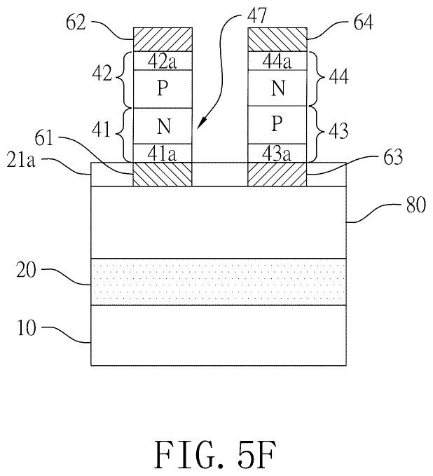

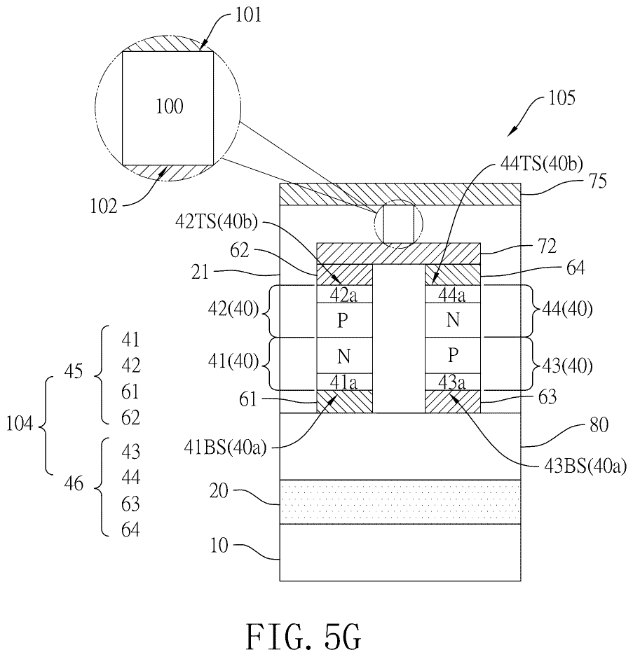

FIGS. 5A to 5G are schematic diagrams illustrating intermediate stages in the manufacture of a semiconductor structure according to one embodiment of the present disclosure. As shown in FIG. 5A, a first structure 200A and a second structure 400B are provided. The first structure 200A comprises a first substrate 10. The first structure 200A and the second structure 400B may be substantially similar to the first structure 200A and the second structure 400B described above with respect to FIG. 3A, except that the second structure 400B does not include an etch stop layer on the second substrate 40. Specifically, the second structure 400B comprises a third doped region 43, a third heavily-doped region 43a, and a first heavily-doped region 41a. Details and processes for forming the third doped region 43, the third heavily-doped region 43a, and first heavily-doped region 41a may be substantially similar to that described above with respect to FIG. 1A, and the related description is omitted for brevity. Other related details described above with respect to FIG. 3A may apply here if applicable.

As shown in FIG. 5B, a first ohmic contact 61 and a third ohmic contact 63 are formed on the second surface 40b of the second substrate 40. In some embodiments, a dielectric structure 21a may be formed on the second surface 40b of the second substrate 40, and the first ohmic contact 61 and the third ohmic contact 63 are formed in the dielectric structure 21a using a damascene or dual damascene process or any suitable method. However, the present disclosure is not limited thereto. The dielectric structure 21a may comprise dielectric material such as silicon oxide, silicon oxynitride, low dielectric constant (low k) materials, a combination thereof, and/or other applicable material and may be formed by deposition such as CVD, PVD, or ALD, spinning, or any suitable method. Other details of the first ohmic contact 61 and the third ohmic contact 63 describe above with respect to FIGS. 1C to 1E may apply here if applicable.

As shown in FIG. 5B, an interconnect structure 80 is formed over the first dielectric structure 21a. The formation processes and related details of the interconnect structure 80 may be substantially similar to that described above with respect to FIG. 1E, and the related description is omitted for brevity.

As shown in FIG. 5C, a first dielectric layer 121 is formed on the first substrate 10, and a second dielectric layer 122 is formed on the interconnect structure 80 before the bonding of the first structure 200A and the second structure 400B. Details and processes for forming the first dielectric layer 121 and the second dielectric layer 122 may be substantially similar to that described above with respect to FIG. 3B, and the related description is omitted for brevity.

As shown in FIG. 5D, the second structure 400B is flipped and bonded onto the first structure 200A by a bonding layer 20 to form a bonded structure. Details and the bonding of the first structure 200A and the second structure 400B may be similar to that described above with respect to FIG. 3B to 3C, and the related description is omitted for brevity. Then, a portion of the second substrate 40 is removed from the bonded structure approximately at the implanted hydrogen layer 110. The removal process and the related details may be substantially similar to that described above with respect to FIG. 3D, and the related description is omitted for brevity. Hence, semiconductor substrate 400 is provided (step (a)).

As shown in FIG. 5E, a second doped region 42 of a first diode is formed in the second substrate 40 (step (b)). The second doped region 42 may be formed extending from the first surface 40a of the second substrate 40. The second doped region 42 may further comprise a second heavily-doped region 42a extending from the first surface 40a of the second substrate 40. A fourth heavily-doped region 44a may also be formed in the second substrate 40. The fourth heavily-doped region 44a may be formed extending from the first surface 40a of the second substrate 40. Details and processes for forming the fourth heavily-doped region 44a, the second doped region 42, and the second heavily-doped region 42a may be substantially similar to that described above with respect to FIG. 1I, and the related description is omitted for brevity.

As shown in FIG. 5E, a second ohmic contact 62 of the first diode and a fourth ohmic contact 64 of the second diode are formed on the first surface 40a of the second substrate 40. Details and processes for forming the second ohmic contact 62 and a fourth ohmic contact 64 may be substantially similar to that described above with respect to FIG. 1J, and the related description is omitted for brevity.

As shown in FIG. 5F, the second substrate 40 is patterned to define a first doped region 41 of the first diode and a fourth doped region of a second diode 46 (step (c)). The patterning processes may be substantially similar to the process described above with respect to FIG. 1D, and the related description is omitted for brevity. In the embodiment shown in FIG. 5F, the dielectric structure 21a may function as an etch stop layer in the etch process for patterning the second substrate 40.

As shown in FIG. 5G, a first dielectric structure 21 is formed. The first dielectric structure 21 may surround the first doped region 41 and the second doped region 42 of the first diode and the third doped region 43 and the fourth doped region 44 of the second diode. The first dielectric structure 21 may fill the trench 47 as shown in FIG. 5F, such that each of the first diode and the second diode that is surrounded by the first dielectric structure 21. The materials and processes for forming the first dielectric structure 21 may be substantially similar to that described above with respect to FIG. 1E, and the related description is omitted for brevity.

As shown in FIG. 5G, a memory unit 100 is formed (step (h)). Details and formation methods of the memory unit 100 may be similar to that described above with respect to FIG. 1J and FIG. 3I, and the related description is omitted for brevity. In the embodiment shown in FIG. 5G, a wiring layer 72 coupled to the second ohmic contact 62 and the fourth ohmic contact 64 is formed, and the memory unit 100 is formed over the wiring layer 72. The materials and processes for forming the wiring layer 72 may be similar to that described above with respect to FIG. 1J, and the related description is omitted for brevity. A bit line 75 may be formed over the memory unit 100. The materials and processes for forming the bit line 75 may be similar to that described above with respect to FIG. 1J, and the related description is omitted for brevity.

Referring to FIG. 5G, a semiconductor structure 104 comprising a first diode 45 and a second diode 46 is provided. The semiconductor structure 104 shown in FIG. 5G may be substantially similar to the semiconductor structure 104 described above with respect to FIG. 1J, where like reference numerals indicate like elements. Related details described above with respect to FIG. 1J may apply here if applicable.

Referring to FIG. 5G, a semiconductor structure 105 is provided. The semiconductor structure 105 comprises the first diode 45 and the second diode 46, as described above, and a memory unit 100. The semiconductor structure 105 shown in FIG. 5G may be substantially similar to the semiconductor structure 105 described above with respect to FIG. 1J, where like reference numerals indicate like elements. Related details of the semiconductor structure 105 described above may apply here if applicable.

In the embodiment shown in FIGS. 5A to 5H, a memory device including a pair of PN diodes as a selector can be fabricated using the method disclosed herein, which may provide additional options for manufacturing and may further reduce the process steps and processing time.

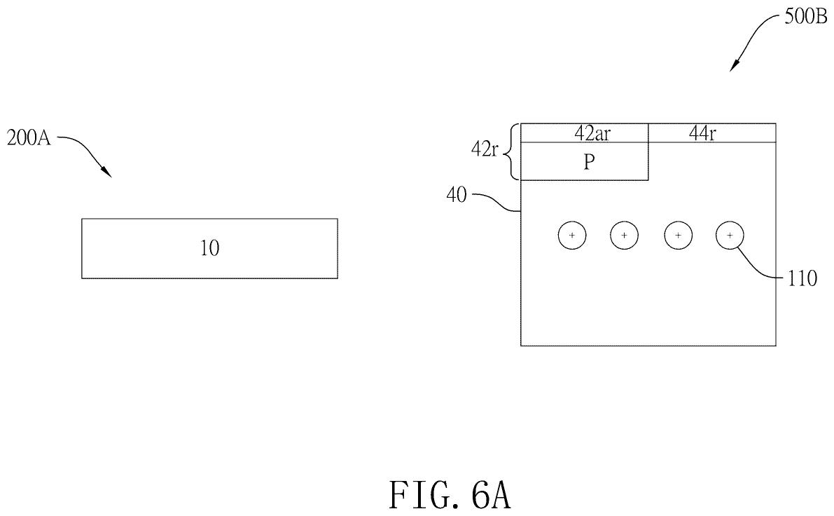

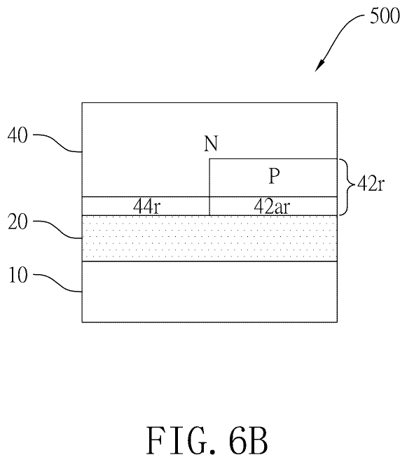

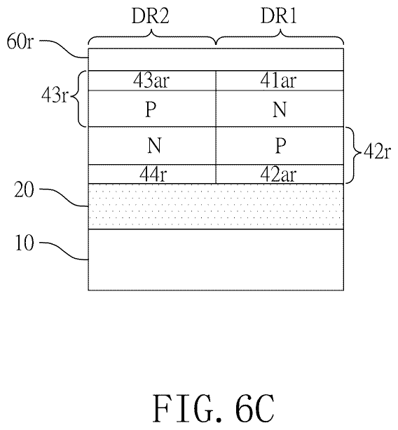

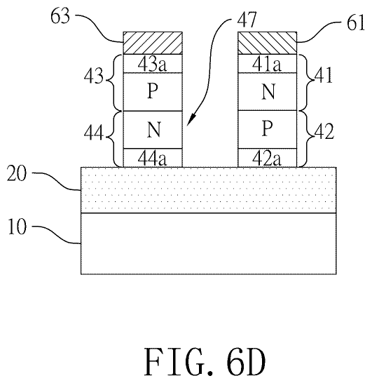

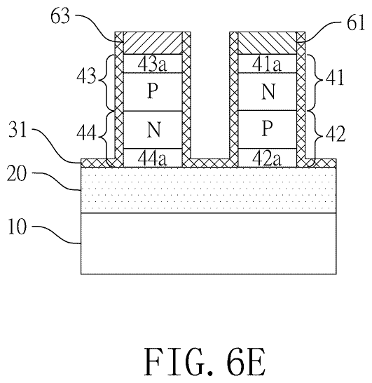

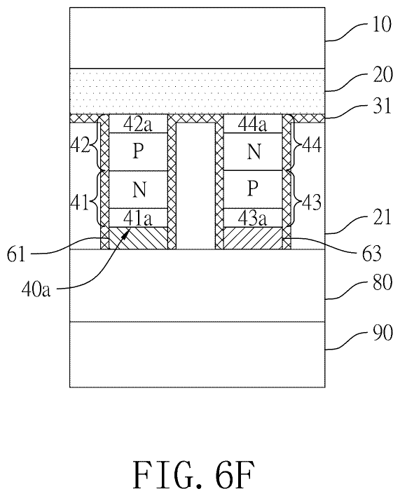

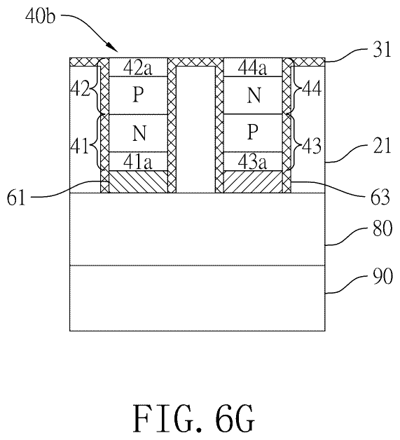

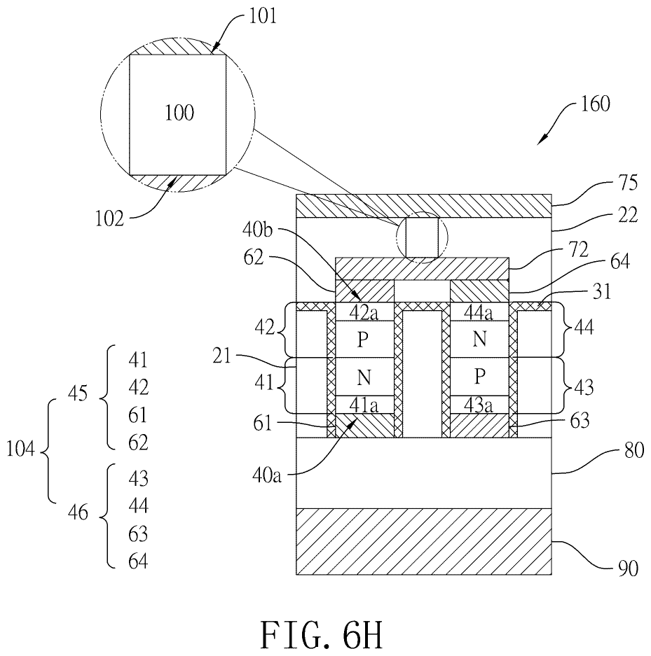

FIGS. 6A to 6G are schematic diagrams illustrating intermediate stages in the manufacture of a semiconductor structure according to one embodiment of the present disclosure. As shown in FIG. 6A, a first structure 200A and a second structure 500B are provided. The first structure 200A comprises a first substrate 10. The first structure 200A and the second structure 500B may be substantially similar to the first structure 200A and the second structure 300B described above with respect to FIG. 4A, where like reference numerals indicate like elements, except that the second structure 500B does not include an etch stop layer on the second substrate 40. Other related details described above with respect to FIG. 4A may apply here if applicable.

As shown in FIG. 6B, a semiconductor substrate 500 is provided (step (a)). The semiconductor substrate 500 may be substantially similar to the semiconductor substrate 300 described above with respect to FIG. 4B, where like reference numerals indicate like elements, except that the semiconductor substrate 500 does not include an etch stop layer. The semiconductor substrate 500 may be formed by processes described above with respect to FIGS. 3B to 3D and FIGS. 4A to 4B, and the related description is omitted for brevity.

As shown in FIG. 6C, a third doped layer 43r is formed in the second substrate 40 (step (b)). The third doped layer 43r may further comprise a third heavily-doped layer 43ar. A first heavily doped layer 41ar may also be formed. Details and formation methods of the third doped layer 43r, the third heavily-doped layer 43ar, and the first heavily doped layer 41ar may be similar to that described above with respect to FIG. 4C, and the related description is omitted for brevity. An ohmic contact material layer 60r may be formed on the second substrate 40. Details and formation methods of the ohmic contact material layer 60r may be similar to that described above with respect to FIG. 4D, and the related description is omitted for brevity.

As shown in FIG. 6D, the ohmic contact layer 60r may be patterned to form a first ohmic contact 61 of a first diode 45 and a third ohmic contact 63 of a second diode 46. Details and formation methods of the first ohmic contact 61 and the third ohmic contact 63 may be substantially similar to that described above with respect to FIG. 4E, and the related description is omitted for brevity.

As shown in FIG. 6D, the second substrate 40 is patterned to define a first doped region 41 of the first diode and a fourth doped region 44 of a second diode (step (c)). In the embodiment shown in FIG. 6D, the bonding layer 20 may function as an etch stop layer in the etch process for patterning the second substrate 40. The second doped layer 42r may be patterned to form a second doped region 42, the second heavily-doped layer 42ar may be patterned to form a second heavily-doped region 42a, and the first heavily-doped layer 41ar may be patterned to form a first heavily-doped layer 41a. The third doped layer 43r may be patterned to form a third doped region 43, the third heavily-doped layer 43ar may be patterned to form a third heavily-doped region 43a, and the fourth heavily-doped layer 41ar may be patterned to form a fourth heavily-doped region 41a. The patterning processes and related details may be substantially similar to that described above with respect to FIGS. 1D and 4E, and the related description is omitted for brevity.

As shown in FIG. 6E, a conformal etch stop layer 31 is formed after patterning the second substrate 40. The conformal etch stop layer 31 may be formed on the sidewalls of the first doped region 41, the second doped region 42, the third doped region 43, and the fourth doped region 44. In the embodiment shown in FIG. 6D, the conformal etch stop layer 31 may also be formed on the bonding layer 20. The conformal etch stop layer 31 may have a high etch selectivity against the bonding layer 20. The conformal etch stop layer 31 may be made of similar material as that of the etch stop layer 30 discussed above with respect to FIG. 1A. For example, in one embodiment, the conformal etch stop layer 31 may comprise silicon nitride and the bonding layer 20 comprises silicon oxide. In one embodiment, the thickness of the conformal etch stop layer 31 may be in a range between 0.2 nm and 5 nm. These values are merely examples and are not intended to be limiting. In one embodiment, the conformal etch stop layer 31 may be formed by epitaxial growth or by deposition such as chemical vapor deposition (CVD), physical vapor deposition (PVD), or atomic layer deposition (ALD). In one embodiment, the conformal etch stop layer 31 may be formed by sputtering or evaporation. In some embodiments, a portion of conformal etch stop layer formed on the first ohmic contact 61 and/or the third ohmic contact 63 (if any) may be removed to ensure the electrical connection with device(s) and/or conductive features that will be subsequently formed over the second substrate 40 (e.g., the interconnect structure 80 shown in FIG. 6F).

As shown in FIG. 6F, a first dielectric structure 21 is formed, and an interconnect structure 80 may be formed over the first dielectric structure 21. Details and formation methods of the first dielectric structure 21 and the interconnect structure 80 may be similar to that described above with respect to FIG. 1E, and the related description is omitted for brevity.

Alternatively, in some other embodiments, the first ohmic contact 61 and/or the third ohmic contact 63 may be formed after the first dielectric structure 21. For example, the first dielectric structure 21 may be formed in the trench between the portions of conformal etch stop layer 31 surrounding the first diode 45 and the second diode 46, and the first ohmic contact 61 and/or the third ohmic contact 63 may be formed in the first dielectric structure 21 using a damascene or dual damascene process or any suitable method to form the structure shown in FIG. 6F.

As shown in FIG. 6F, a third substrate 90 is added to the first surface 40a of the second substrate 40, wherein the second substrate 40 is located between the third substrate 90 and the first substrate 10 (step (d)). Methods of formation and/or attachment and details of the third substrate 90 may be similar to that described above with respect to FIG. 1F, and the related description is omitted for brevity.

As shown in FIG. 6G, the first substrate 10 and the bonding layer 20 are removed to expose a second surface 40b of the second substrate 40. The removal of the first substrate 10 and the bonding layer 20 may be substantially similar to the processes described above with respect to FIG. 1G. Specifically, in the embodiment shown in FIG. 6G, the bonding layer 20 may be removed to expose the second surface 40b of the second substrate 40 and the conformal etch stop layer 31. The second doped region 42 of the first diode and the fourth doped region 44 of the second diode may be exposed (step (f)) after removing the bonding layer 20. In the embodiment shown in FIG. 6G, the second heavily-doped region 42a of the second doped region 42 and the fourth heavily-doped region 44a of the fourth doped region 44 is exposed. Materials of the conformal etch stop layer 31 and the bonding layer 20 may be selected such that the conformal etch stop layer 31 may function as an etch stop layer with a higher etch selectivity against the bonding layer and/or may function as an etch stop layer under more desirable etch conditions. In some embodiments, materials of the second substrate 40 may be selected such that the first heavily-doped regions 42a and 44a may function as an etch stop layer with a higher etch selectivity against the bonding layer 20.

As shown in FIG. 6H, a second ohmic contact 62 of the first diode 45 and a fourth ohmic contact 64 of the second diode 46 is formed on the second surface 40b of second substrate 40 (step (f)). Details and formation methods of the second ohmic contact 62 and the fourth ohmic contact 64 may be substantially similar to the second ohmic contact 62 and the fourth ohmic contact 64 described above with respect to FIG. 1J, respectively.

As shown in FIG. 6H, a second dielectric structure 22 is formed. The second dielectric structure 22 may include one or more stacked dielectric layers. The second dielectric structure 22 may comprise dielectric material such as silicon oxide, silicon oxynitride, low k materials, a combination thereof, and/or other applicable material and may be formed by deposition such as CVD, PVD, or ALD, spinning, or any suitable method. In some embodiments, the second ohmic contact 62 and the fourth ohmic contact 64 may be formed after the formation of the second dielectric structure 22 using a damascene or dual damascene process or any suitable method.

As shown in FIG. 6H, a memory unit 100 is formed (step (h)). Details and formation methods of the memory unit 100 may be similar to that described above with respect to FIG. 1J, and the related description is omitted for brevity. In the embodiment shown in FIG. 6H, a wiring layer 72 coupled to the second ohmic contact 62 and the fourth ohmic contact 64 may be formed, and the memory unit 100 may be formed in the second dielectric structure 22 and over the wiring layer 72. The wiring layer 72 may be formed in the second dielectric structure 22 using a damascene or dual damascene process or any suitable method. The materials and processes for forming the wiring layer 72 may be similar to that described above with respect to FIG. 1J.

As shown in FIG. 6H, a bit line 75 may be formed over the memory unit 100. The bit line 75 may be formed in the second dielectric structure 22 using a damascene or dual damascene process or any suitable method. The materials and processes for forming the bit line 75 may be similar to that described above with respect to FIG. 1J.

Referring to FIG. 6H, a semiconductor structure 104 comprising a first diode 45 and a second diode 46 is provided. The semiconductor structure 104 shown in FIG. 6H may be substantially similar to the semiconductor structure 104 described above with respect to FIG. 1J, where like reference numerals indicate like elements. Related details described above with respect to FIG. 1J may apply here if applicable.

Referring to FIG. 6H, a semiconductor structure 160 is provided. The semiconductor structure 160 comprises the first diode 45 and the second diode 46, as described above, and a memory unit 100. The semiconductor structure 160 shown in FIG. 6H may be substantially similar to the semiconductor structure 105 described above with respect to FIG. 1J, where like reference numerals indicate like elements. In the embodiment shown in FIG. 6H, a conformal etch stop layer 31 is disposed on the sidewalls of the first doped region 41, the second doped region 42, the third doped region 43, and the fourth doped region 44. The conformal etch stop layer 31 may also be disposed between the first dielectric structure 21 and the second dielectric structure 22. The conformal etch stop layer 31 may protect these features from the etching process for removing the bonding layer 20. This reduces the difficulty in fabricating the semiconductor structure 160.

In the embodiment shown in FIGS. 6A to 6H, a memory device including a pair of PN diodes as a selector can be fabricated using the method disclosed herein, which may provide additional options for manufacturing and may further reduce the process steps and processing time. For example, the removal process of the etch stop layer 30 as shown in FIG. 1H may be omitted. Moreover, the conformal etch stop layer may function as diffusion barrier for metal portions (e.g., ohmic contacts, etc.) of the semiconductor structure 160.

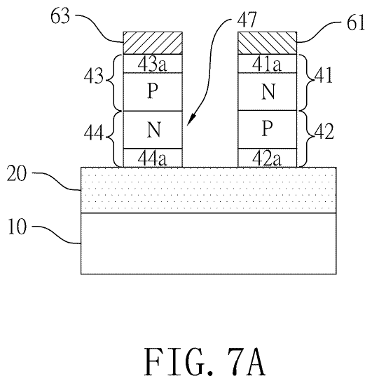

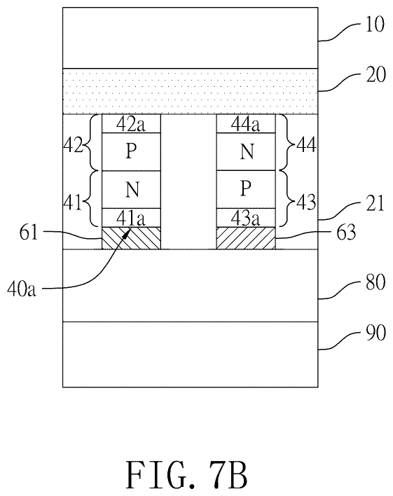

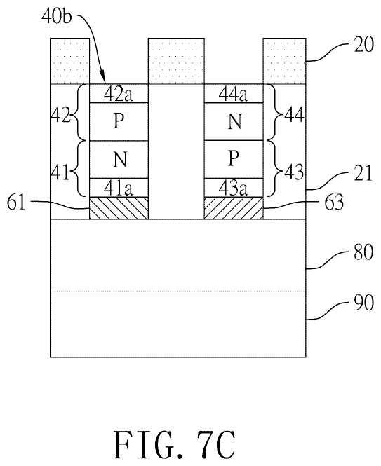

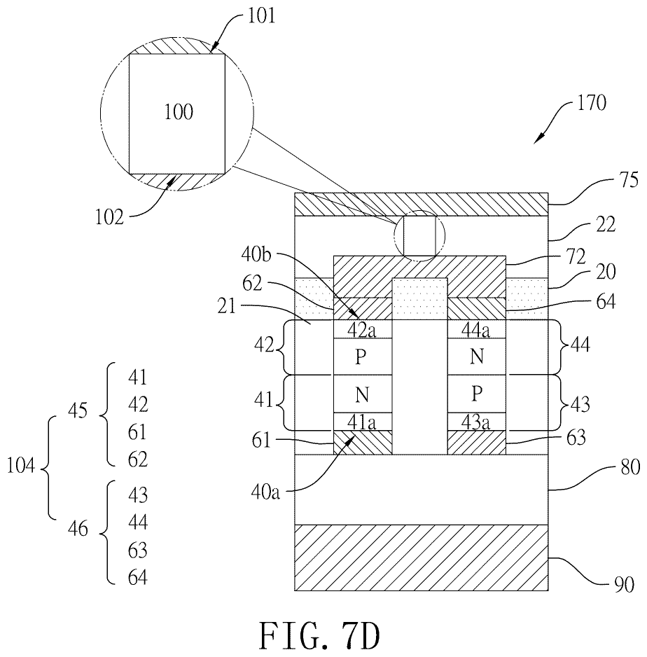

FIGS. 7A to 7E are schematic diagrams illustrating intermediate stages in the manufacture of a semiconductor structure according to one embodiment of the present disclosure. As shown in FIG. 7A, a second doped region 42, a second heavily-doped region 42a, a third doped region 43, a third heavily-doped region 43a, a first ohmic contact 61 and a third ohmic contact 63 are formed, and a first doped region 41 and a fourth doped region 44 are defined through patterning the second substrate 40. Details and formation methods of the semiconductor structure shown in FIG. 7A may be substantially similar to that described above with respect to FIGS. 6A-6D, where like reference numerals indicate like elements.

As shown in FIG. 7B, a first dielectric structure 21 is formed, an interconnect structure 80 may be formed over the first dielectric structure 21. Details and formation methods of the first dielectric structure 21 and the interconnect structure 80 may be similar to that described above with respect to FIG. 1E, and the related description is omitted for brevity.

As shown in FIG. 7B, a third substrate 90 is added to the first surface 40a of the second substrate 40, wherein the second substrate 40 is located between the third substrate 90 and the first substrate 10 (step (d)). Methods of formation and/or attachment and details of the third substrate 90 may be similar to that described above with respect to FIG. 1F, and the related description is omitted for brevity.

As shown in FIG. 7C, the first substrate 10 and the bonding layer 20 are removed to expose a second surface 40b of the second substrate 40. The removal of the first substrate 10 may be substantially similar to the processes described above with respect to FIG. 1G. Specifically, in the embodiment shown in FIG. 7C, only a portion of the bonding layer 20 over the second doped region 42 and over the fourth doped region 44 is removed. Trench(es) may be formed in the bonding layer 20 using suitable methods such as photolithography and etching techniques. The second doped region 42a of the first diode and the fourth doped region 64a of the second diode in the second substrate 40 is exposed (step (f)) after removing the first substrate 10 and the bonding layer 20. In the embodiment shown in FIG. 7C, the second heavily-doped region 42a of the second doped region 42 and the fourth heavily-doped region 44a of the fourth doped region 44 are exposed. In some embodiments, materials of the second substrate 40 may be selected such that the second heavily-doped regions 42a and the fourth heavily-doped region 44a may function as an etch stop layer with a higher etch selectivity against the bonding layer 20.

As shown in FIG. 7D, a second ohmic contact 62 and a fourth ohmic contact 64 are formed on the second surface 40b of the second substrate 40. In the embodiment shown in FIG. 7D, the second ohmic contact 62 and the fourth ohmic contact 64 may be formed in the trench(es) extending through the bonding layer 20. Materials and formation methods of the second ohmic contact 62 and the fourth ohmic contact 64 may be substantially similar to that described above with respect to FIG. 1J, and the related description is omitted for brevity.

As shown in FIG. 7D, a second dielectric structure 22 is formed. The second dielectric structure 22 may include one or more stacked dielectric layers. Details and formation methods of the second dielectric structure 22 may be substantially similar to that described above with respect to FIG. 6H, and the related description is omitted for brevity. In some embodiments, the first ohmic contact 62 and the fourth ohmic contact 64 may be formed in the second dielectric structure 22 using a damascene or dual damascene process or any suitable method.

As shown in FIG. 7D, a memory unit 100 is formed (step (h)). Details and formation methods of the memory unit 100 may be similar to that described above with respect to FIG. 1J, and the related description is omitted for brevity. In the embodiment shown in FIG. 7E, a wiring layer 72 coupled to the second ohmic contact 62 and the fourth ohmic contact 64 may be formed, and the memory unit 100 may be formed in the second dielectric structure 22 and over the wiring layer 72. The wiring layer 72 may be formed in the second dielectric structure 22 and/or the bonding layer 20 using a damascene or dual damascene process or any suitable method. The materials and processes for forming the wiring layer 72 may be similar to that described above with respect to FIG. 1J. As shown in FIG. 7D, a bit line 75 may be formed over the memory unit 100. The materials and processes for forming the bit line 75 are described above with respect to FIG. 1J, and the related description is omitted for brevity.

Referring to FIG. 7D, a semiconductor structure 104 comprising a first diode 45 and a second diode 46 is provided. The semiconductor structure 104 shown in FIG. 7D may be substantially similar to the semiconductor structure 104 described above with respect to FIG. 1J, where like reference numerals indicate like elements. Related details described above with respect to FIG. 1J may apply here if applicable.

Referring to FIG. 7D, a semiconductor structure 170 is provided. The semiconductor structure 170 comprises the first diode 45 and the second diode 46, as described above, and a memory unit 100. The semiconductor structure 170 shown in FIG. 7D may be substantially similar to the semiconductor structure 105 described above with respect to FIG. 1J, where like reference numerals indicate like elements. Related details of the semiconductor structure 105 described above may apply here if applicable.

In the embodiment shown in FIGS. 7A to 7D, a memory device including a pair of PN diodes as a selector can be fabricated using the method disclosed herein, which may provide additional options for manufacturing and may further reduce the process steps and processing time.

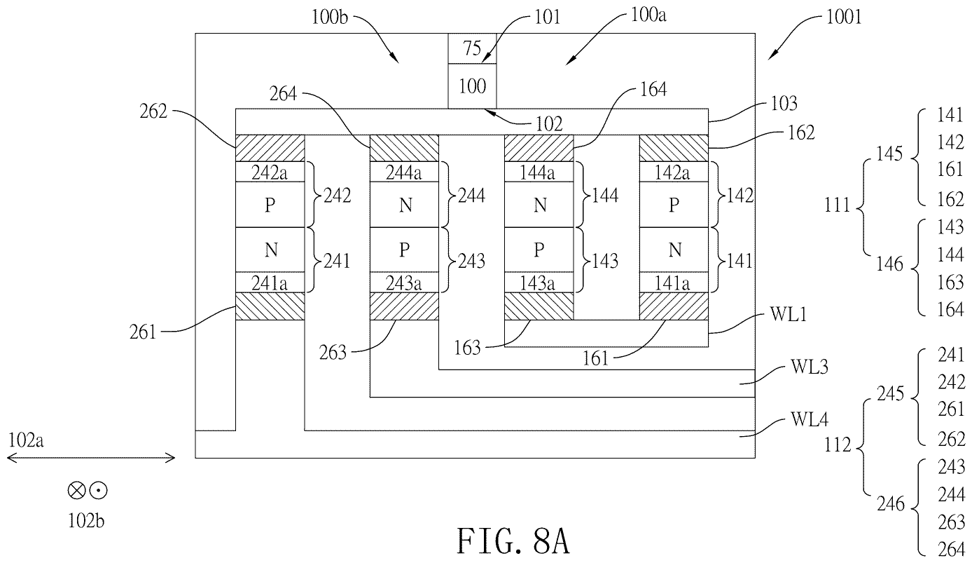

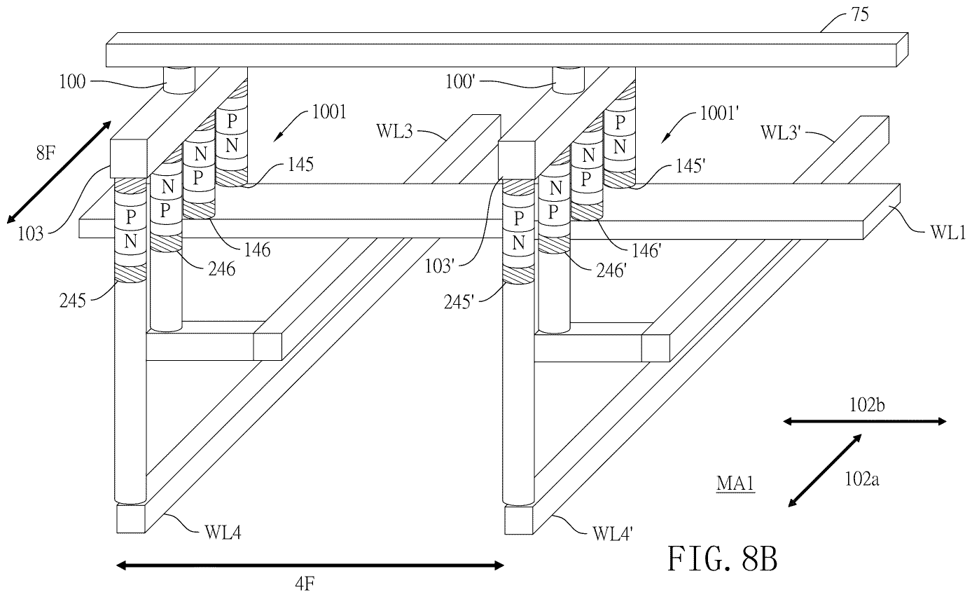

FIGS. 8A to 8B are schematic views to illustrate an embodiment of a memory device according to the present disclosure. As shown in FIGS. 8A and 8B, a memory device 1001 is provided. The memory device 1001 comprises a memory unit 100, an electrode 103, a first diode pair 111, and a second diode pair 112. The memory unit 100 may have a first end 101 and a second end 102. The memory unit 100 is electrically coupled to the electrode 103 from the second end 102 of the memory unit 100.

The electrode 103 extends laterally in a first direction 102a from a first side 100a of the memory unit 100 to a second side 100b of the memory unit 100. As shown in FIGS. 8A and 8B, the electrode 103 may be disposed vertically between the memory unit 100 and the first diode pair 111. The electrode 103 may be disposed vertically between the memory 100 and the second diode pair 112. However, the present disclosure is not limited thereto. In some embodiments, the electrode 103 comprises materials with high spin Hall effect, for example, β-Tantalum (β-Ta), β-Tungsten (β-W), Ta, W, Pt, Cu doped with elements such as Ir, Bi, and any of the elements which may exhibit high spin-orbit coupling. The electrode 103 may be formed in a first dielectric structure 21 using a damascene or dual damascene process or any suitable method.

The memory unit 100 may comprise a magnetic tunnel junction (MTJ) structure. Details and formation methods of the memory unit 100 may be substantially similar to those described above with respect to FIG. 1J, and the related description is omitted for brevity.

As shown in FIGS. 8A and 8B, each of the first diode pair 111 and the second diode pair 112 comprises a first diode and a second diode. In some embodiments, the first diode 245 and the second diode 246 of the second diode pair 112 are arranged in the first direction 102a.

As shown in FIGS. 8A and 8B, the first diode pair 111 may be disposed on the first side 100a of the memory unit 100. Each of the first diode 111 and the second diode 112 of the first diode pair 111 is electrically coupled to the electrode at the first side 100a of the memory unit 100. In some embodiments, the first diode 145 and the second diode 146 of the first diode pair 111 are arranged in the first direction 102a. The first diode 145 of the first diode pair 111 comprises a first doped region 141 and a second doped region 142. The second doped region 142 is disposed over and in contact with the first doped region 141. The second diode 146 of the first diode pair 111 comprises a third doped region 143 and a fourth doped region 144. The fourth doped region 144 is disposed over and in contact with the third doped region 143. A top surface of the second doped region 142 is higher than a bottom surface of the third doped region 143, and a top surface of the fourth doped region 144 is higher than a bottom surface of the first doped region 141. Each of the first doped region 141 and the fourth doped region 144 is doped with a first conductivity-type of dopant, and each of the second doped region 142 and the third doped region 143 is doped with a second conductivity-type of dopant opposite to the first conductivity-type.

Details and formation methods of the first diode pair 111 and the first diode 145 and the second diode 146 thereof may be substantially similar to the semiconductor structure 105, 160, or 170 and the first diode 45 and the second diode 46 thereof described herein with respect to FIGS. 1A to 1J, FIGS. 2A to 2E, FIGS. 3A to 3I, FIGS. 4A to 4F, FIGS. 5A to 5G, FIGS. 6A to 6H, FIGS. 7A to 7D, FIGS. 16A to 16D, and FIGS. 17A to 17C where like reference numerals indicate like elements.

As shown in FIGS. 8A and 8B, the second diode pair 112 disposed on the second side 100b of the memory unit 100. Each of the first diode 245 and the second diode 246 of the second diode pair 112 is electrically coupled to the electrode at the second side 100b of the memory unit 100. In some embodiments, the first diode 245 and the second diode 246 of the second diode pair 112 are arranged in the first direction 102a. The first diode 245 of the second diode pair 112 comprises a first doped region 241 and a second doped region 242. The second doped region 242 is disposed over and in contact with the first doped region 241. The second diode 246 of the second diode pair 112 comprises a third doped region 243 and a fourth doped region 244. The fourth doped region 244 is disposed over and in contact with the third doped region 243.. A top surface of the second doped region 242 is higher than a bottom surface of the third doped region 243, and a top surface of the fourth doped region 244 is higher than a bottom surface of the first doped region 241. Each of the first doped region 241 and the fourth doped region 244 is doped with a first conductivity-type of dopant, and each of the second doped region 242 and the third doped region 243 is doped with a second conductivity-type of dopant opposite to the first conductivity-type.

Details and formation methods of the second diode pair 112 and the first diode 245 and the second diode 246 thereof may be substantially similar to the semiconductor structure 105, 160, or 170 and the first diode 45 and the second diode 46 thereof described herein with respect to FIGS. 1A to 1J, FIGS. 2A to 2E, FIGS. 3A to 3I, FIGS. 4A to 4F, FIGS. 5A to 5G, FIGS. 6A to 6H, FIGS. 7A to 7D, FIGS. 16A to 16D, and FIGS. 17A to 17C where like reference numerals indicate like elements. In some embodiments, the second diode pair 112 can be manufactured simultaneously in the manufacturing process of the first diode pair 111. The memory device 1001 or similar semiconductor structures may be formed by processes similar to that described herein with respect to FIGS. 1A to 1J, FIGS. 2A to 2E, FIGS. 3A to 3I, FIGS. 4A to 4F, FIGS. 5A to 5G, FIGS. 6A to 6H, FIGS. 7A to 7D, FIGS. 16A to 16D, and FIGS. 17A to 17C.

As shown in FIG. 8A, the first diode 145 of the first diode pair 111 may further comprise a first ohmic contact 161 and a second ohmic contact 162. The first ohmic contact 161 may be in contact with the bottom surface of the first doped region 141 of the first diode pair 111. The second ohmic contact 162 may be in contact with the top surface of the second diode region 142. The second diode 146 of the first diode pair 111 may further comprise a third ohmic contact 163 and a fourth ohmic contact 164. The third ohmic contact 163 may be in contact with the bottom surface of the third doped region 143. The fourth ohmic contact 164 may be in contact with the top surface of the fourth doped region 144. The first diode 245 of the first diode pair 112 may further comprise a first ohmic contact 261 and a second ohmic contact 242. The first ohmic contact 261 may be in contact with the bottom surface of the first doped region 241. The second ohmic contact 262 may be in contact with the top surface of the second doped region 242. The second diode 246 of the second diode pair 112 may further comprise a third ohmic contact 263 and a fourth ohmic contact 264. The third ohmic contact 263 may be in contact with the bottom surface of the third doped region 243. The fourth ohmic contact 264 may be in contact with the top surface of the fourth doped region 244.

In some embodiments, the first doped region 141 may further comprise a first heavily-doped region 141a. The second doped region 142 may further comprise a second heavily-doped region 142a. The third doped region 143 may further comprise a third heavily-doped region 143a. The fourth doped region 144 may further comprise a fourth heavily-doped region 144a. An ohmic junction may be formed between the first ohmic contact 161 and the first heavily-doped region 141a, an ohmic junction may be formed between the second ohmic contact 162 and the second heavily-doped region 142a, an ohmic junction may be formed between the third ohmic contact 163 and the third heavily-doped region 163a, and an ohmic junction may be formed between the fourth ohmic contact 164 and the fourth heavily-doped region 164a.

In some embodiments, the first doped region 241 may further comprise a first heavily-doped region 241a. The second doped region 242 may further comprise a second heavily-doped region 242a. The third doped region 243 may further comprise a third heavily-doped region 243a. The fourth doped region 244 may further comprise a fourth heavily-doped region 244a. An ohmic junction may be formed between the first ohmic contact 261 and the first heavily-doped region 261a, an ohmic junction may be formed between the second ohmic contact 262 and the second heavily-doped region 262a, an ohmic junction may be formed between the third ohmic contact 263 and the third heavily-doped region 263a, and an ohmic junction may be formed between the fourth ohmic contact 264 and the fourth heavily-doped region 264a.

As shown in FIGS. 8A and 8B, each of the first diode 145 and the second diode 146 of the first diode pair 111 may be electrically coupled to the electrode 103 at the first side 100a of the memory unit 100, and each of the first diode 245 and the second diode 246 of the second diode pair 112 may be electrically coupled to the electrode at the second side 100b of the memory unit 100. In the embodiment shown in FIGS. 8A and 8B, the memory unit 100 is electrically coupled to the second ohmic contact 162 of the second diode 146 of the first diode pair 111 and the second contact layer 262 of the first diode 162 of the second diode pair 112. The memory unit 100 may also be electrically coupled to the fourth ohmic contact layer 164 of the first diode 145 of the first diode pair 111 and the fourth ohmic contact layer 264 of the second diode 246 of the second diode pair 112. In the embodiment where the second ohmic contacts 162 of the first diode pair 111 and the second ohmic contacts 262 of the second diode pair 112 are omitted, the memory unit 100 may be electrically coupled to the second doped region 142 of the first diode pair 111 and the second doped region 242 of the second diode pair 112. In the embodiment where the fourth ohmic contacts 164 of the first diode pair 111 and the fourth ohmic contacts 264 of the second diode pair 112 are omitted, the memory unit 100 may be electrically coupled to the fourth doped region 144 of the first diode pair 111 and the fourth doped region 242 of the second diode pair 112. In some other embodiments, the disposition of the first diode pair 111 and the second diode pair 112 may be interchangeable. In some other embodiments, the disposition of the first diode 145 and the second diode 146 of the first diode pair 111 may be interchangeable. In some other embodiments, the disposition of the first diode 145 and the second diode 146 of the second diode pair 112 may be interchangeable.

As shown in FIGS. 8A and 8B, a bit line 75 is formed over the memory unit 100. The memory unit 100 may be electrically coupled to the bit line 75 from the first end 101 of the memory unit 100. The bit line 75 may extend laterally in a second direction 102b. The second direction 102b is different from the first direction 102a. The materials and processes for forming the bit line 75 may be similar to that described above with respect to FIG. 1J, and the related description is omitted for brevity.

As shown in FIGS. 8A and 8B, both the first diode 145 and the second diode 146 of the first diode pair 111 are electrically coupled to a first word line WL1. The first word line WL1 extends in the second direction 102b. However, the present disclosure is not limited thereto. In some embodiments, the first word line WL1 may be electrically coupled to both the first ohmic contact 161 of the first diode 145 and the third ohmic contact 163 of the second diode 146. In some embodiments, the first word line WL1 may be disposed in the same layer as and between the first ohmic contact 161 and the third ohmic contact 163. In the embodiments where the first ohmic contact 161 of the first diode 145 is connected with the third ohmic contact 163 of the second diode 146, extension portions of the first ohmic contact 161 and/or the third ohmic contact 163 may function as a word line, and an additional wiring structure (e.g., the first word line WL1 in FIG. 8A) may not be required.

As shown in FIGS. 8A and 8B, the second diode 246 of the second diode pair 112 is electrically coupled to a third word line WL3, and the first diode 245 of the second diode pair 112 is electrically coupled to a fourth word line WL4. Both the third word line WL3 and the fourth word line WL4 extend in the first direction 102a. However, the present disclosure is not limited thereto. In some embodiments, the third word line WL3 may be electrically coupled to the third ohmic contact 253 of the first diode 246, and the fourth word line WL4 may be electrically coupled to the first ohmic contact 261 of the first diode 245.

The word lines WL1, WL3, and WL4 may comprise Pt, Pd, Ir, Ru, Cu, W, some other suitable material(s), or a combination of the foregoing and may be formed in the first dielectric structure 21 using a damascene or dual damascene process or any suitable method. The terms “word line” and “bit line” in the present disclosure are only being used for clarity and are not intended to limit the present disclosure. For example, in some instances, the word lines WL3 and WL4 shown in FIGS. 8A and 8B may be referred to as “bit lines”, while the word line WL1 is referred to as word line; in some instances, the word line WL1 shown in FIGS. 8A and 8B may be referred to as “bit line”, while the word lines WL3 and WL4 are referred to as word lines; or, in some instances, the bit line 75 shown in FIGS. 8A and 8B may be referred to as “read line”.

The memory device 1001 shown in FIGS. 8A and 8B may be a spin-orbit torque type MRAM device (SOT-MRAM) when the memory unit 100 comprises a magnetic tunnel junction (MTJ) structure. When a program current flows through the electrode 103, the spin Hall effect (SHE) of the electrode 103 produces spin injection to the free magnetic layer of the MTJ structure. A larger spin Hall effect may provide sufficient spin injection to switch the orientation of the magnetization of the free magnetic layer. The larger spin Hall effect can be achieved by using a suitable material with a high spin Hall effect (with a high spin injection efficiency) for the electrode 103 or by flowing a larger program current through the electrode 103.

For example, to conduct a data writing process, a program current may flow along a first current flow path from the first word line WL1 to the fourth word line WL4 through the second diode 146 of the first diode pair 111, the electrode 103, and the first diode 245 of the second diode pair 112; or, a program current may flow along a second current flow path from the third word line WL3 to the first word line WL1 through the second diode 246 of the second diode pair 112, the electrode 103, and the first diode 145 of the first diode pair 145. The flow and the direction of the program current may be controlled by the voltages applied to the word lines. Despite that only one memory cell is illustrated in FIG. 8A, a plurality of memory cells or an array of memory cells can be fabricated at the same time using the method disclosed herein.

FIG. 8B is a perspective view of the memory device 1001 shown in FIG. 8A disposed in a memory array MA1. As shown in FIG. 8B, the memory device 1001 and an adjacent memory device 1001′ are arranged in the second direction 102b and connected in series via the bit line 75 and the first word line WL1. The adjacent memory device 1001′ may be substantially similar to the memory device 1001, where like reference numerals indicate like elements.

As shown in FIG. 8B, the memory device 1001 may have cell dimensions of 8F and 4F respectively in the first direction 102a and the second direction 102b, which provides a cell size of 32 feature squares (F²). The symbol “F” herein denotes the minimum feature size (or one half of the minimum feature pitch) normally associated with a particular lithography process.

In the embodiment shown in FIGS. 8A and 8B, a memory device including two pairs of PN diodes as a selector can be fabricated by using the method disclosed herein. The first diode pair 111 and the second diode pair 112 each comprising two diodes arranged in opposite directions while being located at about the same level as described above, therefore, the memory device disclosed herein may include a simplified routing structure and may have a reduced cell size. Moreover, the SOT-MRAM memory device disclosed herein may have a lower programming voltages, a lower write error rates, and a lower resistance of the current flow path than a STT-MRAM memory device and may switch faster (e.g., in less than 10 ns). The memory device disclosed herein may also provide a higher current density than a memory device using a transistor as selector, and may have desired properties such as greater efficiency, faster memory access, and low power consumption.

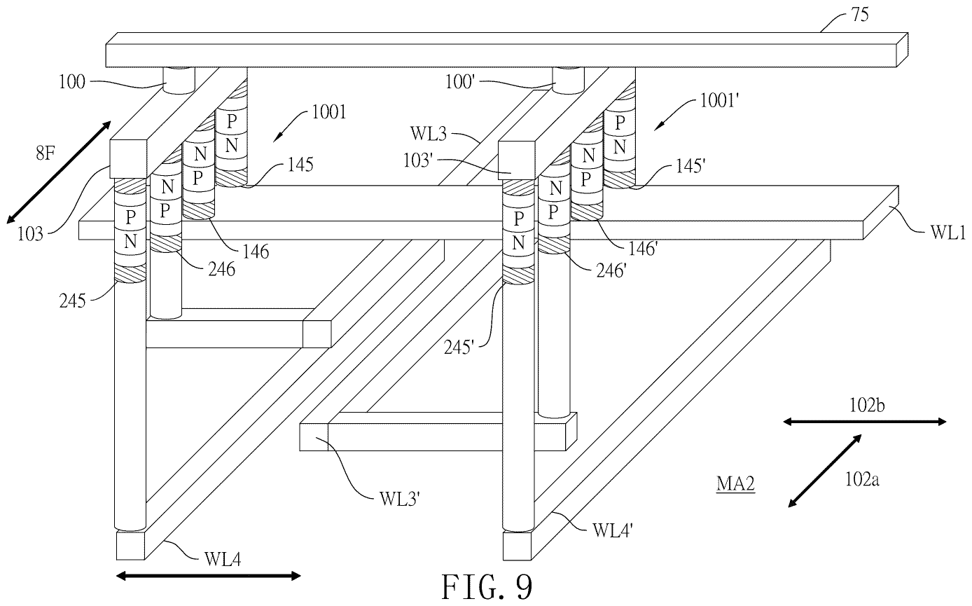

FIG. 9 is a schematic view to illustrate an embodiment of a memory device according to the present disclosure. FIG. 9 is a perspective view of the memory device 1001 shown in FIG. 8A disposed in a memory array MA2. The memory array MA2 shown in FIG. 9 may be substantially similar to the memory array MA1 described above with respect to FIGS. 8A and 8B, where like reference numerals indicate like elements. Referring to FIG. 9, the third word line WL3′ of the memory device 1001′ may be vertically overlapped (e.g., in a third direction perpendicular to both the first direction 102a and the second direction 102b) with the third word line WL3 of the memory device 1001. The arrangement of the memory array MA2 as shown in FIG. 9 may further reduce the cell dimensions of the memory devices 1001 and 1001′ to 8F and 3F respectively in the first direction 102a and the second direction 102b, which provides a cell size of 24 feature squares (F²).

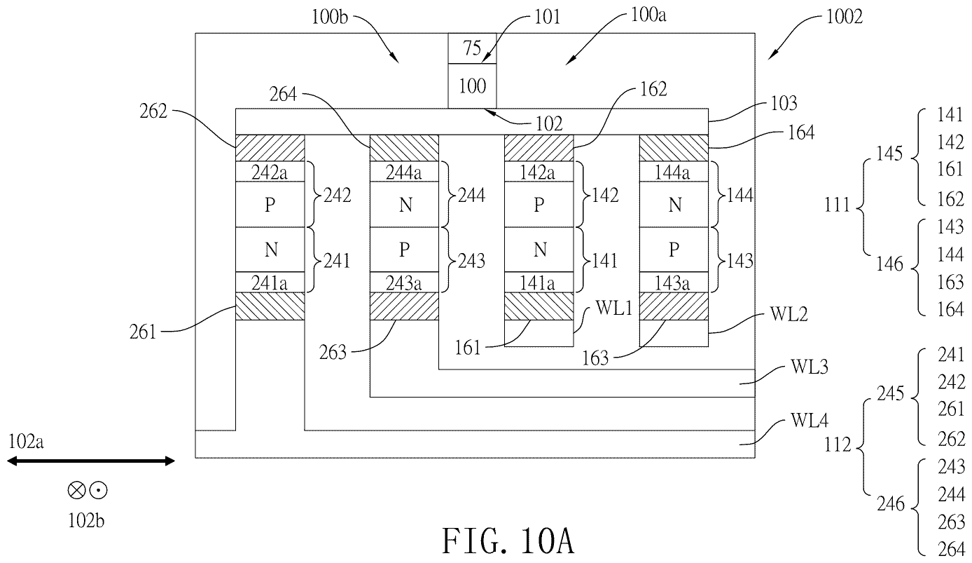

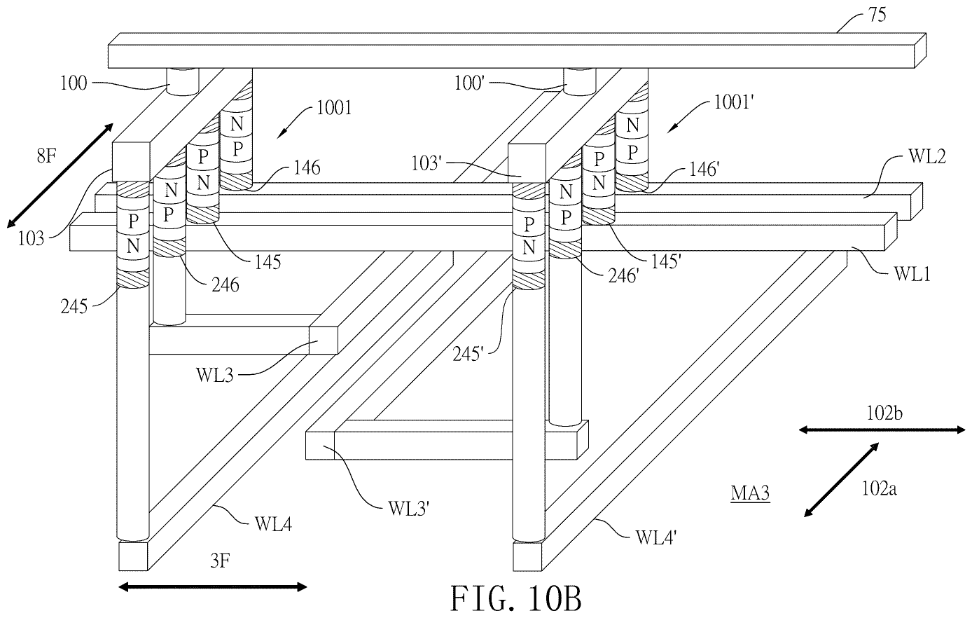

FIGS. 10A to 10B are schematic views to illustrate an embodiment of a memory device according to the present disclosure. As shown in FIGS. 10A and 10B, a memory device 1002 is provided. The memory device 1002 shown in FIGS. 10A and 10B may be substantially similar to the memory device 1001 described above with respect to FIGS. 8A, 8B, and 9 where like reference numerals indicate like elements.

As shown in FIGS. 10A and 10B, the first diode 145 of the first diode pair 111 is electrically coupled to a first word line WL1, and the second diode 146 of the first diode pair 111 is electrically coupled to a second word line WL2. Both the first word line WL1 and the second word line WL2 extend in the second direction 102b. In some embodiments, the first word line WL1 may be electrically coupled to the first ohmic contact 161 of the first diode 145 of the first diode pair 111, and the second word line WL2 may be electrically coupled to the third ohmic contact 163 of the second diode 146 of the first diode pair 111. In some embodiments, the first word line WL1 may be disposed in the same layer as the first ohmic contact 161. In some embodiments, the second word line WL2 may be disposed in the same layer as the third ohmic contact 163. In some embodiments, extension portion(s) of the first ohmic contact 161 may function as a word line, such that an additional wiring layer (e.g., the first word line WL1 in FIG. 10A) may not be required. In some embodiments, extension portion(s) of the third ohmic contact 163 may function as a word line, such that an additional wiring layer (e.g., the second word line WL2 in FIG. 10A) may not be required. The first word line WL1 and the second word line WL2 may be formed using similar materials and methods as the word lines WL1, WL3, and WL4 described above with reference to FIG. 8A. The description of the bit line 75, the third word line WL3, and the fourth word line WL4 with respect to FIGS. 8A and 8B may apply here if applicable. In some other embodiments, the disposition of the first diode pair 111 and the second diode pair 112 may be interchangeable. In some other embodiments, the disposition of the first diode 145 and the second diode 146 of the first diode pair 111 may be interchangeable. In some other embodiments, the disposition of the first diode 245 and the second diode 246 of the second diode pair 112 may be interchangeable.

The memory device 1002 shown in FIGS. 10A and 10B may be a SOT-MRAM device when the memory unit 100 comprises a magnetic tunnel junction (MTJ) structure. The related details of the SOT-MRAM device may be substantially similar to the SOT-MRAM device described above with respect to FIG. 8A, where like reference numerals indicate like elements. In the embodiment shown in FIG. 10A, to conduct a data writing process, a program current may flow along a first current flow path from the first word line WL2 to the fourth word line WL4 through the second diode 146 of the first diode pair 111, the electrode 103, and the first diode 245 of the second diode pair 112; or, a program current may flow along a second current flow path from the third word line WL3 to the second word line WL1 through the second diode 246 of the second diode pair 112, the electrode 103, and the first diode 145 of the first diode pair 111. The flow and the direction of the program current may be controlled by the voltages applied to the word lines. Despite that only one memory cell is illustrated in FIG. 10A, a plurality of memory cells or an array of memory cell can be fabricated at the same time using the method disclosed herein.

FIG. 10B is a perspective view of the memory device 1002 shown in FIG. 10A disposed in a memory array MA3. As shown in FIG. 10B, the memory device 1002 and an adjacent memory device 1002′ are arranged in the second direction 102b and connected in series via the bit line 75, the first word line WL1, and the second word line WL2. The adjacent memory device 1002′ may be substantially similar to the memory device 1002, where like reference numerals indicate like elements. With the arrangement shown in FIG. 10B, the memory device 1002 may have cell dimensions of 8F and 3F respectively in the first direction 102a and the second direction 102b, which provides a cell size of 24 feature squares (F²).

Compared to the four-terminal memory device 1001 shown in FIGS. 8A to 8B and FIG. 9 (e.g., connected to the first word line WL1, the third word line WL3, the fourth word line WL4, and the bit line 75), the memory device 1002 is a five-terminal memory device (e.g., connected to the first word line WL1, the second word line WL2, the third word line WL3, the fourth word line WL4, and the bit line 75). The five-terminal memory device 1002 may provide additional options for controlling the voltage of each line and may enable different operation modes and/or improve the performance of the memory devices.

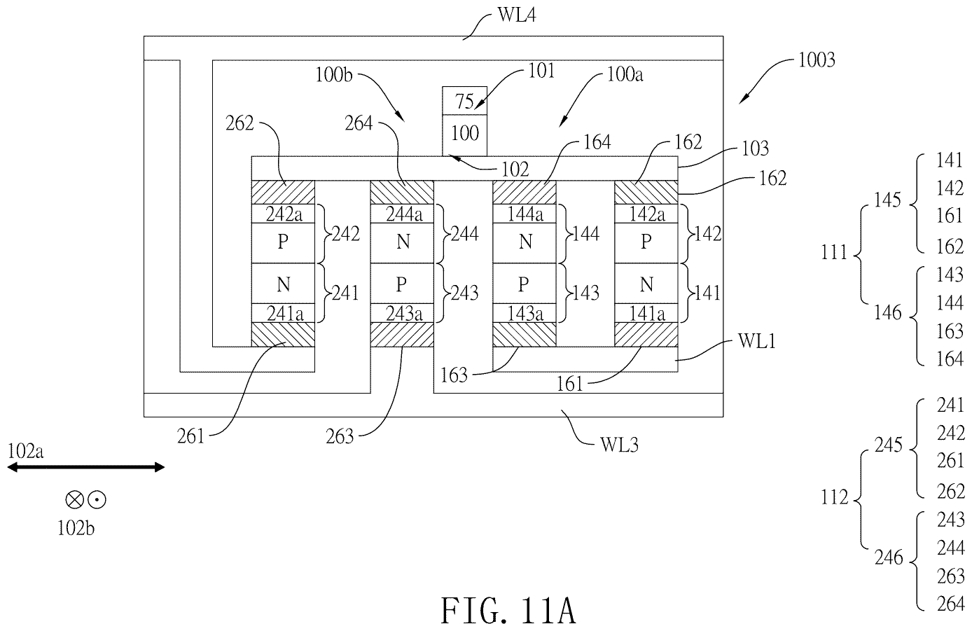

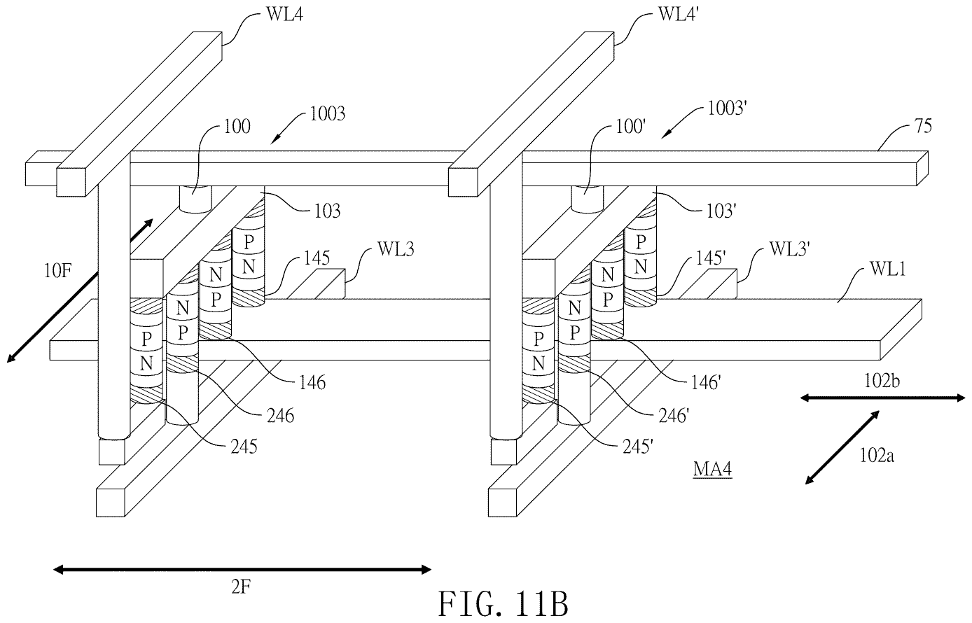

FIGS. 11A to 11B are schematic views to illustrate an embodiment of a memory device according to the present disclosure. As shown in FIGS. 11A and 11B, a memory device 1003 is provided. The memory device 1003 shown in FIGS. 11A and 11B may be substantially similar to the memory device 1001 described above with respect to FIGS. 8A and 8B, where like reference numerals indicate like elements.

As shown in FIGS. 11A and 11B, the fourth word line WL4 is disposed over the electrode 103, such that the memory unit 100 is disposed vertically between the fourth word line WL4 and the electrode 103. In some embodiments, the fourth word line WL4 is disposed over the memory unit 100. Other description of the bit line 75, the word lines WL1, WL3, and WL4 with respect to FIGS. 8A and 8B may apply here if applicable. In some other embodiments, the disposition of the first diode pair 111 and the second diode pair 112 may be interchangeable. In some other embodiments, the disposition of the first diode 145 and the second diode 146 of the first diode pair 111 may be interchangeable. In some other embodiments, the disposition of the first diode 245 and the second diode 246 of the second diode pair 112 may be interchangeable. In some other embodiments, similar to the memory device 1002 shown in FIGS. 10A and 10B, the first diode 145 may be electrically coupled to a first word line WL1, and the second diode 146 may be electrically coupled to a second word line WL2.

The memory device 1003 shown in FIGS. 11A and 11B may be a SOT-MRAM device when the memory unit 100 comprises a magnetic tunnel junction (MTJ) structure. The related details of the SOT-MRAM device may be substantially similar to the SOT-MRAM device described above with respect to FIG. 8A, where like reference numerals indicate like elements.

FIG. 11B is a perspective view of the memory device 1003 shown in FIG. 11A disposed in a memory array MA4. The memory device 1003 and an adjacent memory device 1003′ are arranged in the second direction 102b and connected in series via the bit line 75 and the first word line WL1. The adjacent memory device 1003′ may be substantially similar to the memory device 1003, where like reference numerals indicate like elements. As shown in FIG. 11B, the third word line WL3 and the fourth word line WL4 are vertically aligned. Specifically, the third word line WL3, the fourth word line WL4, and the electrode 103 may be vertically aligned, such that the cell size of the memory device 1003 can be further reduced. With the arrangement shown in FIG. 11B, the memory device 1003 may have cell dimensions of 10F and 2F respectively in the first direction 102a and the second direction 102b, which provides a cell size of 20 feature squares (F²). The structure of the memory devices 1003 and 1003′ and the arrangement of the memory array MA4 may further reduce the cell dimensions of the memory devices 1003 and 1003′.

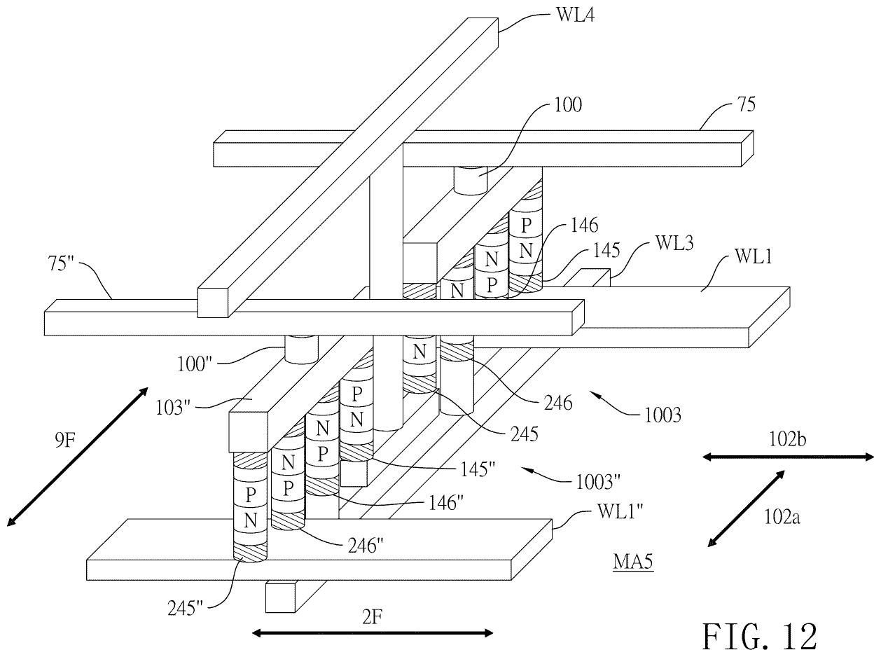

FIG. 12 is a schematic view to illustrate an embodiment of a memory device according to the present disclosure. FIG. 12 is a perspective view of the memory device 1003 shown in FIG. 11A disposed in a memory array MA5. The memory device 1003 and another adjacent memory device 1003″ are arranged in the first direction 102a and connected in series via the third word line WL3. The adjacent memory device 1003″ may be substantially similar to the memory device 1003, where like reference numerals indicate like elements. As shown in FIG. 12, the memory devices 1003 and 1003″ can share the fourth word line WL4. With the arrangement shown in FIG. 12, the memory device 1003 may have cell dimensions of 9F and 2F respectively in the first direction 102a and the second direction 102b, which provides a cell size of 18 feature squares (F²). The arrangement of the memory array MA5 may further reduce the cell dimensions of the memory devices 1003 and 1003′.

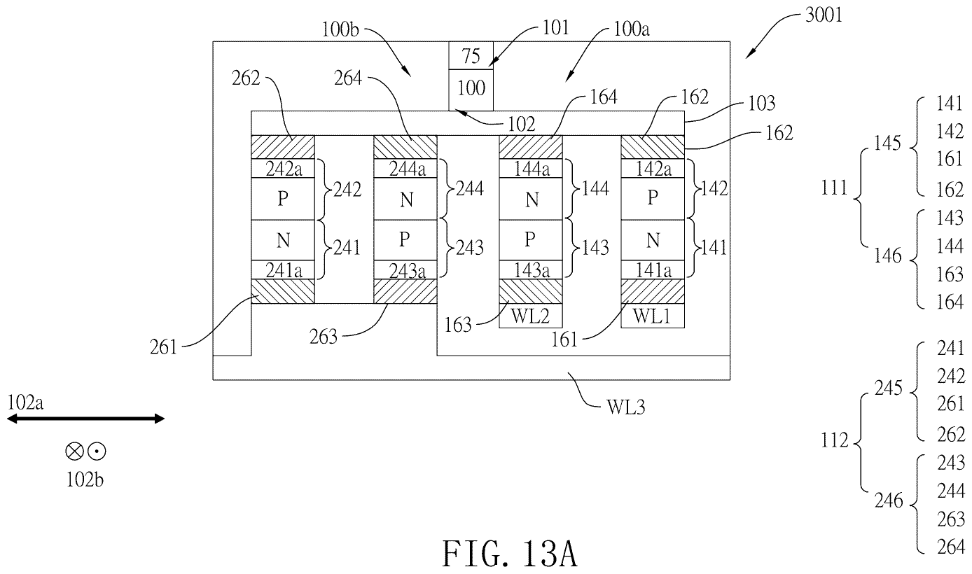

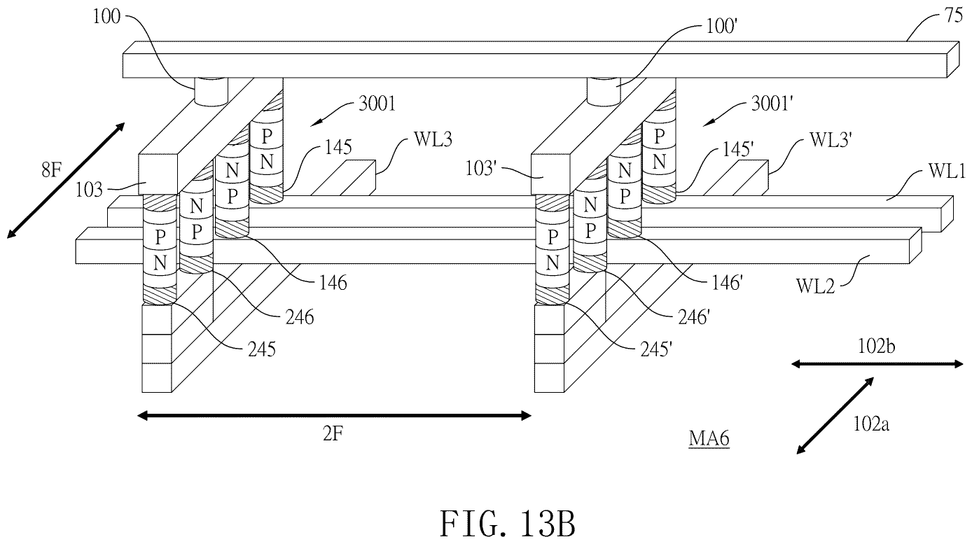

FIGS. 13A to 13B are schematic views to illustrate an embodiment of a memory device according to the present disclosure. As shown in FIGS. 13A and 13B, a memory device 3001 is provided. The memory device 3001 shown in FIGS. 13A and 13B may be substantially similar to the memory device 1002 described above with respect to FIGS. 10A and 10B, where like reference numerals indicate like elements.

As shown in FIGS. 13A and 13B, both the first diode 245 and the second diode 246 of the second diode pair 112 are electrically coupled to a third word line WL3. The third word line WL3 extends in the first direction 102a. In some embodiments, the third word line WL3 may be electrically coupled to the first ohmic contact 261 of the first diode 245 of the second diode pair 112 and the third ohmic contact 263 of the second diode 246 of the second diode pair 112. The third word line WL3 may be formed using similar materials and methods as that described above with reference to FIG. 8A. The description of the bit line 75, the first word line WL1, and the second word line WL2 with respect to FIGS. 10A and 10B may apply here if applicable. In some other embodiments, the disposition of the first diode pair 111 and the second diode pair 112 may be interchangeable. In some other embodiments, the disposition of the first diode 145 and the second diode 146 of the first diode pair 111 may be interchangeable. In some other embodiments, the disposition of the first diode 245 and the second diode 246 of the second diode pair 112 may be interchangeable.

The memory device 3001 shown in FIGS. 13A and 13B may be a SOT-MRAM device when the memory unit 100 comprises a magnetic tunnel junction (MTJ) structure. The related details of the SOT-MRAM device may be substantially similar to the SOT-MRAM device described above with respect to FIG. 8A, where like reference numerals indicate like elements. In the embodiment shown in FIG. 13A, to conduct a data writing process, a program current may flow along a first current flow path from the second word line WL2 to the third word line WL3 through the second diode 146 of the first diode pair 111, the electrode 103, and the first diode 245 of the second diode pair 112; or, a program current may flow along a second current flow path from the third word line WL3 to the first word line WL1 through the second diode 246 of the second diode pair 112, the electrode 103, and the first diode 145 of the first diode pair 111. The flow and the direction of the program current may be controlled by the voltages applied to the word lines. Despite that only one memory cell is illustrated in FIG. 13A, a plurality of memory cells or an array of memory cell can be fabricated at the same time using the method disclosed herein.

FIG. 13B is a perspective view of the memory device 3001 shown in FIG. 13A disposed in a memory array MA6. As shown in FIG. 13B, the memory device 3001 and an adjacent memory device 3001′ are arranged in the second direction 102b and connected in series via the bit line 75, the first word line WL1, and the second word line WL2. The adjacent memory device 3001′ may be substantially similar to the memory device 3001, where like reference numerals indicate like elements. As shown in FIG. 13B, the third word line WL3 may be disposed vertically below the electrode 103, the first word line WL1, and the second word line WL2. The third word line WL3 and the electrode 103 may be vertically aligned. With the arrangement of the memory array MA6 as shown in FIG. 13B, the cell dimensions of the memory devices 3001 and 3001′ can be further reduce to 8F and 2F respectively in the first direction 102a and the second direction 102b, which provides a cell size of 16 feature squares (F²).

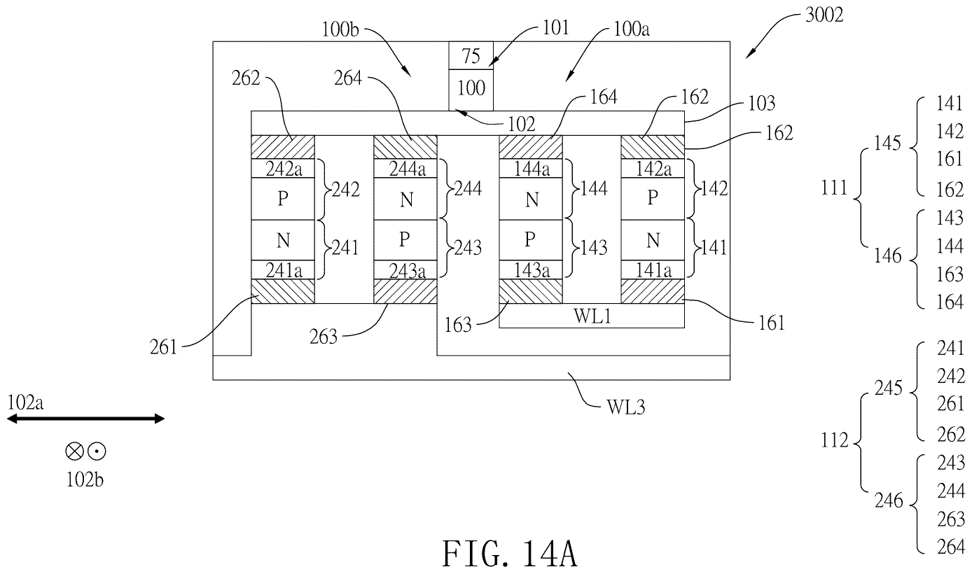

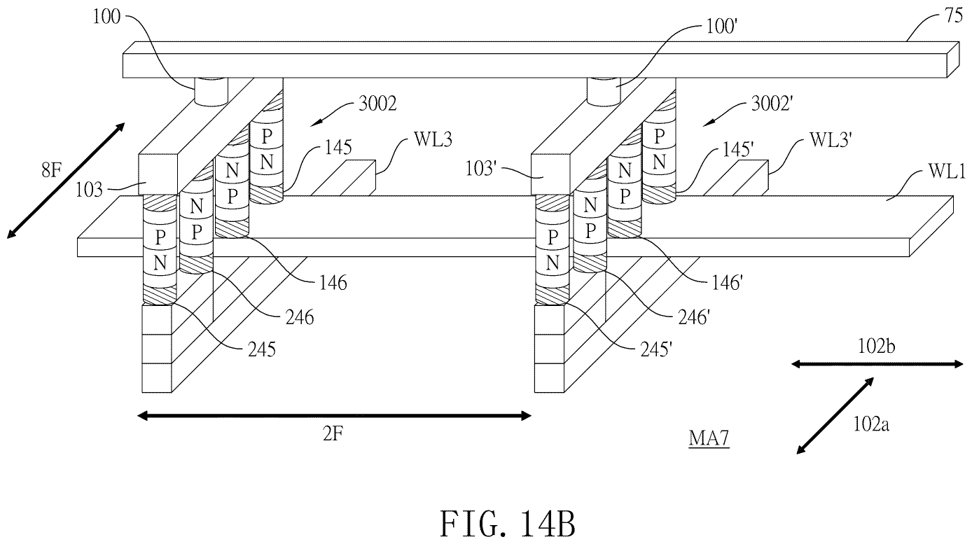

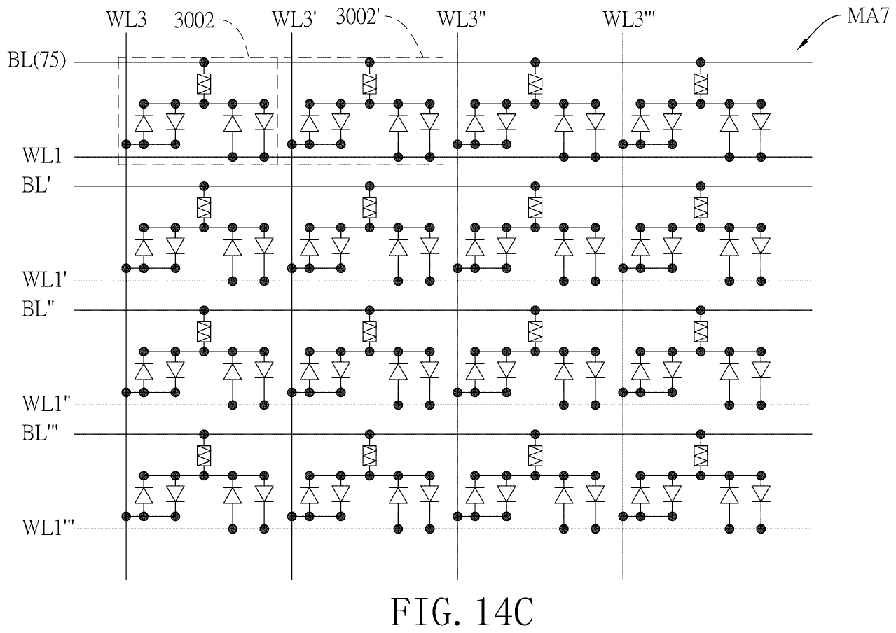

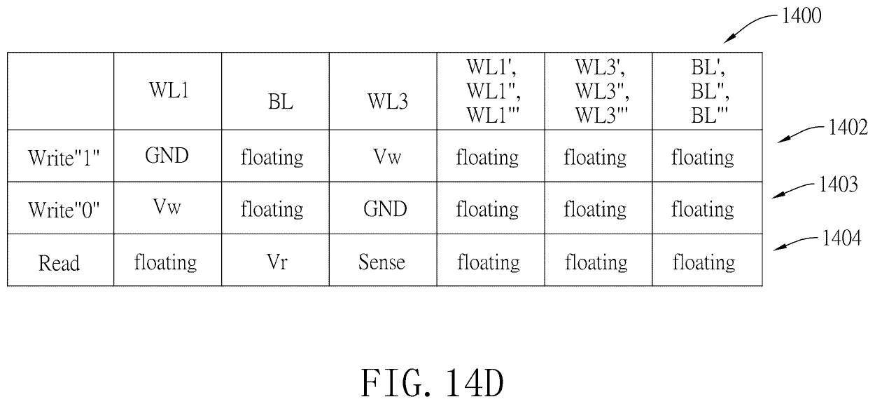

FIGS. 14A to 14D are schematic views to illustrate an embodiment of a memory device according to the present disclosure. FIG. 14C is an electronic schematic diagram to illustrate a memory array including the memory device as shown in FIGS. 14A and 14B. FIG. 14D is a table of operation voltage of the memory cells in the memory array as shown in FIG. 14C. As shown in FIGS. 14A and 14B, a memory device 3002 is provided. The memory device 3002 shown in FIGS. 14A and 14B may be substantially similar to the memory device 1001 and the memory device 3001 described above with respect to FIGS. 8A to 9 and FIGS. 13A and 13B where like reference numerals indicate like elements.

As shown in FIGS. 14A and 14B, both the first diode 145 and the second diode 146 are electrically coupled to a first word line WL1. The description of the first word line WL1 above with respect to FIGS. 8A and 8B may apply here if applicable. As shown in FIGS. 14A and 14B, both the first diode 245 and the second diode 246 are electrically coupled to a third word line WL3. The description of the third word line WL3 above with respect to FIGS. 13A and 13B may apply here if applicable. In some other embodiments, the disposition of the first diode pair 111 and the second diode pair 112 may be interchangeable. In some other embodiments, the disposition of the first diode 145 and the second diode 146 of the first diode pair 111 may be interchangeable. In some other embodiments, the disposition of the first diode 245 and the second diode 246 of the second diode pair 112 may be interchangeable.

The memory device 3002 shown in FIGS. 14A and 14B may be a SOT-MRAM device when the memory unit 100 comprises a magnetic tunnel junction (MTJ) structure. The related details of the SOT-MRAM device may be substantially similar to the SOT-MRAM device described above with respect to FIG. 13A, where like reference numerals indicate like elements. In the embodiment shown in FIG. 14A, to conduct a data writing process, a program current may flow along a first current flow path from the first word line WL1 to the third word line WL3 through the second diode 146 of the first diode pair 111, the electrode 103, and the first diode 245 of the second diode pair 112; or, a program current may flow along a second current flow path from the third word line WL3 to the first word line WL1 through the second diode 246 of the second diode pair 112, the electrode 103, and the first diode 145 of the first diode pair 111. The flow and the direction of the program current may be controlled by the voltages applied to the word lines. Despite that only one memory cell is illustrated in FIG. 14A, a plurality of memory cells or an array of memory cell can be fabricated at the same time using the method disclosed herein.

FIG. 14B is a perspective view of the memory device 3002 shown in FIG. 14A disposed in a memory array MA7. As shown in FIG. 14B, the memory device 3002 and an adjacent memory device 3002′ are arranged in the second direction 102b and connected in series via the bit line 75 and the first word line WL1. The adjacent memory device 3002′ may be substantially similar to the memory device 3002, where like reference numerals indicate like elements. As shown in FIG. 14B, the third word line WL3 may be disposed vertically below the electrode 103 and the first word line WL1. The third word line WL3 and the electrode 103 may be vertically aligned. With the arrangement of the memory array MA6 as shown in FIG. 14B, the cell dimensions of the memory devices 3002 and 3002′ may be 8F and 2F respectively in the first direction 102a and the second direction 102b, which provides a cell size of 16 feature squares (F²). The arrangement of the memory array MA7 shown in FIG. 14B may further reduce the memory cell size of the memory devices.

Compared to the four-terminal memory device 3001 shown in FIGS. 13A to 13B (e.g., connected to the first word line WL1, the second word line WL2, the third word line WL3, and the bit line 75), the memory device 3002 is a three-terminal memory device (e.g., connected to the first word line WL1, the third word line WL3, and the bit line 75). The three-terminal memory device 3002 may provide additional options for voltage control and may simplify the routing of power rails and/or signal lines while having a relatively small memory cell size.

FIG. 14C is an electronic schematic diagram to illustrate a memory array including the memory devices as shown in FIGS. 14A and 14B. As shown in FIG. 14C, the memory devices 3002 and 3002′ as shown in FIG. 14B and a plurality of memory devices similar to the memory devices 3002 are arranged within the memory array MA7 in rows and columns. Despite showing sixteen memory devices in FIG. 14C, the number of the memory devices included in the memory array MA7 is not limited thereto.

In the embodiment shown in FIG. 14C, the memory array MA7 is controlled by a plurality of bit lines BL, BL′, BL″, and BL″′, a plurality of first word lines WL1, WL1′, WL1″, and WL1′″, and a plurality of third word lines WL3, WL3′, WL3″, and WL3′″. The numbers of the bit lines and the word lines are not limited thereto.

FIG. 14D shows an exemplified table of operation voltage of a memory cell (e.g., the memory device 3002) in the memory array MA7 as shown in FIG. 14C.

Referring to a second row 1402 of the table 1400, when the memory device 3002 is selected for a first write operation (e.g., write “1”), a write voltage (Vw) is applied to the third word line WL3, the first word line WL1 is ground (GND), and the bit line BL is electrically floating, while other lines, e.g., the first word lines WL1′, WL1″, and WL1″′, the third word lines WL3′, WL3″, and WL3″′, and the bit lines BL′, BL″, and BL″′, are electrically floating.

Referring to a third row 1403 of table 1400, when the memory device 3002 is selected for a second write operation (e.g., write “0”), a write voltage (Vw) is applied to the first word line WL1, the third word line WL3 is ground (GND), and the bit line BL is electrically floating, while other lines, e.g., the first word lines WL1′, WL1″, and WL1″′, the third word lines WL3′, WL3″, and WL3″′, and the bit lines BL′, BL″, and BL″′, are electrically floating.

Referring to a fourth row 1404 of table 1400, when the memory device 3002 is selected for reading, a read voltage (Vr) is applied to the bit line BL, the first word line WL1 is electrically floating, while other lines, e.g., the first word lines WL1′, WL1″, and WL1″′, the third word lines WL3′, WL3″, and WL3″′, and the bit lines BL′, BL″, and BL″′, are electrically floating. The state of the memory unit can be determined through sensing a voltage of the third word line WL3. Table 1400 shows a set of possible operation voltage for the memory device. However, the present disclosure is not limited thereto.

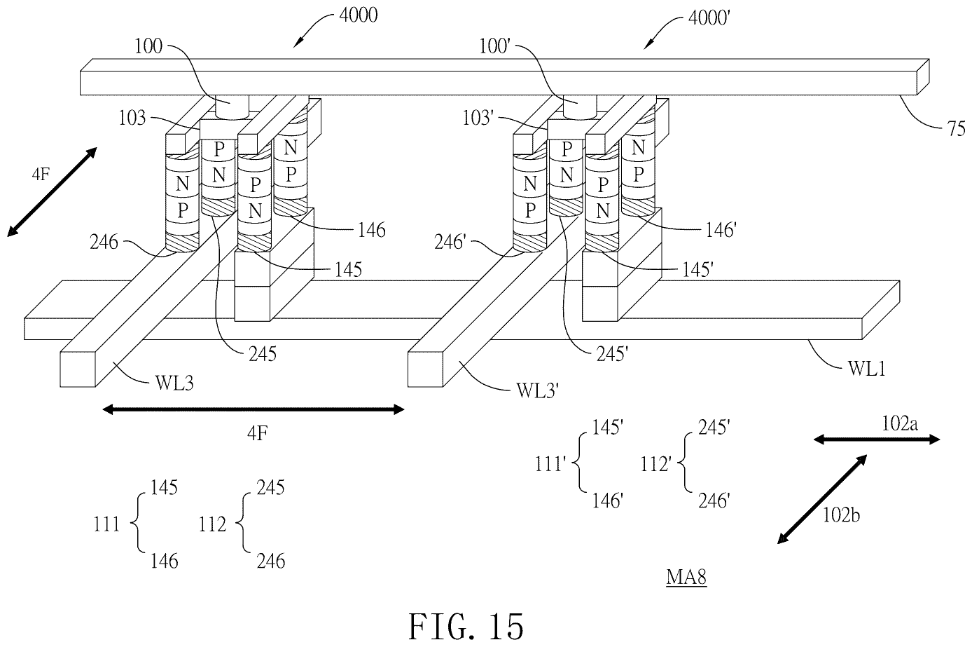

FIG. 15 is a schematic view to illustrate an embodiment of a memory device according to the present disclosure. As shown in FIG. 15, a memory device 4000 is provided. The memory device 4000 shown in FIG. 15 may be substantially similar to the memory device 3002 described above with respect to FIGS. 14A and 14B, where like reference numerals indicate like elements.

As shown in FIG. 15, the first diode 145 and the second diode 146 of the first diode pair 111 are arranged in a second direction 102b different from a first direction 102a. The first diode 245 and the second diode 246 of the second diode pair 112 are arranged in the second direction 102b. In the embodiment shown in FIG. 15, the bit line 75 extends in the first direction 102a. However, the present disclosure is not limited thereto. In some other embodiments, the disposition of the first diode pair 111 and the second diode pair 112 may be interchangeable. In some other embodiments, the disposition of the first diode 145 and the second diode 146 of the first diode pair 111 may be interchangeable. In some other embodiments, the disposition of the first diode 245 and the second diode 246 of the second diode pair 112 may be interchangeable.

The memory device 4000 shown in FIG. 15 may be a SOT-MRAM device when the memory unit 100 comprises a magnetic tunnel junction (MTJ) structure. The related details of the SOT-MRAM device may be substantially similar to the SOT-MRAM device described above with respect to FIG. 8A, where like reference numerals indicate like elements. In the embodiment shown in FIG. 15, to conduct a data writing process, a program current may flow along a first current flow path from the first word line WL1 to the third word line WL3 through the second diode 146 of the first diode pair 111, the electrode 103, and the first diode 245 of the second diode pair 112; or, a program current may flow along a second current flow path from the third word line WL3 to the first word line WL1 through the second diode 246 of the second diode pair 112, the electrode 103, and the first diode 146 of the first diode pair 111. The flow and the direction of the program current may be controlled by the voltages applied to the word lines.

FIG. 15 is a perspective view of the memory device 4000 disposed in a memory array MA7. As shown in FIG. 15, the memory devices 4000 and an adjacent memory device 4000′ are arranged in the first direction 102a and connected in series via the bit line 75 and the first word line WL1. The adjacent memory device 4000′ may be substantially similar to the memory device 4000, where like reference numerals indicate like elements. With the arrangement of the memory array MA8 as shown in FIG. 15, the cell dimensions of the memory devices 4000 and 4000′ may be 4F and 4F respectively in the first direction 102a in and the second direction 102b, which provides a cell size of 16 feature squares (F²). The three-terminal memory device 4000 may provide additional options for voltage control and may simplify the routing of power rails and/or signal lines while having a relatively small memory cell size.

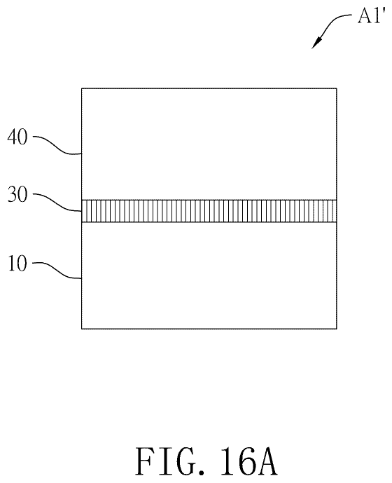

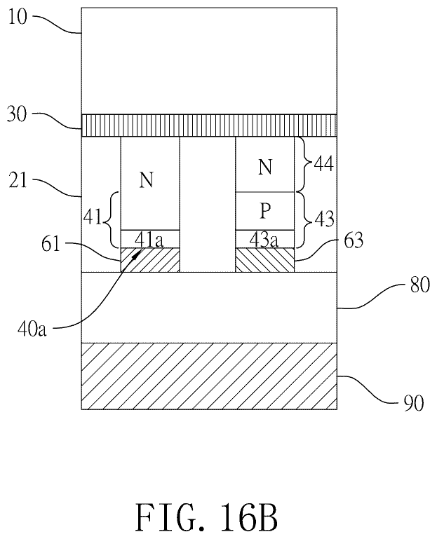

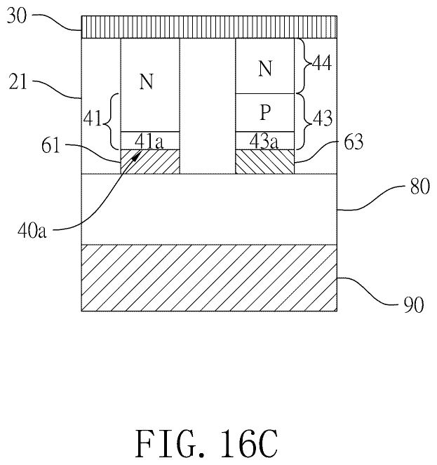

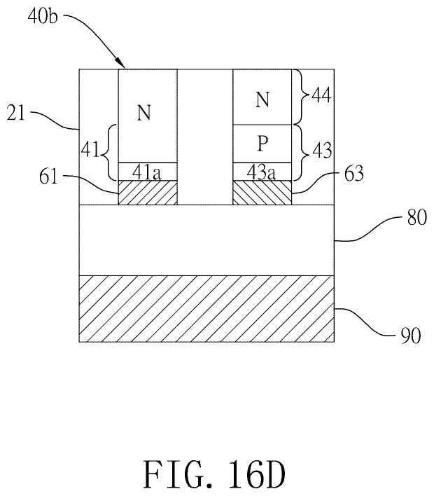

FIGS. 16A to 16D are schematic diagrams illustrating intermediate stages in the manufacture of a semiconductor structure according to one embodiment of the present disclosure. As shown in FIG. 16A, a semiconductor substrate A1′ is provided (step (a)). The semiconductor substrate A1′ comprises a first substrate 10 and a second substrate 40 on the first substrate 10. The first substrate 10 and the second substrate 40 may be substantially similar to the first substrate 10 and the second substrate 40 described above with respect to FIG. 1A, and the related description is omitted for brevity. The semiconductor substrate A1′ further comprises an etch stop layer 30 between the first substrate 10 and the second substrate 40. The etch stop layer 30 may have a high etch selectivity against the first substrate 10.

In the embodiment shown in FIG. 16A, the first substrate 10 may comprise silicon or germanium. In some other embodiments, the first substrate 10 may comprise glass, polysilicon, or ceramic. The etch stop layer 30 may comprise silicon germanium (SiGe). The second substrate 40 may comprise semiconductor material, such as silicon or germanium. In some embodiments, the etch stop layer 30 and the second substrate 40 may be sequentially formed on the first substrate 10, e.g., by epitaxial growth, to form the semiconductor substrate A1′.

As shown in FIG. 16B, a third substrate 90 is added to the first surface 40a of the second substrate 40, wherein the second substrate 40 is located between the third substrate 90 and the first substrate 10 (step (d)). The structure shown in FIG. 16B may be formed by processes substantially similar to that described above with respect to FIGS. 1A to 1F, where like reference numerals indicate like elements.

As shown in FIG. 16C, the first substrate 10 is removed to expose the etch stop layer 30. The first substrate 10 may be removed by performing suitable process(es) such as grinding, chemical mechanical polishing (CMP), and etching process. In one embodiment, a portion of the first substrate 10 is removed by grinding and/or CMP process, and the remaining portion of the first substrate 10 may be removed by one or more etching process. In the embodiment shown in FIG. 16C, the etch stop layer 30 can protect the fourth doped region 44, a region in the second substrate 40 in which the second doped region is predetermined to be formed, and the first dielectric structure 21 from the etching process.

As shown in FIG. 16D, at least a portion of the etch stop layer 30 is removed. The etch stop layer 30 may be removed by oxide etching, plasma etching, hydrogen peroxide etching, the like, and/or any suitable method. At least a portion of a second surface 40b of the second substrate 40 is exposed after the removal of the etch stop layer 30. By methods disclosed herein, the exposed second surface 40b of the second substrate 40 may have better planarity, thus the heights of the diodes formed in the second substrate 40 may be more uniform and more controllable. Also, endpoint of etching process that removes the first substrate 10 may be easier to control. Semiconductor structures substantially similar to the semiconductor structure 104 and semiconductor structure 105 described above can be formed from the structure showed in FIG. 16D by process(es) similar to that described above with respect to FIGS. 1H to 1J. In some embodiments, the manufacturing process described above with respect to FIGS. 2A to 2E may start from the semiconductor substrate A1′ shown in FIG. 16A.

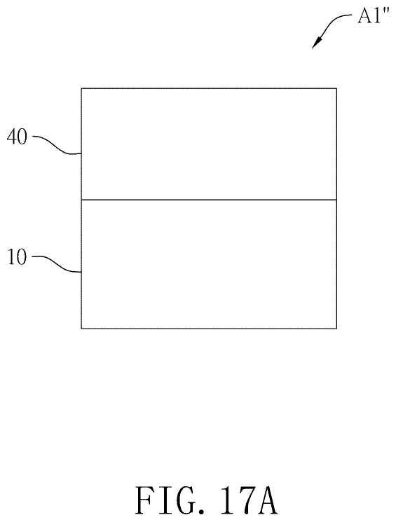

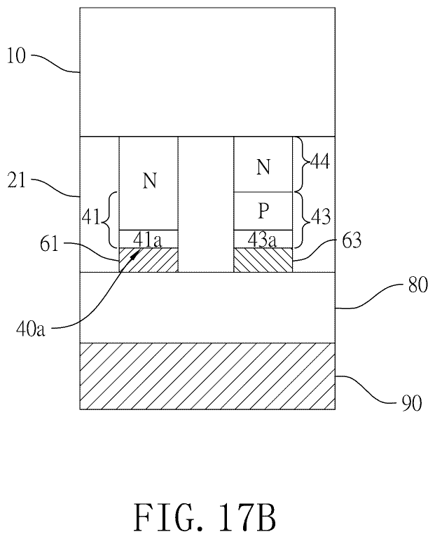

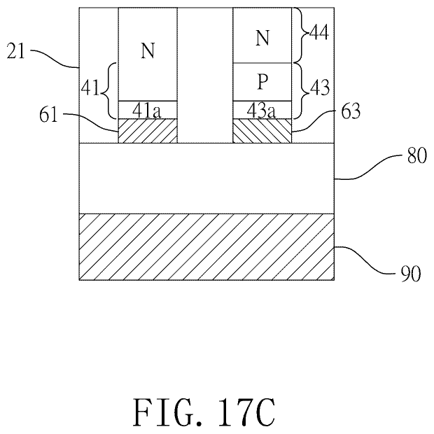

FIGS. 17A to 17C are schematic diagrams illustrating intermediate stages in the manufacture of a semiconductor structure according to one embodiment of the present disclosure. As shown in FIG. 17A, a semiconductor substrate A1″ is provided (step (a)). The semiconductor substrate A1″ comprises a first substrate 10 and a second substrate 40 on the first substrate. The first substrate 10 and the second substrate 40 may be substantially similar to the first substrate 10 and the second substrate 40 described above with respect to FIG. 1A, and the related description is omitted for brevity.

In the embodiment shown in FIG. 17A, the first substrate 10 may comprise silicon or germanium. In some other embodiments, the first substrate 10 may comprise glass, polysilicon, or ceramic. The second substrate 40 may comprise silicon germanium (SiGe). In some embodiments, the second substrate 40 may be formed on the first substrate 10 by epitaxial growth to form the semiconductor substrate A1″.

As shown in FIG. 17B, a third substrate 90 is added to the first surface 40a of the second substrate 40, wherein the second substrate 40 is located between the third substrate 90 and the first substrate 10 (step (d)). The structure shown in FIG. 17B may be formed by processes substantially similar to that described above with respect to FIGS. 1A to 1F, where like reference numerals indicate like elements.

As shown in FIG. 17C, the first substrate 10 is removed to expose the second substrate 40. The first substrate 10 may be removed by performing suitable process(es) such as grinding, chemical mechanical polishing (CMP), and etching process. At least a portion of a second surface 40b of the second substrate 40 is exposed after the removal of the first substrate 10. In one embodiment, a portion of the first substrate 10 is removed by grinding and/or CMP process, and the remaining portion of the first substrate 10 may be removed by one or more etching process. Semiconductor structures substantially similar to the semiconductor structure 104 and semiconductor structure 105 described above can be formed from the structure showed in FIG. 17D by process(es) similar to that described above with respect to FIGS. 1H to 1J. In some embodiments, the manufacturing process described above with respect to FIGS. 2A to 2E may start from the semiconductor substrate A1″ shown in FIG. 17A.

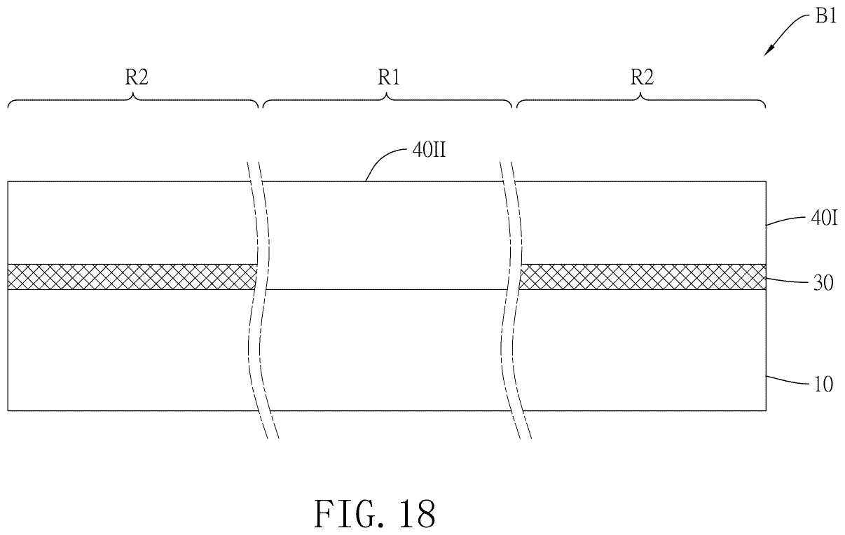

FIG. 18 is a schematic view to illustrate an embodiment of a semiconductor substrate according to the present disclosure. As shown in FIG. 18, a semiconductor substrate B1 is provided. The semiconductor substrate B1 may be used as the semiconductor substrate in step (a) in the methods discussed above. The semiconductor substrate B1 may comprise a first region R1 and a second region R2. The first region R1 of the semiconductor substrate B1 may be substantially similar to the semiconductor substrate A1″ described above with respect to FIG. 17A, and the second region R2 of the semiconductor substrate B1 may be substantially similar to the semiconductor substrate A1′ described above with respect to FIG. 16A, where like reference numerals indicate like elements. In the embodiment shown in FIG. 18, the first substrate 10 may comprise silicon or germanium. The etch stop layer 30 may comprise silicon germanium (SiGe). The second substrate 40I in the first region R1 may comprise silicon germanium (SiGe). The second substrate 40II in the second region R2 may comprise semiconductor material, such as silicon or germanium. In some embodiments, the etch stop layer 30, the second substrate 40I, and the second substrate 40II may be formed by epitaxial growth on the first substrate 10 using a mask to form the semiconductor substrate B1. In one embodiment, semiconductor devices, e.g., the first diode 45, the second diode 46, the semiconductor structure 104, and/or semiconductor structure 105 describe above or the like may be formed in the first region R1. In one embodiment, peripheral device(s) such as a control device, a word line selection device, and a bit line selection device may be formed in the second region R2.

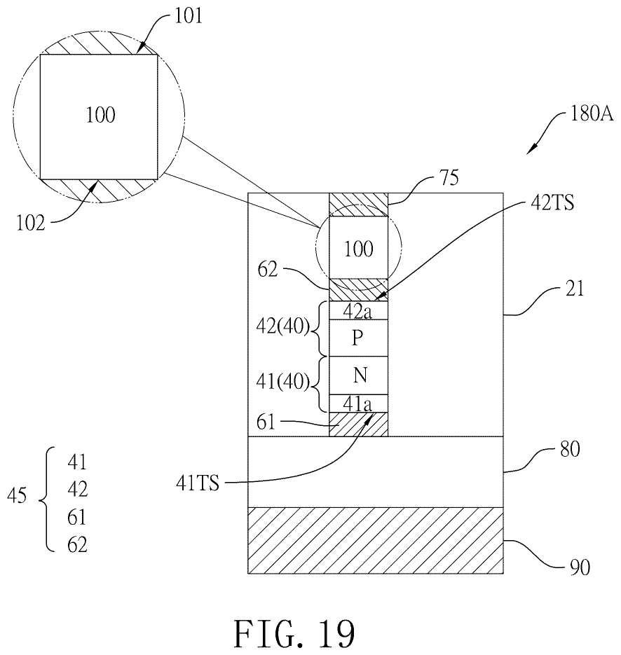

FIG. 19 is a schematic view to illustrate an embodiment of a semiconductor structure according to the present disclosure. As shown in FIG. 19, a semiconductor structure 180A is provided. The semiconductor structure 180A may be similar to the semiconductor structure 105 described above with respect to FIGS. 1J, 3I, 4F, 5G, 6H, and 7D, where like reference numerals indicate like elements. The semiconductor structure 180A or similar semiconductor structures may be formed by processes similar to that described above with respect to FIGS. 1A to 1J, 2A to 2E, 3A to 3I, 4A to 4F, 5A to 5G, 6A to 6H, 7A to 7D, 16A to 16D, and 17A to 17C. Related details described above may apply here if applicable.

The semiconductor structure 180A comprises a first doped region 41 and a second doped region 42. The first doped region 41 and the second doped region 42 shown in FIG. 19 may be substantially similar to the first doped region 41 and the second doped region 42 described above with respect to FIG. 1A to 1J, respectively, and the related description is omitted for brevity. The second doped region 42 is disposed over and in contact with the first doped region 41. The first doped region 41 is doped with a first conductivity-type of dopant, and the second doped region 42 is doped with a second conductivity-type of dopant opposite to the first conductivity-type. In the embodiment shown in FIG. 19, the first doped region 41 is doped with n-type dopant, and the second doped region 42 is doped with p-type dopant, and a p-n junction is formed between the first doped region 41 and the second doped region 42. In one embodiment, each of the first doped region 41 and the second doped region 42 comprises a single crystalline semiconductor material. As shown in FIG. 19, the sidewalls of the first doped region 41 and the second doped region 42 are vertically aligned.

In the embodiment shown in FIG. 19, the first doped region 41 comprises a first heavily-doped region 41a extending from the bottom surface 41BS of the first doped region 41. The first heavily-doped region 41a is doped with the first conductivity-type of dopant (e.g., the n-type dopant). In the embodiment shown in FIG. 19, the second doped region 42 comprises a second heavily-doped region 42a extending from the top surface 42TS of the second doped region 42. The second heavily-doped region is doped with the second conductivity-type of dopant (e.g., the p-type dopant). The first heavily-doped region 41a and the second heavily-doped region 42a shown in FIG. 19 may be substantially similar to the first heavily-doped region 41a and the second heavily-doped region 42a described above with respect to FIG. 1A to 1J, respectively, and the related description is omitted for brevity.

As shown in FIG. 19, the semiconductor structure 180A further comprises a first ohmic contact 61 and a second ohmic contact 62. The first ohmic contact 61 is disposed in contact with a bottom surface of the first doped region 41. An ohmic junction is formed between the first doped region 41 and the first ohmic contact 61. The second ohmic contact 62 is disposed in contact with a top surface of the second doped region 42. An ohmic junction is formed between the second doped region 42 and the second ohmic contact 62. The first ohmic contact 61 and the second ohmic contact 62 shown in FIG. 19 may be substantially similar to the first ohmic contact 61 and the second ohmic contact 62 described above with respect to FIGS. 1A to 1J, respectively, and the related description is omitted for brevity.

As shown in FIG. 19, the semiconductor structure 180A further comprises a first dielectric layer 21. The first dielectric layer 21 is disposed surrounding each of the first doped region 42, the second doped region 42, the first ohmic contact 61, and the second ohmic contact 62. The first dielectric layer 21 shown in FIG. 19 may be substantially similar to the first dielectric layer 21 described above with respect to FIG. 1A to 1J, respectively, and the related description is omitted for brevity.

In the embodiment shown in FIG. 19, the semiconductor structure 180A may further comprise a memory unit 100. The memory unit 100 have a first end 101 and a second end 102. The memory unit 100 is electrically coupled to the first ohmic contact 61 from the second end 102 of the memory unit 100. The memory unit 100 shown in FIG. 19 may be substantially similar to the memory unit 100 described above with respect to FIG. 1J, and the related description is omitted for brevity. In one embodiment, the memory unit 100 may comprise a magnetic tunnel junction (MTJ) structure, or a phase-change material, or a variable resistance material. The semiconductor structure 180A shown in FIG. 19 may be a PcRAM device or RRAM device. Despite that only one memory cell is illustrated in FIG. 19, a plurality of memory cells or an array of memory cells can be fabricated at the same time using the method disclosed herein.

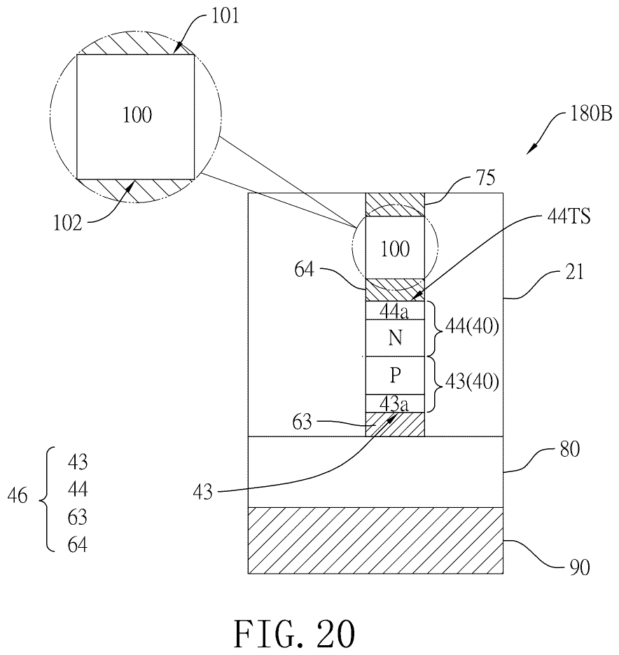

FIG. 20 is a schematic view to illustrate an embodiment of a semiconductor structure according to the present disclosure. As shown in FIG. 20, a semiconductor structure 180B is provided. The semiconductor 180B shown in FIG. 20 may be substantially similar to the semiconductor structure 105 described above with respect to FIGS. 1J, 3I, 4F, 5G, 6H, and 7D, where like reference numerals indicate like elements. The semiconductor structure 180B or similar semiconductor structures may be formed by processes similar to that described above with respect to FIGS. 1A to 1J, 2A to 2E, 3A to 3I, 4A to 4F, 5A to 5G, 6A to 6H, 7A to 7D, 16A to 16D, and 17A to 17C. Related details described above may apply here if applicable.

The semiconductor structure 180B comprises a third doped region 43 and a fourth doped region 44. The third doped region 43 and the fourth doped region 44 shown in FIG. 20 may be substantially similar to the third doped region 43 and the fourth doped region 44 described above with respect to FIG. 1A to 1J, respectively, and the related description is omitted for brevity. The fourth doped region 44 is disposed over and in contact with the third doped region 43. The third doped region 43 is doped with a first conductivity-type of dopant, and the fourth doped region 44 is doped with a second conductivity-type of dopant opposite to the first conductivity-type. In the embodiment shown in FIG. 20, the third doped region 43 is doped with p-type dopant, and the fourth doped region 44 is doped with n-type dopant, and a p-n junction is formed between the third doped region 43, and the fourth doped region 44. In one embodiment, each of the third doped region 43 and the fourth doped region 44 comprises a single crystalline semiconductor material. As shown in FIG. 20, the sidewalls of the third doped region 43 and the fourth doped region 44 are vertically aligned.

In the embodiment shown in FIG. 20, the third doped region 43 comprises a third heavily-doped region 43a extending from the bottom surface 43BS of the third doped region 43. The third heavily-doped region 43a is doped with the first conductivity-type of dopant (e.g., the p-type dopant). In the embodiment shown in FIG. 20, the fourth doped region 44 comprises a fourth heavily-doped region 44a extending from the top surface 44TS of the fourth doped region 44. The fourth heavily-doped region 44a is doped with the second conductivity-type of dopant (e.g., the n-type dopant). The third heavily-doped region 43a and the fourth heavily-doped region 44a shown in FIG. 20 may be substantially similar to the third heavily-doped region 43a and the fourth heavily-doped region 44a described above with respect to FIGS. 1A to 1J, respectively, and the related description is omitted for brevity.

As shown in FIG. 20, the semiconductor structure 180B further comprises a third ohmic contact 63 and a fourth ohmic contact 64. The third ohmic contact 63 is disposed in contact with a bottom surface of the third doped region 43. An ohmic junction is formed between the third doped region 43 and the third ohmic contact 63. The fourth ohmic contact 64 is disposed in contact with a top surface of the fourth doped region 44. An ohmic junction is formed between the fourth doped region 44 and the fourth ohmic contact 64. The third ohmic contact 63 and the fourth ohmic contact 64 shown in FIG. 19 may be substantially similar to the third ohmic contact 63 and the fourth ohmic contact 64 described above with respect to FIGS. 1A to 1J, respectively, and the related description is omitted for brevity.

As shown in FIG. 20, the semiconductor structure 180B further comprises a first dielectric layer 21. The first dielectric layer 21 is disposed surrounding each of the third doped region 43, the fourth doped region 44, the third ohmic contact 63, and the fourth ohmic contact 64. The first dielectric layer 21 shown in FIG. 20 may be substantially similar to the first dielectric layer 21 described above with respect to FIGS. 1A to 1J, respectively, and the related description is omitted for brevity.

In the embodiment shown in FIG. 20, the semiconductor structure 180B may further comprise a memory unit 100. The memory unit 100 have a first end 101 and a second end 102. The memory unit 100 is electrically coupled to the fourth ohmic contact 64 from the second end 102 of the memory unit 100. The memory unit 100 shown in FIG. 20 may be substantially similar to the memory unit 100 described above with respect to FIG. 1J, and the related description is omitted for brevity. In one embodiment, the memory unit 100 may comprise a magnetic tunnel junction (MTJ) structure, or a phase-change material, or a variable resistance material. The semiconductor structure 180B shown in FIG. 20 may be a PcRAM device or RRAM device. Despite that only one memory cell is illustrated in FIG. 20, a plurality of memory cells or an array of memory cells can be fabricated at the same time using the method disclosed herein.

The foregoing description of embodiments is provided to enable any person skilled in the art to make and use the subject matter. Various modifications to these embodiments will be readily apparent to those skilled in the art, and the novel principles and subject matter disclosed herein may be applied to other embodiments without the use of the innovative faculty. The claimed subject matter set forth in the claims is not intended to be limited to the embodiments shown herein but is to be accorded the widest scope consistent with the principles and novel features disclosed herein. It is contemplated that additional embodiments are within the spirit and true scope of the disclosed subject matter. Thus, it is intended that the present invention covers modifications and variations that come within the scope of the appended claims and their equivalents.

What is claimed is:

1. A semiconductor structure, comprising:
a first doped region;
a second doped region over and in contact with the first doped region;
a first ohmic contact in contact with a bottom surface of the first doped region;
a second ohmic contact in contact with a top surface of the second doped region; and
a first dielectric structure surrounding each of the first doped region, the second doped region, the first ohmic contact, and the second ohmic contact;
wherein the first doped region is doped with a first conductivity-type of dopant, and the second doped region is doped with a second conductivity-type of dopant opposite to the first conductivity-type, such that a p-n junction is formed between the first doped region and the second doped region; and wherein an ohmic junction is formed between the first doped region and the first ohmic contact, and an ohmic junction is formed between the second doped region and the second ohmic contact.

2. The semiconductor structure of claim 1, wherein the first doped region comprises a first heavily-doped region extending from the bottom surface of the first doped region; and the first heavily-doped region is doped with the first conductivity-type of dopant.

3. The semiconductor structure of claim 1, wherein the second doped region comprises a second heavily-doped region extending from the top surface of the second doped region; and
the second heavily-doped region is doped with the second conductivity-type of dopant.

4. The semiconductor structure of claim 1, wherein each of the first doped region and the second doped region comprises a single crystalline semiconductor material.

5. The semiconductor structure of claim 1, wherein the sidewalls of the first doped region and the second doped region are vertically aligned.

6. The semiconductor structure of claim 1 further comprising a memory unit having a first end and a second end, wherein the memory unit is electrically coupled to the first ohmic contact from the second end of the memory unit.

7. The semiconductor structure of claim 6, wherein the memory unit comprises a magnetic tunnel junction (MTJ) structure, or a phase-change material, or a variable resistance material.

8. A method for manufacturing a semiconductor structure, comprising:
(a) providing a semiconductor substrate comprising a first substrate and a second substrate on the first substrate;
(b) forming a first ohmic contact on the first surface of the second substrate or in the second substrate;
(c) patterning the second substrate to define a first doped region;
(d) adding a third substrate to the first surface of the second substrate, wherein the second substrate is between the third substrate and the first substrate;
(e) removing the first substrate and exposing a second surface of the second substrate opposite to the first surface;
(f) either exposing or forming a second doped region in the second substrate or on the second surface of the second substrate
(g) forming a second ohmic contact on the second surface of the second substrate or in the second substrate.

9. The method of claim 8, wherein the second substrate is doped with a first conductivity-type of dopant.

10. The method of claim 8, wherein the second doped region is doped with a second conductivity-type of dopant opposite to the first conductivity-type.

11. The method of claim 8, wherein the semiconductor substrate further comprises a bonding layer between the first substrate and the second substrate; and the step (e) further comprises removing the bonding layer.

12. The method of claim 11, wherein the semiconductor substrate further comprises an etch stop layer between the second substrate and the bonding layer; and the step (e) further comprises removing at least a portion of the etch stop layer.

13. The method of claim 8, wherein the semiconductor substrate further comprises an etch stop layer between the first substrate and the second substrate; and the step (e) further comprises removing at least a portion of the etch stop layer.

14. The method of claim 8, wherein the step (b) further comprises forming a first heavily-doped region.

15. The method of claim 8, wherein the second doped region comprises a second heavily-doped region.

16. The method of claim 8 further comprising (h) forming a memory unit after the step (f), wherein the memory unit is electrically coupled to the second ohmic contact.

17. The method of claim 8, wherein the second substrate comprises a single crystalline semiconductor material.

18. The method of claim 8 further comprising depositing a first dielectric structure surrounding the first doped region before the step (d).

19. A semiconductor structure, comprising:
a first diode comprising a first doped region and a second doped region over and in contact with the first doped region; and
a second diode comprising a third doped region and a fourth doped region over and in contact with the third doped region;
wherein each of the first doped region and the fourth doped region is doped with a first conductivity-type of dopant, and each of the second doped region and the third doped region is doped with a second conductivity-type of dopant opposite to the first conductivity-type; and
a top surface of the second doped region is higher than a bottom surface of the third doped region, and a top surface of the fourth doped region is higher than a bottom surface of the first doped region.

20. The semiconductor structure of claim 19, wherein the bottom surface of the first doped region is substantially level with the bottom surface of the third doped region.

21. The semiconductor structure of claim 19, wherein the top surface of the second doped region is substantially level with the top surface of the fourth doped region.

22. The semiconductor structure of claim 19, wherein the first diode further comprises a first ohmic contact in contact with the bottom surface of the first doped region, and the second diode further comprises a fourth ohmic contact in contact with the top surface of the fourth doped region.

23. The semiconductor structure of claim 19, wherein the first diode further comprises a second ohmic contact in contact with the top surface of the second doped region, and the second diode further comprises a third ohmic contact in contact with the bottom surface of the third doped region.

24. The semiconductor structure of claim 19, wherein the first doped region comprises a first heavily-doped region extending from the bottom surface of the first doped region, and the fourth doped region comprises a fourth heavily-doped region extending from the top surface of the fourth doped region ; each of the first heavily-doped region and the fourth heavily-doped region is doped with the first conductivity-type of dopant.

25. The semiconductor structure of claim 19, wherein the second doped region comprises a second heavily-doped region extending from the top surface of the second doped region, and the third doped region comprises a third heavily-doped region extending from the bottom surface of the third doped region; each of the second heavily-doped region and the third heavily-doped region is doped with the second conductivity-type of dopant.

26. The semiconductor structure of claim 19 further comprising a first dielectric structure, wherein each of the first diode and the second diode is surrounded by the first dielectric structure.

27. The semiconductor structure of claim 19, wherein each of the first doped region and the fourth doped region comprises a single crystalline semiconductor material.

28. The semiconductor structure of claim 19, wherein each of the second doped region and the third doped region comprises a single crystalline semiconductor material.

29. The semiconductor structure of claim 19, wherein the sidewalls of first doped region and the second doped region of the first diode are vertically aligned, and sidewalls of the third doped region and the fourth doped region of the second diode are vertically aligned.

30. The semiconductor structure of claim 19 further comprising a memory unit having a first end and a second end, wherein the memory unit is electrically coupled to both the first diode and the second diode from the second end of the memory unit.

31. The semiconductor structure of claim 30, wherein the memory unit is electrically coupled to both the second doped region of the first diode and the fourth doped region of the second diode.

32. The semiconductor structure of claim 30, wherein the memory unit comprises a magnetic tunnel junction (MTJ) structure, or a phase-change material, or a variable resistance material.

33. A method for manufacturing a semiconductor structure, comprising:
(a) providing a semiconductor substrate comprising a first substrate and a second substrate on the first substrate;
(b) forming a third doped region of a second diode in the second substrate or on a first surface of the second substrate;
(c) patterning the second substrate to define a first doped region of the first diode and a fourth doped region of a second diode;
(d) adding a third substrate to the first surface of the second substrate, wherein the second substrate is between the third substrate and the first substrate;
(e) removing the first substrate and exposing a second surface of the second substrate opposite to the first surface;
(f) either exposing or forming a second doped region of the first diode in the second substrate or on the second surface of the second substrate.

34. The method of claim 33, wherein the second substrate is doped with a first conductivity-type of dopant.

35. The method of claim 34, wherein each of the second doped region and the third doped region is doped with a second conductivity-type of dopant opposite to the first conductivity-type.

36. The method of claim 33, wherein the semiconductor substrate further comprises a bonding layer between the first substrate and the second substrate; and the step (e) further comprises removing the bonding layer.

37. The method of claim 36, wherein the semiconductor substrate further comprises an etch stop layer between the second substrate and the bonding layer; and the step (e) further comprises removing at least a portion of the etch stop layer.

38. The method of claim 33, wherein the semiconductor substrate further comprises an etch stop layer between the first substrate and the second substrate; and the step (e) further comprises removing at least a portion of the etch stop layer.

39. The method of claim 33, wherein the step (b) further comprises forming a first ohmic contact of the first diode and a third ohmic contact of the second diode on the first surface of the second substrate or in the second substrate.

40. The method of claim 33, wherein the step (f) further comprises forming a second ohmic contact of the first diode and a fourth ohmic contact of the second diode on the second surface of the second substrate or in the second substrate.

41. The method of claim 33, wherein the step (b) further comprises forming a first heavily-doped region.

42. The method of claim 33, wherein the step (f) further comprises either exposing or forming a fourth heavily-doped region.

43. The method of claim 33, wherein the second doped region comprises a second heavily-doped region.

44. The method of claim 33, wherein the third doped region comprises a third heavily-doped region.

45. The method of claim 33 further comprising (h) forming a memory unit before the step (d), wherein the memory unit is electrically coupled to both the first diode and the second diode.

46. The method of claim 33 further comprising (h) forming a memory unit after the step (f), wherein the memory unit is electrically coupled to both the first diode and the second diode.

47. The method of claim 33 further comprising forming a conformal etch stop layer on the sidewalls of the first doped region, the third doped region, and the fourth doped region after the step (c).

48. The method of claim 33, wherein the second substrate comprises a single crystalline semiconductor material.

49. A memory device, comprising:
a memory unit having a first end and a second end;
an electrode extending laterally in a first direction from a first side of the memory unit to a second side of the memory unit, wherein the memory unit is electrically coupled to the electrode from the second end of the memory unit;
a first diode pair disposed on the first side of the memory unit; and
a second diode pair disposed on the second side of the memory unit;
wherein each of the first diode pair and the second diode pair comprises a first diode and a second diode, each of the first diode of the first diode pair and the second diode pair comprises a first doped region and a second doped region over and in contact with the first doped region, each of the second diode of the first diode pair and the second diode pair comprises a third doped region and a fourth doped region over and in contact with the third doped region, each of the first doped region of the first diode pair and the second diode pair is doped with a first conductivity-type of dopant, each of the second doped region of the first diode pair and the second diode pair is doped with a second conductivity-type of dopant opposite to the first conductivity-type, each of the third doped region of the first diode pair and the second diode pair is doped with a second conductivity-type of dopant, and each of the fourth doped region is doped with a first conductivity-type of dopant; and
wherein in each of the first diode pair and the second diode pair, a top surface of the second doped region is higher than a bottom surface of the third doped region, and a top surface of the fourth doped region is higher than a bottom surface of the first doped region; and
wherein each of the first diode and the second diode of the first diode pair is electrically coupled to the electrode at the first side of the memory unit, and each of the first diode and the second diode of the second diode pair is electrically coupled to the electrode at the second side of the memory unit.

50. The memory device of claim 49, wherein the electrode is disposed vertically between the memory unit and the first diode pair.

51. The memory device of claim 49, wherein the electrode is disposed vertically between the memory unit and the second diode pair.

52. The memory device of claim 49, wherein the memory unit comprises a magnetic tunnel junction (MTJ) structure.

53. The memory device of claim 49, wherein the memory unit is electrically coupled to a bit line from the first end of the memory unit.

54. The memory device of claim 53, wherein the bit line extends laterally in a second direction different from the first direction.

55. The memory device of claim 49, wherein the first diode and the second diode of the first diode pair are arranged in the first direction.

56. The memory device of claim 49, wherein the first diode and the second diode of the second diode pair are arranged in the first direction.

57. The memory device of claim 49, wherein both the first diode and the second diode of the first diode pair are electrically coupled to a first word line, and the first word line extends laterally in a second direction different from the first direction.

58. The memory device of claim 49, wherein the first diode of the first diode pair is electrically coupled to a first word line, the second diode of the first diode pair is electrically coupled to a second word line, and both the first word line and the second word line extend laterally in a second direction different from the first direction.

59. The memory device of claim 49, wherein the first diode of the second diode pair is electrically coupled to a third word line, the second diode of the second diode pair is electrically coupled to a fourth word line, and both the third word line and the fourth word line extend in the first direction.

60. The memory device of claim 59, wherein the memory unit is disposed vertically between the fourth word line and the electrode.

61. The memory device of claim 49, wherein both the first diode and the second diode of the second diode pair are electrically coupled to a third word line, and the third word line extends in the first direction.

62. The memory device of claim 49, wherein the first diode and the second diode of the first diode pair are arranged laterally in a second direction different from the first direction.

63. The memory device of claim 49, wherein the first diode and the second diode of the second diode pair are arranged laterally in a second direction different from the first direction.

64. The memory device of claim 49, wherein the memory device has a cell size between about 16 feature squares (F²) and about 32 feature squares (F²).
